(19) United States
(12) Patent Application Publication
(10) Pub. No.: US 2025/0382171 A1
(43) Pub. Date: Dec. 18, 2025

(54) SYSTEMS AND METHODS FOR MECHANICALLY INTERLOCKING STRUCTURES AND METAMATERIALS FOR COMPONENT INTEGRATION

(71) Applicant: University of Hawaii, Honolulu, HI (US)

(72) Inventors: Joseph Brown, Honolulu, HI (US); Kody Wakumoto, Honolulu, HI (US); Geoffrey Garcia, Honolulu, HI (US)

(21) Appl. No.: 18/876,344

(22) PCT Filed: Jul. 17, 2023
(86) PCT No.: PCT/US2023/070359

§ 371 Date: Dec. 18, 2024

Related U.S. Application Data
(60) Provisional application No. 63/389,438, filed on Jul. 15, 2022.

(51) Int. Cl. B81C 3/00

(52) U.S. Cl. CPC B81C 3/008

(57) ABSTRACT

A system for mechanical attachment includes a first structure including a first body that is configured for a supporting surface and is connected to a member that extends from the first body. The system further includes a second structure including a second body that is also configured for a supporting surface with a compliant member that extends from the second body. The second structure is configured to form a connection with the first structure by deformation of at least a portion of the compliant member relative to the first structure.

### CROSS REFERENCE TO RELATED APPLICATIONS

This is a PCT application that claims benefit to U.S. provisional application Ser. No. 63/389,438 filed on Jul. 15, 2022 which is incorporated by reference in its entirety.

### GOVERNMENT SUPPORT

This invention was made with government support under FA9550-20-1-0256 awarded by the Air Force Office of Scientific Research (AFOSR). The government has certain rights in the invention.

### FIELD

The present disclosure generally relates to electronics manufacturing and mechanical retention technologies; and in particular to systems and methods for mechanical attachment using asymmetric construction for heterogenous integration.

### BACKGROUND

Existing methods for mechanical attachment in microelectronics rely on permanent mechanisms such as solder joints or wiring. While these attachment mechanisms provide strong electrical connections, they come with drawbacks such as a potential of failure due to thermal expansion mismatch, or radio frequency (RF) interference due to wiring acting as a pseudo-antenna that interferes in RF applications. A reworkable mechanical attachment structure that is capable of providing a both strong physical and electrical connection has yet to be developed due to difficulties in modeling behavior of materials at small scale.

It is with these observations in mind, among others, that various aspects of the present disclosure were conceived and developed.

### SUMMARY

The present disclosure provides a number of examples that describe mechanical attachment techniques and operations for reworkable heterogenous integration in, e.g., electronics manufacturing. In the context of the disclosed methods, devices, techniques, apparatus, systems, and so on, the terms “operable to,” “configured to,” and “capable of” used herein are interchangeable.

In a first set of illustrative examples, the disclosed mechanical attachment techniques are embodied as a system for mechanical attachment between, e.g., a substrate and a chip. The system includes a first structure including a first body defining a first end and a second end opposite the first end, with the first end configured to be fixed to a first supporting surface, and a member extending from the second end of the first body. The system further includes a second structure configured for engagement with the first structure, including: a second body defining a first end and a second end opposite the first end, with the first end configured to be fixed to a second supporting surface and a compliant member extending from the second end of the second body, with the compliant member configured for deformation. The second structure is configured to form a connection with the first structure by deformation of at least a portion of the compliant member relative to the first structure.

In a second set of illustrative examples, the disclosed mechanical attachment techniques are embodied as a system of mechanically interlocking materials for component integration. The system includes one or more first structures. Each of the first structures defines a member and includes at least a rigid portion that resists deformation. The system further includes one or more second structures. Each of the second structures defines a compliant member, including at least some portion configured for deformation relative to the first structure. The member of the first structures can include a rigid cantilever extending from a body (e.g., pillar), and the compliant member of the second structures can include a compliant cantilever extending from a body (e.g., pillar).

In a third set of illustrative examples, the disclosed mechanical attachment techniques are embodied as a method of making a system for mechanical attachment, wherein the interlocking structures can be fabricated using microfabrication processes. Specifically, non-planar or out-of-plane structures can be shaped with patterned photoresist or other polymers, and such polymer materials can then serve as sacrificial material which is removed after fabrication of the first and second structures, and thereby enables mechanical engagement between the first and second structures.

In a fourth set of illustrative examples, the disclosed mechanical attachment techniques are embodied as a method of making a system for mechanical attachment, comprising steps of forming an array of first structures, including steps of forming a base pattern of sacrificial photoresist on a substrate using photolithography; depositing a metal layer over the base pattern of sacrificial photoresist; forming a final pattern of sacrificial photoresist on top of the metal layer to construct a rigid member along each of the first structures; etching away a portion of the metal layer that is uncovered by the final pattern of sacrificial photoresist; and removing all layers of sacrificial photoresist to release the first structures. The method further includes forming an array of second structures, including steps of: forming a base pattern of sacrificial photoresist on a substrate using photolithography; forming an upper pattern of sacrificial photoresist on the base pattern using photolithography to create three-dimensional shaping on the base pattern; depositing a metal layer over the sacrificial photoresist; forming a final pattern of sacrificial photoresist on top of the metal layer to construct a compliant member along each of the second structures; etching away a portion of the metal layer that is uncovered by the final pattern of sacrificial photoresist; and removing all layers of sacrificial photoresist to release the second structures. In this example, the method accommodates mechanical engagement between the first and second structures.

The foregoing examples broadly outline various aspects, features, and technical advantages of examples according to the disclosure in order that the detailed description that follows may be better understood. It is further appreciated that the above operations described in the context of the illustrative example method, device, and computer-readable medium are not required and that one or more operations may be excluded and/or other additional operations discussed herein may be included. Additional features and advantages will be described hereinafter. The conception and specific examples illustrated and described herein may be readily utilized as a basis for modifying or designing other structures for carrying out the same purposes of the present disclosure. Such equivalent constructions do not depart from the spirit and scope of the appended claims.

### BRIEF DESCRIPTION OF THE DRAWINGS

FIG. 1 depicts a simplified diagram of a method of quick joining chips with interlocking cantilever pads.

FIG. 2A depicts an isometric view of an array of rigid interlocking structures and an array of rigid interlocking structures in the process of engaging an array of flat compliant cantilever structures.

FIGS. 3A and 3B depict simplified isometric views of an array of flat compliant cantilever structures with dimensional variables and an array of rigid interlocking structures with dimensional variables.

FIG. 3C depicts a side view of a single rigid interlocking structure and a single flat compliant cantilever structure with dimensional variables.

FIG. 3D depicts a plot of the expected bond strength as a function of the width of the supporting pillar of the compliant cantilever structure where the aspect ratio is maximized.

FIGS. 4A and 4B depict a simplified side view of a misaligned interlocking cantilever structure both before and after deflection has occurred.

FIG. 4C depicts a plot of the maximum snap-through force for a pair of cantilevers as a function of the translational misalignment of the interlocking cantilevers, where P1 represents a growing separation distance and P2 represents a decreasing separation distance.

FIG. 4D depicts a plot of the vertical force acting on the cantilever contact point as a function of the translational misalignment of the interlocking cantilevers.

FIG. 4E depicts a plot of the net horizonal force components acting on the misaligned cantilever pair as a function of the translational misalignment of the interlocking cantilevers.

FIG. 5A depicts a plot of the normalized force as a function of normalized cantilever end displacement under a yield stress constraint.

FIG. 5B depicts a plot of the dimensionless length as a function of the normalized cantilever end displacement under a yield stress constraint.

FIG. 5C depicts a plot of the maximum bending stress as a function of the cantilever aspect ratio at several given maximum displacement values of the cantilever end under a yield stress constraint.

FIGS. 6A, 6B, 6C, 6D, and 6E depict the set up of the large scale deflection model for 2 interlocking flat compliant cantilevers.

FIG. 7 depicts the initial 2-Dimensional (2D) deflection simulation of two cantilevers in contact.

FIG. 8 depicts a plot of the normalized loading parameter as a function of the normalized displacement for the contact condition of two cantilevers, the point load, and the analytical model described herein.

FIG. 9 depicts the dimensionless loading parameter as a function of the dimensionless displacement for both simulation data and physical testing results.

FIG. 10 depicts the normalized force as a function of the normalized displacement for various aspect ratios.

FIGS. 11A and 11B depict plots of the push in force as a function of the displacement of the cantilevers and the pull out force as a function of the displacement of the cantilevers.

FIG. 12 depicts a 2D simulation of two flat cantilevers positioned at a 45-degree angle in contact.

FIG. 13 depicts a 2D simulation of two flat cantilevers positioned at a 45-degree angle undergoing deformation.

FIG. 14 depicts a 2D simulation of 2 “L” shaped cantilevers being pulled apart.

FIG. 15 depicts a side view of the experimental set up for 2 stainless steel “L” shaped cantilevers as they are pushed together.

FIG. 16 depicts a plot of the force required as a function of the displacement of the stainless steel “L” shaped cantilevers for both test data and simulated data.

FIGS. 17A and 17B depict plots of the averaged test data of the force of push in and pull out as a function of displacement of the stainless steel “L” shaped cantilevers.

FIG. 18 depicts a 2D simulation of an “L” shaped cantilever having a 45-degree angle as it is pulled upward.

FIG. 19 depicts a 2D simulation of 2 interlocking hook cantilevers.

FIG. 20 depicts a 2D simulation of the inverted “S” cantilever.

FIG. 21 depicts a 2D simulation of the inverted “S” cantilever having radii in place of corners.

FIG. 22 depicts a 2D simulation of the inverted “S” cantilever having semicircles in place of corners.

FIG. 23A depicts an isometric view of a 3-dimensional (3D) embodiment of an array of inverted “S” shaped compliant cantilever structures.

FIG. 23B depicts a side view of a single rigid interlocking structure and a single inverted “S” shaped compliant cantilever structure with dimensional variables.

FIG. 23C depicts a plot of the maximal Von Mises stress in the inverted “S” cantilever as a function of the displacement.

FIG. 23D depicts a plot of the vertical component of the applied contact force as a function of the displacement of the inverted “S” cantilever.

FIG. 24 depicts an isometric view of a 3D embodiment of an array of inverted “S” shaped compliant cantilever structures having extended cantilever ends.

FIGS. 25A and 25B depict a side view of a single compliant inverted “S” cantilever structure before and after engaging with a rigid interlocking structure.

FIG. 26A depicts a plot of averaged push in and pull-out forces as a function of displacement for a stainless steel inverted “S” cantilever.

FIG. 26B depicts a plot of the push in and pull-out forces as a function of displacement for an aluminum inverted “S” cantilever.

FIG. 27 depicts a side view of the experimental test of the aluminum inverted “S” cantilever undergoing a push in deflection test.

FIGS. 28A and 28B depict plots of averaged test data of the force of push in and pull out as a function of displacement of the aluminum inverted “S” cantilever.

FIG. 29 depicts a plot of the force of push in and pull out as a function of displacement of the aluminum inverted “S” cantilever comparing the experimental data to simulated data.

FIG. 30 depicts a side view of the experimental test of the stainless steel inverted “S” cantilever undergoing a pull-out test.

FIGS. 31A and 31B depict plots of averaged test data of the force of push in and pull out as a function of displacement of the stainless steel inverted “S” cantilever.

FIG. 32 depicts a plot of the force of push in and pull out as a function of displacement of the stainless steel inverted “S” cantilever comparing the experimental data to simulated data.

FIG. 33 depicts a side view of an embodiment of curved interlocking cantilevers and an isometric view of a 3D array of curved interlocking cantilevers.

FIG. 34 depicts isometric view of a 2D array of serpentine shaped cantilevers and a side view of a single serpentine shaped cantilever.

FIG. 35 depicts an isometric view of an additional embodiment of the 3D array of the serpentine shaped cantilevers.

FIGS. 36A and 36B depict side and isometric views of a 1D interlocking cantilever array.

FIGS. 37A and 37B depict isometric views of a single unit of a proposed interlocking flat cantilever structure and an array of interlocking flat cantilever structures.

FIG. 38A depicts a plot of the bonding strength of the 1D interlocking cantilever array as a function of pillar pitch as compared to previously available data.

FIG. 38B depicts a plot of bonding strength of the 1D interlocking cantilever array as a function of displacement comparing the 1D array with a 2D array.

FIG. 38C depicts a plot of the tensile strength of the 1D and 2D interlocking cantilever designs along with existing bonding data and commercially available Velcro™.

FIG. 38D depicts a plot of the tensile strength of commercially available permanent joining methods used in MEMS devices.

FIG. 39 depicts a 3D simulation of the central pillar of the interlocking cantilever array under a load force.

FIG. 40A depicts a plot of the displacement of the central pillar of the interlocking cantilever array as a function of the applied load force.

FIG. 40B depicts a plot of the Von Mises stress of the central pillar of the interlocking cantilever array as a function of the applied load force in different locations on the central pillar.

FIG. 41 depicts a flowchart of a method for optimal cantilever design.

FIG. 42A depicts a plot of the large and small deflection models with the plotted snap through force and corresponding snap-through displacement.

FIG. 42B depicts a plot of the normalized cantilever arc length that extends from the anchor point to the contact point as the vertical contact point increases.

FIG. 42C depicts a plot of several nondimensional displacements as lines against bending stress plotted against the bending stress and cantilever aspect ratio.

FIG. 43 depicts a plot of the bond strength of an interlocking cantilever array as a function of thru-via width.

FIG. 44 depicts various steps for a method of fabricating a free-standing thin film structure.

FIG. 45 depicts a series of photomasks for use in the photolithography steps of manufacturing an array of interlocking compliant cantilevers.

FIG. 46 depicts a series of photomasks for use in the photolithography steps of manufacturing an array of rigid interlocking structures.

FIG. 47 depicts simplified diagrams of various interlocking cantilever attachment schemes.

FIGS. 48A, 48B, 48C, and 48D depict plots of raw force data as a function of displacement for a flat aluminum cantilever having an interaction distance of 2.5″, 3″, 3.5″, and 4″.

FIG. 49A depicts a plot of the averaged force data at each interaction distance as a function of displacement for the flat aluminum cantilever.

FIG. 49B depicts a plot of the averaged nondimensional force as a function of the nondimensional displacement for the flat aluminum cantilever at each interaction distance and using the elliptic model.

FIGS. 50A, 50B, 50C, and 50D depict plots of raw force data as a function of displacement for a flat brass cantilever having an aspect ratio of 174, 193, 232, and 271.

FIG. 51A depicts a plot of the processed force data at each aspect ratio as a function of displacement for the flat brass cantilever.

FIG. 51B depicts a plot of the normalized force as a function of the normalized displacement for the flat brass cantilever at each aspect ratio and using the elliptic model.

FIGS. 52A, 52B, and 52C depict plots of raw force data as a function of displacement for a flat copper cantilever having an aspect ratio of 174, 193, and 232.

FIG. 53A depicts a plot of the averaged force data at each aspect ratio as a function of displacement for the flat copper cantilever.

FIG. 53B depicts a plot of the averaged nondimensional force as a function of the nondimensional displacement for the flat copper cantilever at each aspect ratio and using the elliptic model.

FIG. 54 depicts a plot of the average force data at each tested interaction length as a function of displacement for thick flat copper samples.

FIG. 55 depicts a plot of the dimensionless loading parameter at each tested interaction length as a function of dimensionless displacement for thick flat copper samples.

FIG. 56 depicts a plot of the simulated dimensionless loading parameter at each tested interaction length as a function of dimensionless displacement for thick flat copper samples.

FIG. 57 depicts a plot comparing the simulated push in and pull out force to the experimental push in and pull out force as a function of displacement of stainless steel “L” shaped cantilevers.

FIG. 58 depicts a plot of the simulated dimensionless loading parameter as a function of the dimensionless displacement of an aluminum cantilever.

FIG. 59 depicts a plot of the experimental dimensionless loading parameter as a function of the dimensionless displacement for varying lengths of an aluminum cantilever.

FIG. 60 depicts a plot of averaged experimental force data at each tested interaction length as a function of displacement of brass cantilevers.

FIG. 61 depicts a plot of experimental dimensionless loading parameter as a function of dimensionless displacement of brass cantilevers.

FIG. 62 depicts a plot of the dimensionless loading parameter at each tested interaction length as a function of dimensionless displacement of thin copper cantilevers simulated in.

FIG. 63 depicts a plot of the averaged experimental force data at each tested interaction length as a function of displacement of thin copper cantilevers.

FIG. 64 depicts a plot of the dimensionless loading parameter at each tested interaction length as a function of dimensionless displacement of thin copper cantilevers.

FIG. 65 depicts a plot of the dimensionless loading parameter at each interaction tested interaction length compared to the analytical dimensionless loading parameter assuming pure plastic deformation as a function of dimensionless displacement of thin copper cantilevers.

FIG. 66A depicts a simplified diagram of a compliant flat cantilever under loading including dimensional variables.

FIG. 66B depicts a plot of the normalized force as a function of normalized deflection of a flat compliant cantilever comparing the large and small deflection models to the 3D finite element model.

FIG. 67 depicts a 3D simulation of 2 flat cantilevers.

Corresponding reference characters indicate corresponding elements among the view of the drawings. The headings used in the figures do not limit the scope of the claims.

### DETAILED DESCRIPTION

Aspects of the present disclosure include examples of mechanical attachment techniques. In one example, the mechanical attachment techniques take the form of a system with a first structure and a second structure configured for (reworkable/releasable) heterogenous integration. By nature of the carefully planned design examples of the system described herein, the forces for engagement of the first structure with the second structure are different from the forces for disengagement (asymmetric forces). At least one of the first or second structures includes a compliant member (e.g., compliant cantilever) that can experience deformation to engage the other corresponding structure. Numerous non-limiting examples of the system and its components are described herein.

### Initial Developments on Interlocking Structures for Heterogeneous Integration

The present disclosure includes examples of interlocking structures for heterogeneous integration in, e.g., electronics manufacturing, using for example freestanding microfabricated electrically conducting films to provide mechanical retention, typically made from metals. The interlocking structures can include an array of free-standing bodies such as pillars with cantilevers extending from the pillar. Complementary surfaces supporting these structures are contacted together and joining takes place by simply applying mechanical force to the components. The cantilevers snap past one another to provide mechanical retention. The present inventive concept is an improvement upon previous attachment technologies by providing modified cantilever designs that accommodate (1) higher retention forces as compared with simple flat cantilevers, (2) an asymmetric force response where the force to join the complementary surfaces is much lower that the force required to pull them apart, and (3) an approach to forming complementary joining structures (and structural arrays) such that one first structure may be reused after initial joining, even if the complementary second structure must be disposed due to permanent deformation in joining and removal processes.

Two example designs of cantilevers are initially presented, one which uses 3D shaping, and one which uses a bimetallic or other curved cantilever. The 3D shaping uses several layers of photoresist to shape the cantilevers into an “L” shape, where the cantilever extends out horizontally, down vertically then out horizontally. This produces a response where the push-in force is much lower than the pull-out force. The other method includes the evaporation of materials with different coefficients of thermal expansion to shape the cantilever into a circular shape that also provides the force asymmetry.

Integration of separately manufactured microelectronic components into a larger device assembly has required new strategies as devices have become smaller and are required to operate at higher temperatures. The process of joining these devices and chips is called heterogeneous integration and there is a need to devise improve efficiency and reduce complexity in this process. Many challenges arise and include standard packaging concerns such as mechanical joining, rework, thermal expansion mismatch, thermal management, electrical connections, and additional unique challenges such as alignment, coupling of RF signals, accommodation of unique material constraints, small contact points, and assembly and manufacturing time. Approaches such as wire bonding, solder, epoxy, and cold welding or brazing face limitations of accuracy, temperature, signal loss, and process time; these constraints motivate a search for novel technologies for heterogeneous integration. Next-generation interconnects utilizing mechanically interlocking structures enable permanent and reworkable joints between microelectronic devices. Previous structures featured two of the same interlocking structures. Aspects of the present disclosure include systems and mechanisms for joining a rigid array with a complementary compliant cantilever array to preserve the condition of reworkability. Mechanical interlocking relies on small structures which join or ‘hook together’ and bending of the interlocking structures is where strength and stiffness comes from. This technology is intended for use in any and all microdevices like processors and sensors as it is a simple way to provide attachment without the need for conventional joining techniques like adhesives. The present technology can also be applied at the macro-level.

During the process of developing new packaging for microelectronic devices, it is often desirable to remove and replace components. Such reworkability then becomes a desirable feature because it means that custom assemblies can be saved to be reused in the event a bonded peripheral device fails. Using a traditional bonding method such as soldering or epoxy requires a tedious and difficult reworking process, which can result in damage to the components. A method of joining wherein components could simply be removed with only mechanical force could be highly advantageous to prototyping. Mechanical interlocking relies on small structures which join or ‘hook together’ and bending of the interlocking structures is where strength and stiffness comes from. This is different from adhesives which rely on some form of chemical bonding, dry adhesive brushes using van der Waals bonding, or in the case of solder, metallic bonding.

Prototyping of microchips creates situations where it would be favorable to change components mounted to a substrate. This imposes a condition where any interlocking structures attached to the substrate must not deform permanently. For reworkable joints, in one approach flat cantilevers would be needed as the force would be the same being pushed in and pulled out, but for this case the length of each cantilever would also have to be large, at least >˜150 times larger than the thickness. This comes with the downside of having a low bond strength.

For chip attachment, there are two types of attachment tasks. For purely mechanical attachment, patches of material may be deposited on a chip to provide a mechanical joint in some unused portion of the chip footprint. Alternatively, bonding on chip contact pads may add electrical signal transfer capabilities to the mechanical attachment. In both cases, it is advantageous to consider the properties of some typical attachment patches as a means to draw abstract mathematical analysis into practical design choices. Applications in RF and reworkability are the main areas where this technology provides the most distinct advantage over current state-of-the-art. Eventual realization of interconnect technology will provide a great improvement of functionality and adaptability in heterogeneous integration and microdevice packaging.

Reworkable joints may enable chips to be removed from their substrates to support reusable device prototyping and packaging, creating the possibility for eventual pick-and-place mechanical bonding of chips with no additional bonding steps required. Interlocking designs present self-aligning in-plane forces that emerge from translational perturbation from perfect alignment.

### Small Deflection Analysis

Analytical modeling of the deflection of a cantilever begins with the Euler-Bernoulli beam theory. The theory states that curvature k=dθ/ds at any distance s along the curve is a function of the bending moment at that point along the beam and is modulated by the flexural rigidity EI, Eq. (1). All analytical models here also assume that cantilever contact points are frictionless, and the cantilevers are inextensible, thus all deflections are due to bending. The flexural rigidity is assumed to be constant along the length, and the thickness of the beam is much smaller than the length. Solving Eq. (1) for a flat beam subjected to a point load at the end results in Eq. (2), which models small cantilever deflections, where the end displacement o is proportional to the applied load P. This model works well for small displacements but is no longer valid once the end of the beam is deflected ˜10° or more.

$$\frac{d θ}{ds} = \frac{M ( s )}{El} \qquad ( 1 )$$

$$δ = \frac{{PL}^{3}}{3 El} \qquad ( 2 )$$

### Large-Deflection Analysis

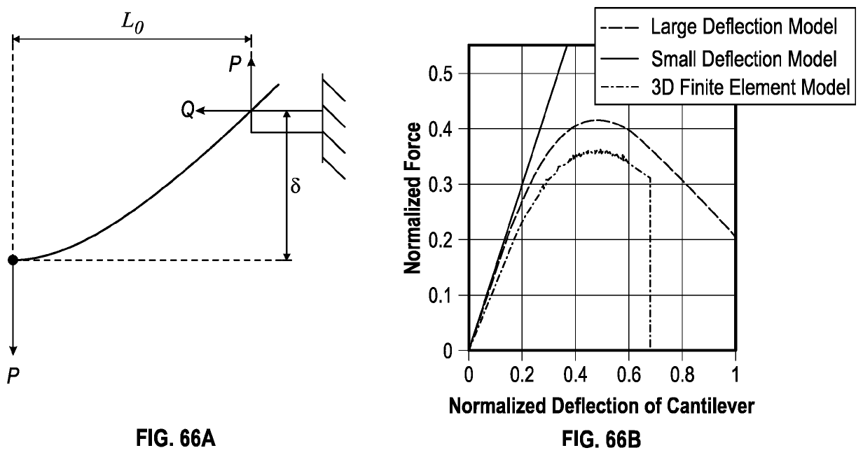

Thin film interlocking structures may deflect to an extent beyond the customary small angle assumption of a few degrees, thereby requiring a large displacement model. Previous work presented an approach to modeling interlocking cantilevers subject to large deflections; this model was implemented here with specific geometric choices for device design. Comparison of the large-deflection and small-deflection models for interlocking horizontal cantilevers subject to vertical displacement is provided in FIG. 66B.

FIG. 66A demonstrates that the large-deflection model peaks at a dimensionless value of 0.417; this corresponds to the peak force that can be delivered by a horizontal cantilever contacting an interlocking constraint. Note that interlocking cantilevers that are too short may trace the force curve but will slip past one another before reaching this peak value. Nonetheless, this peak value can be used directly to predict the maximum force from a pair of interlocked cantilevers and the nominal bond strength σₘ from an array of N of these joints in an area A, Eq. (3).

$${σ}_{m} = \frac{{NP}_{max}}{A} = \frac{N ( 0.417 ) ( 2 El )}{{A ( \frac{d}{2} )}^{2}} \qquad ( 3 )$$

### Finite-Element Modeling

Finite-element analysis (FEA) was performed to verify the analytical methods as well as to enable analysis of more complicated geometries that may add tedious complication to a purely analytical approach. The maximum von Mises stress and contact force were found from surface maxima in post-processing of model results. In simple contacting flat cantilever studies, a divergence was observed; as shown in FIG. 66B, of about 10% from the peak value of the large-deflection analytical model. The analytical flat cantilever model was observed to match well with macroscale experimentation and FEA based on point loading perpendicular to the cantilever end. Several potential sources for the error in the contacting cantilever FEA used in the present study were examined. Reproducing the previous point-load FEA produced good agreement with the analytical model, indicating that the newer FEA is not intrinsically a source of error. Furthermore, mesh and cantilever aspect ratio showed no significant effect on the error. Therefore, the error was most likely due to implementation of the contact boundary condition in the present FEA model. From this, it is anticipated that FEA using the contact condition may imply a 10% deviation from analytical and experimental results.

### Misalignment and Self-Alignment

The force and bond strength analyses above assume that the interlocking structures are perfectly aligned. When attempting to join interlocking structure arrays with one another, it would be reasonable to assume that there would be some deviation of the positioning of the chips from the ideal location. To assess effects of any deviations from this ideal, the model was modified to include a translational misalignment factor μ, whereby the amount of deviation from the ideal center would factor into the amount of force holding the cantilevers together. This factor is important to the performance of the structures and helps in understanding the requirements for the precision of equipment needed to assemble devices. For joining methods such as epoxy and solder this factor is not as important as a poorly misaligned chip will still function the same, whereas with these periodic structures, misalignment could have a drastic effect on the performance.

Even small translational misalignments may consume a large fraction of the cantilever interaction lengths, leading to significant deviation from the perfectly aligned model. Other misalignments are less important, and other design factors such as the specific shape of the cantilevers, pitch, material thickness, residual stresses, etc. all play a role in the strength of system and relationships among these are considered throughout this disclosure. The implementation of fabricated structures in device assembly depends on the resilience to rotational and translational misalignments between joining surfaces, which affect the final assembly and have the potential to determine whether or not interlocking structures are a viable solution towards heterogeneous integration. The joining mechanism operates through out-of-plane motion, therefore out-of-plane translational and rotational misalignments are accommodated through the joining mechanism. For the analysis presented here, these are not limiting factors to the viability of the mechanism. In-plane rotational misalignment is also not a significant factor for initial design considerations. Rectilinear objects such as microchips can be rotationally aligned to a good degree of accuracy through even simple techniques such as contact with a flat surface. Furthermore, the rotation giving a 10 μm misalignment at the edge of a 1 cm² chip is only about 0.11°[=tan⁻¹ (10⁻⁵ m/5×10⁻³ m)]; this is not enough to significantly modify the cantilevers from basic rectangular geometry. Across an array of interlocking structures, small rotational misalignments would manifest locally as translational effects on the contact force, with only minor effects due to small rotation of the contacting cantilevers. It should be noted that any large rotational misalignment that would cause any of the structures to not align would mean the structure as a whole could not be inserted or it means damage to those structures.

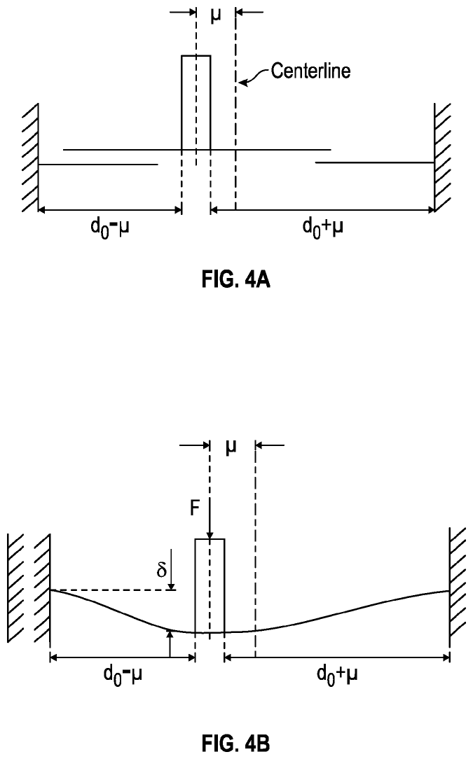

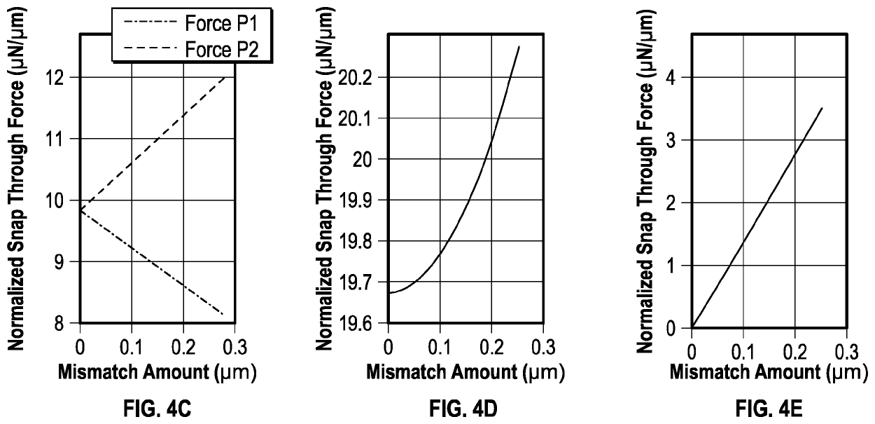

A diagram of in-plane misalignment can be seen in FIG. 4. The original formulation of the maximum bonding strength can then be modified to account for the translational mismatch. As shown in FIG. 4, the mismatch is quantified as a single value u. This results in the interaction distance between two cantilevers to either grow or shrink the amount u. The snap-through force for two pairs of cantilevers on the same interlocking structure with some misalignment can be found with Eq. (4). The maximum bonding with misalignment one pair will slip before the other, at which point the entire structure will snap through.

$${P}_{m} = \frac{0.4 \; 17 EI}{{( {L}_{o} + μ )}^{2}} + \frac{0.4 \; 17 EI}{{( {L}_{o} + μ )}^{2}} \qquad ( 4 )$$

$${σ}_{m} = \frac{0.417 NEI}{{A ( {L}_{o} + μ )}^{2}} + \frac{0.417 NEI}{{A ( {L}_{o} + μ )}^{2}} \qquad ( 5 )$$

From FIG. 4D the net maximum bonding strength increases as misalignment increases. It should be noted that percent change is relatively small and the figure has been drawn to enable visualization of the relationship. The net horizontal force also increases as the misalignment increases, as depicted in FIG. 4E, which suggests that there is an inherent self-alignment behavior where the chips will be pushed towards the ideal center position.

Periodic Array Designs with Interlocking Cantilevers

### Design Implementation for Reworkable Interlocking Structures

As mentioned previously there is a balance among the beam parameters for the structures to prevent permanent deformation but also maximize bond strength. Under loading, the bending stresses may quickly exceed the yield strength of the material, becoming permanently deformed, thus making it unsuitable for reusable attachment.

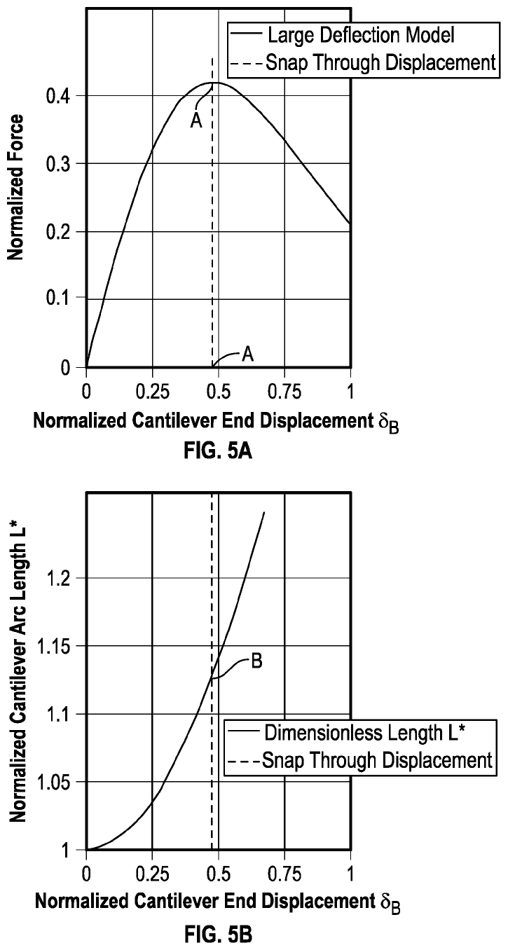

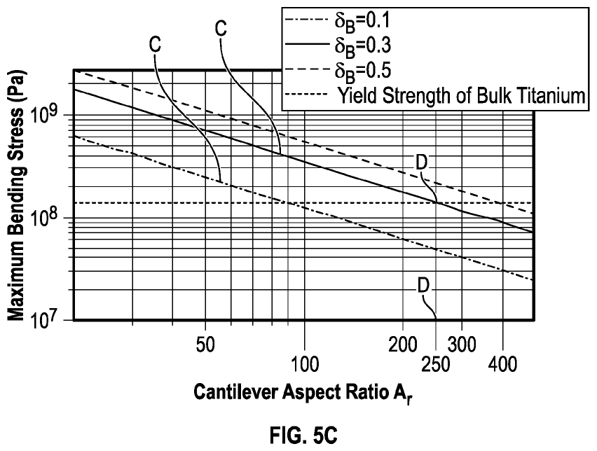

Design begins by first selecting a desired or predetermined force to displace the (compliant) members or cantilevers. In the large-deflection analysis above, it was assumed that the cantilevers would always be sufficiently long that the cantilevers would experience the peak nondimensional force of 0.417. Selecting a nondimensional force before reaching the peak will give similar performance with less deflection and internal stress occurring. In FIG. 5A this is shown with label (A) where a snap-through displacement is selected at 0.3, which produces a snap-through force of 0.36, this is nearly 80% of the maximum, but importantly necessitates only 63% of the displacement required for the peak force.

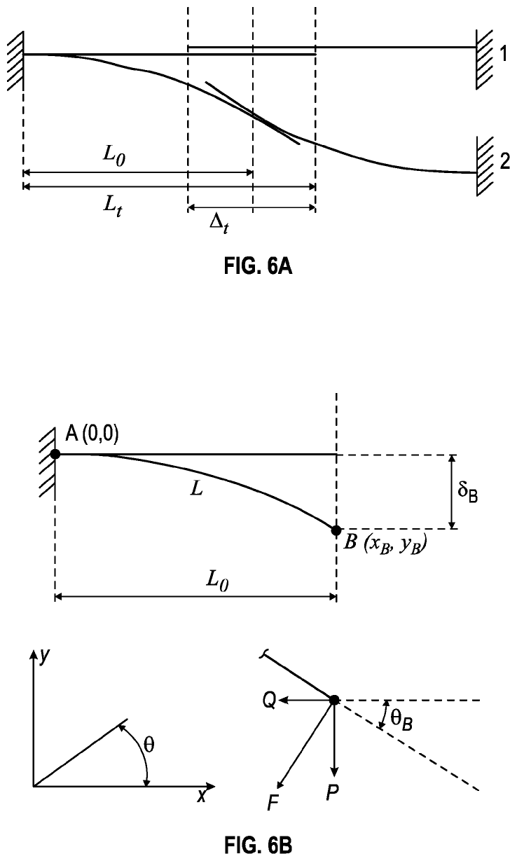

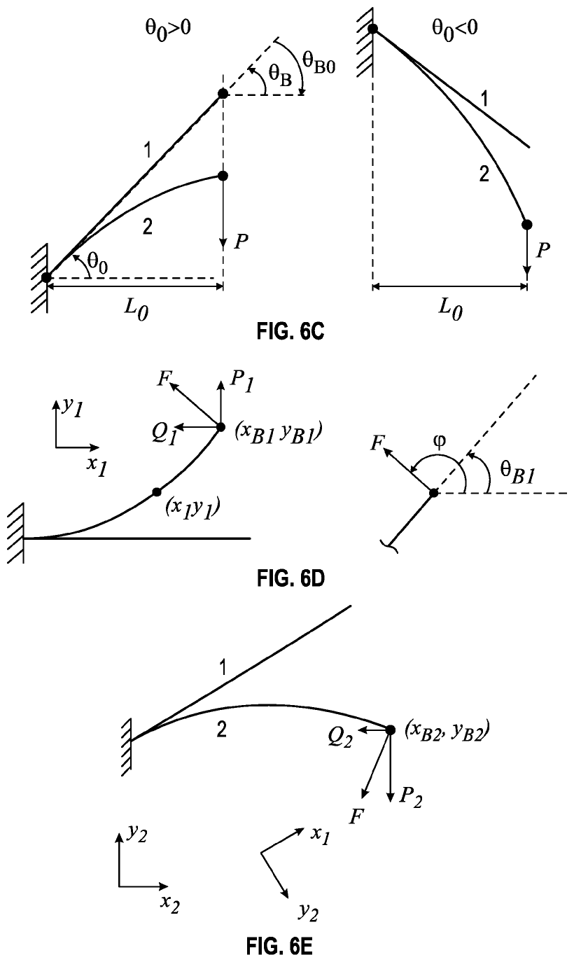

A new nondimensional term L*=L/L₀ is then introduced, which is the arc length L of the beam from the anchor point to the loading point, as drawn in FIG. 6, divided by the horizontal distance L₀ of the loading point to the anchor point. Another nondimensional term Aᵣ=L/t is introduced; this is the aspect ratio and is defined as the dimensionless measure of the total cantilever length L (which is defined by the arc length at snap-through) to its thickness t. This term is important for further analysis and becomes one of the most important parameters that can determine many parameters in the design.

Using FIG. 5B, L* can be found with the deflection from FIG. 5A, as indicated with label (B). Next, Aᵣ can be found using FIG. 5C. Here, plots of the maximum material stress at given displacements as functions of Aᵣ are plotted. These lines are Eq. (6) evaluated at the end angle θ_{B} at a given dimensionless displacement δ_{B}. In FIG. 5C these lines are shown by label (C).

$${σ}_{b} = {\frac{E f}{2 {A}_{r}} [ sin ( {θ}_{B} ) ]}^{\frac{1}{2}} \qquad ( 6 )$$

The yield strength of the material is plotted as a horizontal line. At the intersection of the stress plots (C) with the yield strength, the minimum Aᵣ is obtained. Selecting an Aᵣ lower than this value will result in the bending stresses exceeding the yield strength and will result in permanent deformation of the compliant member structures.

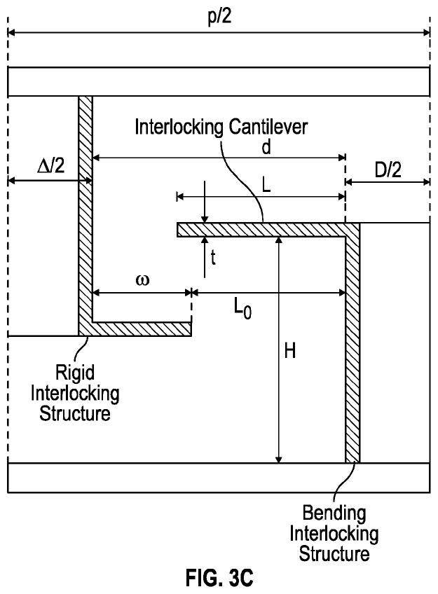

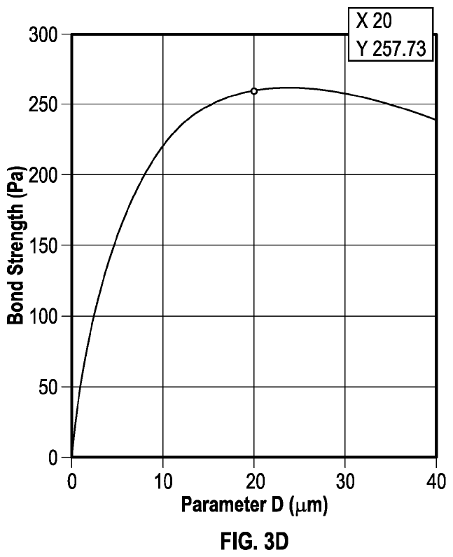

The aspect ratio constraint interacts with constraints of lithography and fabrication processes to define the geometry for a repeating unit in an array of interlocking cantilevers, illustrated in FIG. 3. Geometric parameters in the unit cell are D, Δ, ω, L, and L₀, where D is the width of the pillar that suspends the cantilevers in free space, Δ is the width of the rigid pillar (here set equal to D, for simplicity), ω is the length of the rigid cantilever that extends from the rigid pillar. Unit cell pitch ρ=2(L₀+ω+D) is determined by the sum of other parameters as shown in FIG. 3C.

An optimal pillar and beam width D can be obtained by plotting interfacial strength σₘ as a function of D, Eq. (7), FIG. 3D. Doing so will result in a graph that peaks at some value of D, then decrease towards 0 as D continues to increase. The peak of this graph is the maximum possible bond strength for the given parameters. Following these steps, the optimal interlocking structure geometry is obtained.

$${σ}_{m} = \frac{{C}_{1} {EDt}^{3}}{3 {{L}_{0}^{2} ( {L}_{0} + ω + D )}^{2}} \qquad ( 7 )$$

In one example, titanium may be used as a fabrication material, due to compatibility with common materials in microelectronics coupled with high stiffness and high yield strength. With δ_{B}=0.30 and corresponding snap-through nondimensional force C₁−0.36, L* is then 1.05 and Aᵣ=250 (FIG. 5C) to maintain operation under elastic behavior. Applying Eq. (7) with the parameters from above, and selecting an ω value of 4 μm, D is selected to be 20 μm and leads to a ρ of 42 μm. This configuration then leads to a maximum bond strength of 250 Pa as shown in FIG. 3D.

It is clear from this analysis that designing interlocking structures that remain within the elastic regime of its material will lead a low-performing material. Pure elastic operation is required of patterned surfaces that can be separated and reattached repeatedly, but this comes at the price of adhesion strength. The condition of reworkability can be preserved if the die bearing the compliant cantilevers is afforded some plastic deformation and treated as a single-use component. In this case the surface of patterned rigid structures enables attachment, removal, and replacement of components.

Following the design and optimization strategy above while allowing some plastic deformation, a design for interlocking flat cantilevers shows the possibility of significantly better performance. First, L and L₀ are selected to be 10 μm and 8 μm, respectively. This gives L*=1.25, which means it will reach the maximum C₁=0.417 and Aᵣ=100. These design parameters feed into the relations above all to generate the resulting parameters in Table 2, which are illustrated as the specific models in FIGS. 3A and 3B. These parameters produce a snap through force per cantilever of 0.81 μN, which leads to a bond strength of 6.3 kPa, which is a theoretical maximum comparable to the performance of commercially available hook and loop materials. This shows that these micro interlocking structures have great promise in improving integration methods of chips, but more work is required to better refine their design through improved modeling of plastic behavior coupled with physical testing of the metallic films that will comprise these structures.

### Design of Interlocking Arrays of Non-Flat Interlocking Cantilevers

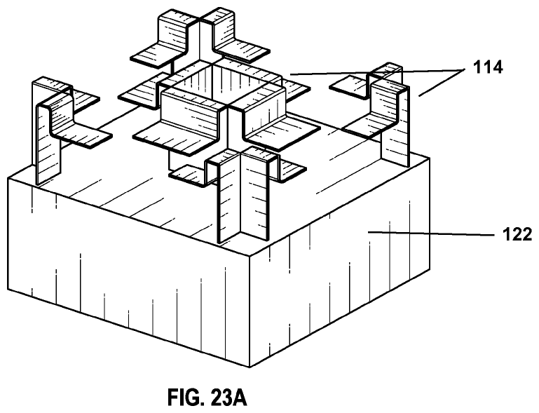

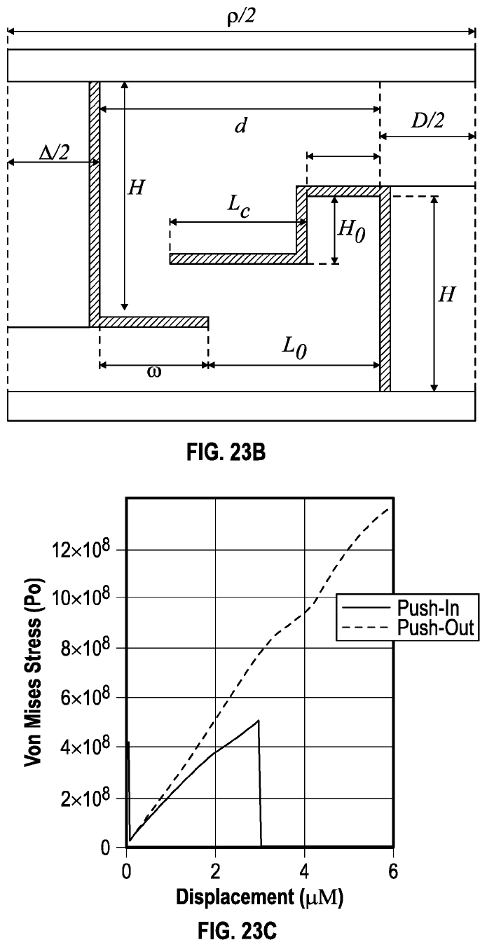

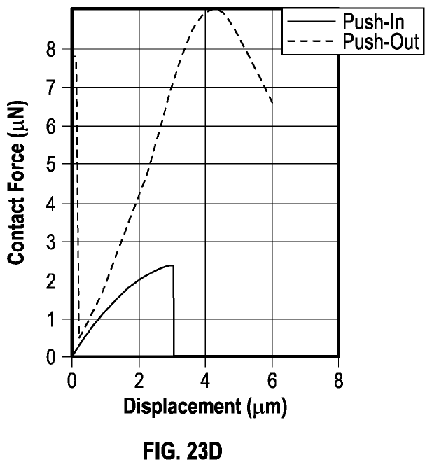

While exploring the mechanical behavior of design variations and seeking to reduce internal material stresses, force asymmetry was observed in interlocking “L” shapes similar to FIG. 3C while allowing compliance in the vertical support of the compliant cantilever. Unfortunately, the result was opposite of ideal for solving the present attachment problem: “L” shapes created high insertion force and low retention force, with corresponding high and low probabilities of exceeding the yield stress. It was hypothesized that this result could be applied to improve performance by flipping the “L” structure and attaching it to a rigid support; this resulted in a concept for a non-flat cantilever design. A model of the repeating unit cell of the proposed design can be seen in FIG. 23A. Finite element simulation confirmed that the added bend allows a low push-in force, and relatively higher force required to separate the components. For implementation in a specific design, a rigid permanent structure is again provided similar to above. With the added shape it is necessary to include additional parameters for design, seen in FIG. 23B and specified in Table 3 (below).

The performance of this design was evaluated with FEA, under pure elastic conditions. The maximum von Mises material stresses are shown in FIG. 23C. Plastic deformation is expected to occur as the yield strength of titanium is 140 MPa is exceeded quickly. The maximum force required to interlock a pair of cantilevers was 2.5 μN, and to separate required a force of 9 μN, FIG. 23D. This corresponds to push-in and pull-out strengths of 8 kPa and 29 kPa respectively, higher than the maximum 6.3 kPa pull-out strength found earlier for arrays of simple flat cantilevers. This design is promising as it gives potentially high retention strength in a reworkable design, but more optimization can be explored and is contemplated by the instant disclosure.

### DISCUSSION

As discussed, traditional methods of joining chips such as epoxy and solder can be problematic because of material cleanup, failure under thermal cycling, and reworkability requiring elevated temperatures or chemical solvents to remove the bonding material. Mechanically compliant attachment presents the potential for die to expand freely without creating high thermal stresses that may cause failure of the joint. Electrical connections may also be potentially made using these structures, allowing techniques such as wire bonding to be avoided, reducing packaging complexity and potentially improving performance of devices such as RF devices which operate at high frequencies.

The analysis and design efforts described herein support the potential for compliant mechanical die attachment systems, but consideration of the internal bending stresses in the cantilever material is critical for successful design. The yield stress is quickly exceeded for most materials; designs which rely on purely elastic bending may be expected only to have weak performance. Additional work performed including plastic deformation and other considerations such as fatigue studies and non-flat or curved designs is discussed in the following description in addition to the further design optimization performed through sensitivity analysis and virtual design-of-experiments modeling considering material and geometry variability. Interlocking cantilever array metamaterial attachment systems show promise for mechanical connection, but further studies can be performed to show acceptable electrical and thermal performance. In RF applications, it must also be shown that they can outperform other methods for electrical connections, and that signals do not degrade and experience little to no interference.

The challenge at hand is to improve the performance of the mechanically compliant attachment to match more permanent attachment methods. Exploration of different materials which can sustain large displacements without permanent deformations is one way that performance may be increased. For example, certain formulations of shape memory alloys such as Nitinol display hyper-elastic behavior, where the elastic region of the material is much higher than in typical engineering materials. To reduce the bending stresses one approach is to process the films such that the sharp corners will be smoothed out into curves. Once the interlocking surfaces have been joined, another concern is the free movement of the chips, i.e., whether the joint experiences any “play”. To stop this free movement, the cantilevers can be designed so that their lengths are longer than the interaction distance D. This would imply the cantilevers would always be in contact with the opposing pillar.

The impact of interlocking structures on nanoscale and microscale designs will be to enable greater interfacing and adaptability of sensors within microsystem and nanosystem packaging. It could be possible to scale this technology down from the microscale to the nanoscale, possibly even to atomically thin films such as 2D nanomaterials like graphene or boron nitride. With reduction to the nanoscale, surface effects such as van der Waals bonding and cold welding arise and may require consideration in design. Other areas which can be explored include the mechanisms of load, phonon propagation, electron transfer, and scaling effects which can affect larger systems.

### Initial Observations

Mechanically interlocking structures present a promising technology for heterogeneous integration. The ability to remove microdevices from larger assemblies has the possibility to make micro devices simpler to service and reuse when prototyping or when replacing dead components on a final product. The present disclosure explores the elastic constraints on design of arrays of mechanically interlocking cantilevers and describes examples of forming complementary metamaterial surfaces for mechanical adhesion. Interlocking structures with flat cantilevers may have a theoretical bond strength up to 6.3 kPa, which is significantly lower than the theoretical bond strength of the proposed structures with non-flat cantilevers which require about 8 kPa to join chips, and require about 29 kPa to separate them. Applications in RF and reworkability two main areas where this technology provides the most distinct advantage over current state-of-the-art. Designs which operate in the purely elastic regime may allow reuse at the cost of low performance. If plastic deformation is allowed to occur on the interlocking surface supported on a replaceable component, the performance may increase significantly to the point of being competitive with other surface bonding technologies. Some considerations with this technology are low bonding strengths, and accommodation of plastic deformation from internal stresses during die attachment and in modeling. These considerations will be discussed in detail in the subsequent sections of this disclosure.

TABLE 1
Specifications for die attachment

| Property | Performance Targets & Comments |
|---|---|
| Adhesion | Pull strength target ≥10 MPa (~10% of standard |
| Pull strength | epoxies) |
| Shear strength | Pull strength refers to a force perpendicular to the |
| | substrate, and shear is parallel to the substrate |
| Alignment | Misalignment tolerance large enough that the chips |
| Translational | can be pushed together easily |
| Rotational | Tolerance ≥3 pm |
| Force Asymmetry | Reworkable joints require symmetric forces |
| Ratio | Easy attachment and strong retention strength |
| (Insertion | require strongly asymmetric forces |
| Force:Retention | With flat design, push in strength will be the same |
| Force) | as pull out |
| | Permanent joints should require force to separate |
| | chips be higher than force to join them |
| Thermal Tolerance | Must be able to operate at 200° C. without |
| | significant loss in adhesion strength |
| Electrical Contact | Design will conduct electricity without significant |
| | increase in resistance and with little interference |
| | from RF |
| | May be used as connections to periphery devices |
| | and replace traditional wire bonds |
| Rigid Connection | Once chips are joined there is no allowed movement |
| | between them |

TABLE 2
Design parameters for interlocking unit
cell with flat cantilevers (FIG. 3C)

| L | 10 | μm |
|---|---|---|
| L₀ | 9 | μm |
| Aᵣ | 100 | |
| D | 10 | μm |
| Δ | 10 | μm |
| H | 15 | μm |
| ρ | 40 | μm |
| ω | 2 | μm |

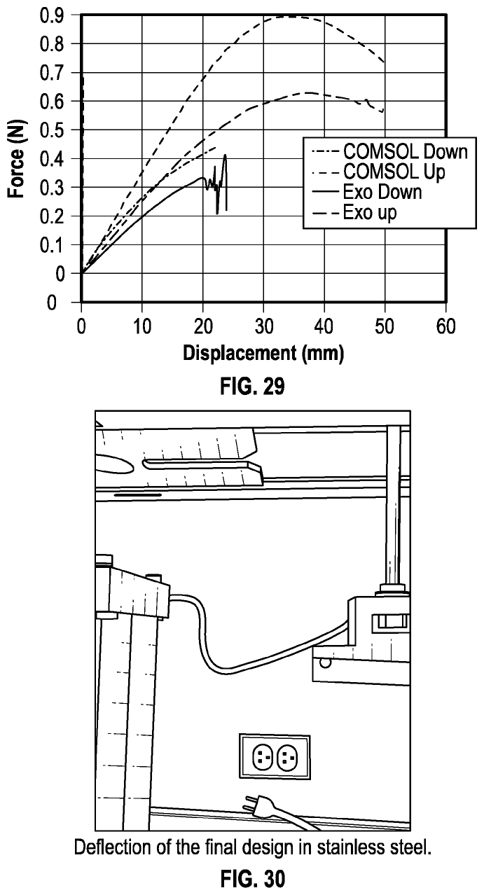

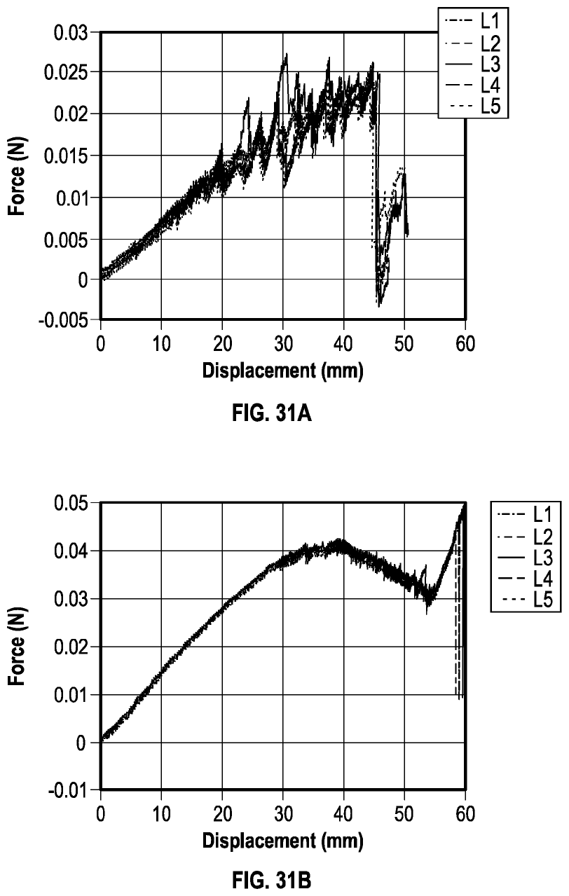

TABLE 3
Design parameters for interlocking unit
cell with non-flat cantilevers (FIG. 29B)

| | | |
|---|---|---|
| L_{C} | 3 | μm |
| L₀ | 11 | μm |
| t | 100 | μm |
| D | 12 | μm |
| Δ | 12 | μm |
| H | 15 | μm |
| H_{B} | 5 | μm |
| ρ | 50 | μm |
| ω | 4 | μm |

### Methods

This section aims to explain the modeling behind the simulations performed in the course of researching examples of the mechanical attachment concepts described herein. In particular, the mathematical models are discussed along with initial experiments. The elliptic integral method and contact force modeling are shown in detail in later sections. Additional designs of interlocking structures are presented along with example novel designs for the system for cantilever-based interlocking.

### Simplified Mathematical Model

The deflection for a flat cantilever beam is based on the Euler-Bernoulli beam theorem. This can be applied to a simple rectangular beam fixed to the wall on the left-hand side at the origin.

$$k ( s ) = \frac{M ( s )}{EI} \qquad ( 8 )$$

Utilizing the small displacement assumption allows Equation 1 to be simplified into

$$δ = \frac{p {l}^{3}}{3 EI} \qquad ( 9 )$$

The force acting on a certain location on a cantilever beam is

$$p = \frac{6 δ EI}{{( {δ}^{2} + {d}^{2} )}^{\frac{3}{2}}} \qquad ( 10 )$$

In this situation the thin film structure will deform further than the small angle approximation allows. Therefore, a new model is required.

### Large Deflection Model

The end goal of developing a model for two cantilevers slipping past each other can be broken down into several smaller sections. The geometry of this model can be compared to the previous small deflection model—as shown in FIG. 6 a cylinder is used to induce the point contact. The cylinder is subject to a load P pushing down on the cantilever. At the contact point there is a reaction force F that is normal to the face of the cantilever. There is also a horizontal contact force Q acting on the cylinder. A second cantilever is introduced on the right-hand side with an overlap defined as Δ₀. The distance from the fixed wall to the point of contact is L₀, and the cantilever length is L_{c}. Both cantilevers share these conditions. The angle from the contact point to horizontal is defined as the variable δ_{B0}. This angle is used as the status of the cantilever. The azimuth angle θ is the counterclockwise angle from the x direction. The variable θ₀ defines the orientation of the cantilever with respect to the x-axis. θ_{B} is the tangent angle of the cantilevers' deflection. θ_{B0} in this model is defined as the angle of the cantilevers tip rotation.

$${θ}_{B 0} = - ( {θ}_{B} - {θ}_{0} ) = {θ}_{0} - {θ}_{B} where 0 \geq {θ}_{B 0} < \frac{π}{2} + {θ}_{0} \qquad ( 11 )$$

Contact length L₀ is an invariant quantity however arc length L and L₀ are variant as the cantilever deflects. The original arc length of

$${L}_{c} - \frac{{Δ}_{0}}{2}$$

varies by a cosine as the direction.

$${L}_{0} = ( {L}_{c} - \frac{{Δ}_{0}}{2} ) cos ( {θ}_{0} ) = L cos ( {θ}_{0} ) \qquad ( 12 )$$

The moment of any (x,y) point along the cantilever can be calculated using the following equation.

$$M = ( - P ) ( {x}_{B} - x ) + Q ( y B - y ) \qquad ( 13 )$$

It is further assumed that the cantilevers are undergoing pure elastic deformation and gravity is omitted. The x component of the load and reaction force is used in future calculations and nondimensionalization. The parameter E is the Youngs Modulus, I is the moment of inertia, κ is the curvature, and s is the arc length. Combining E and I defines the flexural rigidity of the cantilever.

$$P = F cos ( {θ}_{B} ) \qquad ( 14 )$$

$$Q = - F sin ( {θ}_{B} ) \qquad ( 15 )$$

$$M = ( - F ) [ cos {θ}_{B} ( {L}_{0 B} - x ) + sin {θ}_{B} ( {y}_{B} - y ) ] \qquad ( 16 )$$

$$\frac{M}{EI} = \frac{d θ}{ds} = k = \frac{\frac{{δ}^{2} y}{δ {x}^{2}}}{{[ 1 + {( \frac{δ y}{δ x} )}^{2} ]}^{\frac{3}{2}}} \qquad ( 17 )$$

Where M=P(X_{B1}−x)+nP(y_{B1}−y)+M₀ and M₀ is the applied moment. The previous dimensionless force and displacement equations have also been modified for analysis with the results of simulations.

$${C}_{1} = \frac{( \frac{{F}_{c}}{2} ) {L}_{0}^{2}}{2 EI} \qquad ( 18 )$$

$${δ}_{B}^{*} = \frac{d - {d}_{0}}{2 {L}_{0}} \qquad ( 19 )$$

This is a summarized representation of the major results of the elliptic integral method. Due to the complexity of the math required, the analytical model was modeled around purely elastic deflection of the cantilever. For experimental purposes it was further assumed that the bulk material properties were the same in microscale.

### The Importance of Von Mises Stress

The von Mises criterion is used for isotopic and ductile materials to compare against the yield stress. If the von Mises stress is less than the yield point, the material will behave elastically and return to its original position and shape after unloading. If the von Mises stress is greater than the yield stress, it deforms plastically. Parameters such as the yield strength, ultimate strength, Young's modulus and Poisson ratio may be determined through standardized tensile testing. The interaction of two solids is described by contact forces using various models. The two main components of contact are the normal force and the friction force which respectively compose the normal and shear stresses.

### Example Designs

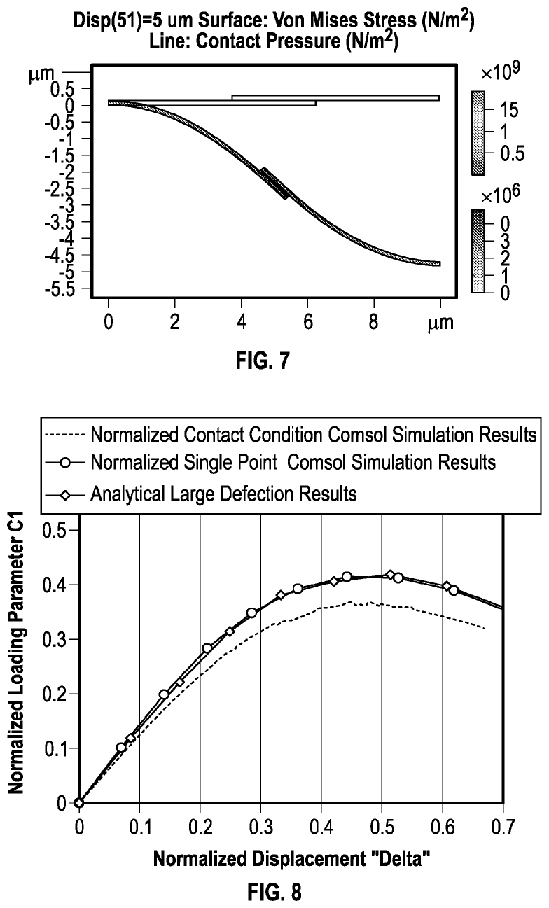

The following designs were developed based on and expanded from the analytical model, design and manufacturing process outlined above. It was a goal to find a design that deforms elastically and plastically under contact. The first design tested was 2 rectangular cantilevers interacting with each other. This led to the simulation in FIG. 7. The next progression was the creation of a L shaped cantilever. Three versions of this design were tested with geometric variations. The first was with 90-degree angle. The second with a 0.5 μm radii, and finally at a 45-degree angle with radii to reduce the stress concentration. The 90-degree variation demonstrated a higher push in force compared to separation force, making it an unsuitable design for the problem at hand. The 45-degree angle variation was unable to be simulated due to a lack of convergence and as such is reserved for future research. These efforts provided a baseline for computational modeling and under contact conditions.

The final design increased the complexity of the design and was an evolution of the first L simulation that added another L on the previous L shaped cantilever design. The reasoning behind this was increase in bends would decrease the stress concentrations at the corners and the base. This is also the design that has the highest possibility of being reworkable. The contact force for the push-in section for the first L design was much greater than the pull-out force (the force to snap through pulling upward in the positive y direction), which was the opposite of the desired results. In response, the L was flipped upside down with the design now suspended in midair. The ideal process would transition from basic simulations to disposable designs to reusable designs. Even suspended it is still feasible to securely anchor the design with additional pillars of photoresist deposited. A summary of all of the designs is shown in Table 4 (below). The final evolution of the design incorporated radii to the cantilevers to reduce stress concentrations. This was determined to be a helpful example or embodiment moving forward as it met the von Mises stress requirements. Each of the design iterations are outlined in further detail in the subsequent sections and a list of final design considerations is outlined in the discussion section.

The experimental and simulation design was incorporated to create an altered design with varied interacting cantilever shapes. It was concluded that the optimal design should be a cantilever design that allows some plastic deformation. This is explained in the discussion section and sections herein. This isn't shown in the simulations as a 2D cross section was used.

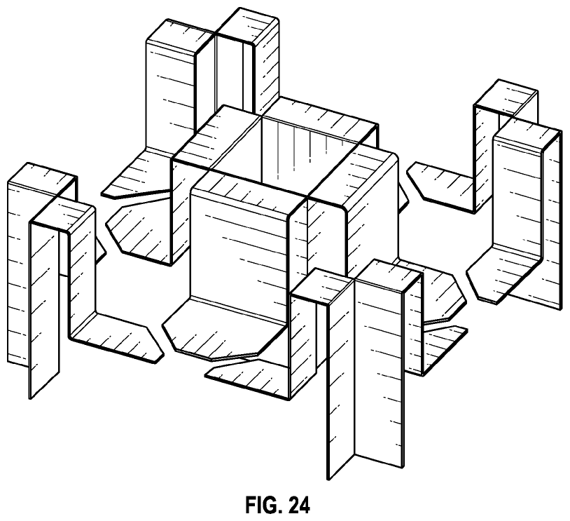

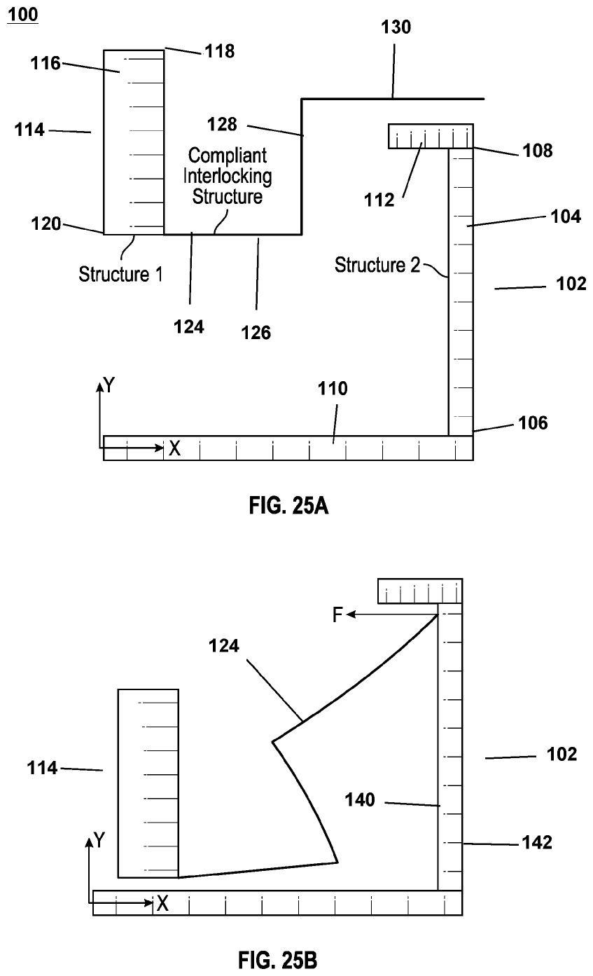

FIGS. 25A-25B show stages of a schematic illustrating how the mechanism (compliant member or cantilever) can interact with the non-deforming structure. The thin interlocking compliant member, which can be a cantilever, can have some plastic deformation and can be made of copper, while the rigid interlocking structure (in some examples) will not deform at all and can be made of gold. The reasoning for this decision will be explained in the analysis and discussion sections.

The final plastic deformation design consists of two rectangle samples joined together with an offset to aid the direction of sliding and deformation. These cantilevers are encapsulated in a box with slits on top for insertion of the undeformed cantilevers. The concept behind this design is to direct the direction of deformation outwards to expand the width and block the gap. These are all non-limiting examples of the design, and similar design and shape configurations are contemplated and included by the present disclosure; some examples shown in the Drawings.

### Simulation Results

This section defines the simulations performed to investigate design variations. The maximum domain probe is used for von Mises stresses and contact forces to determine if the mechanism plastically deformed. Stationary solid mechanics studies were performed. The addition of friction forces was also attempted but also led to a convergence failure. In 2D simulations all meshes were performed at the extremely fine setting. The 3D simulations used the normal mesh size setting to reduce the simulation times. A table summarizing the findings from these simulations is outlined in Table 4.

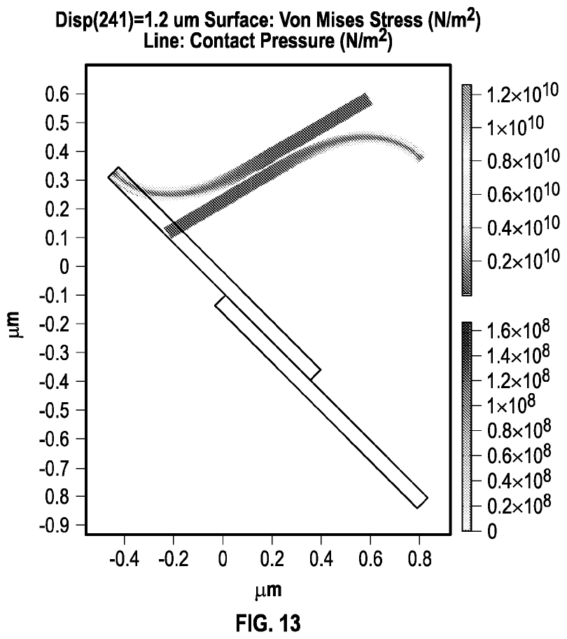

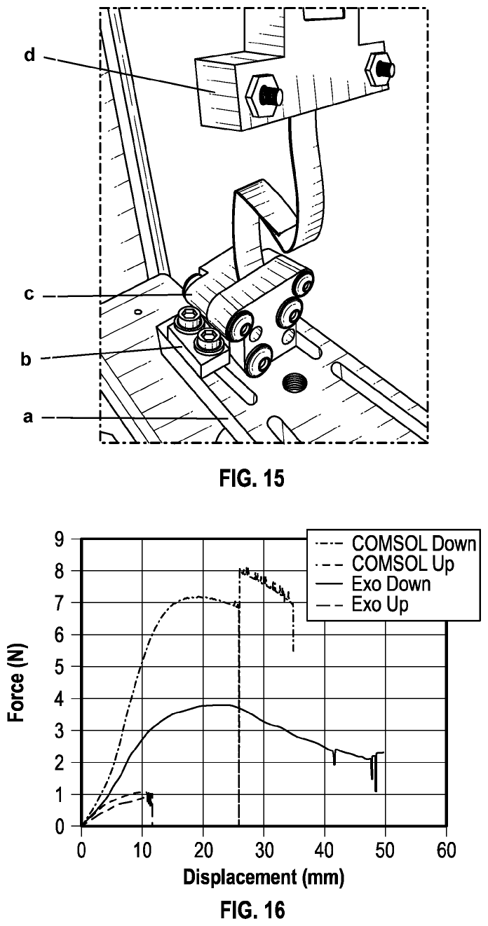

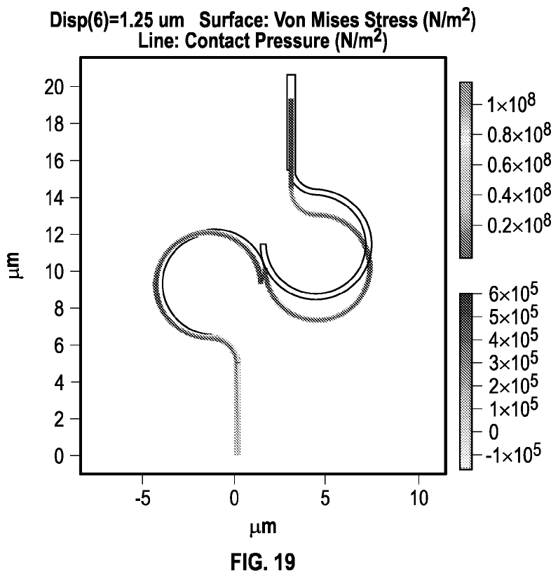

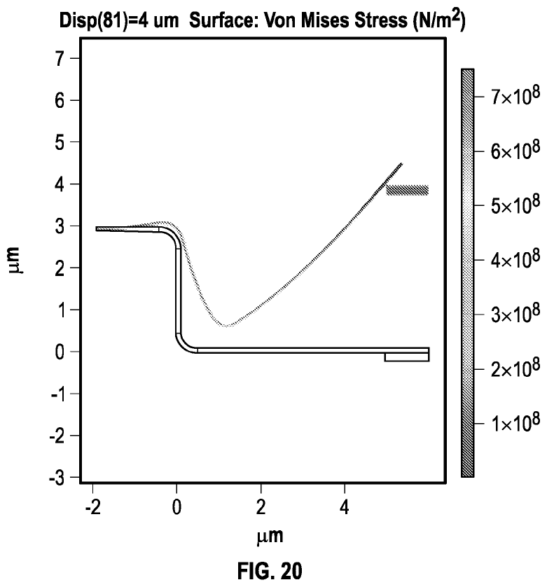

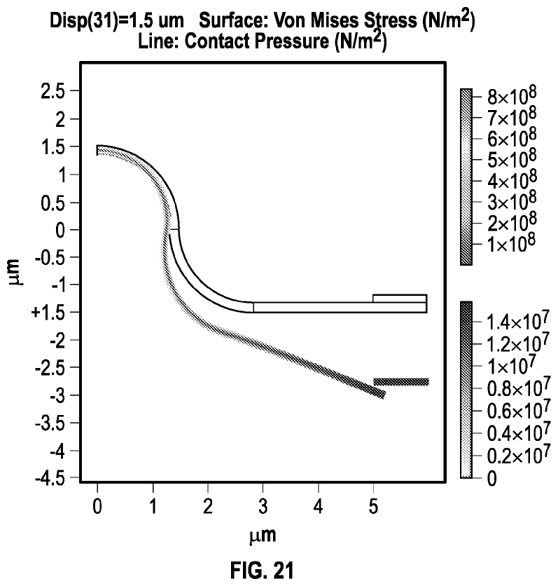

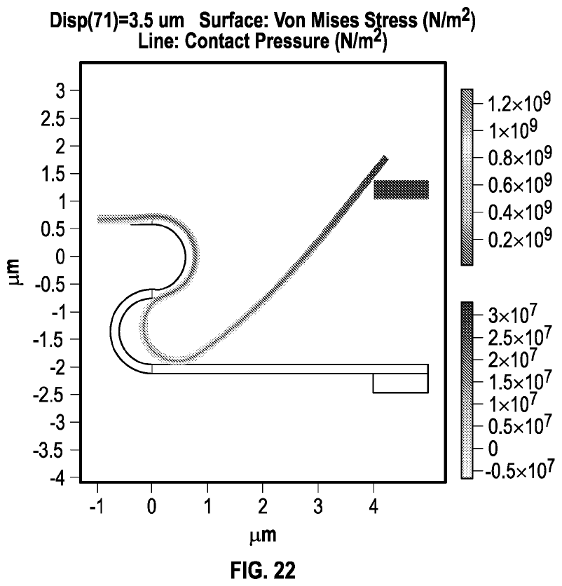

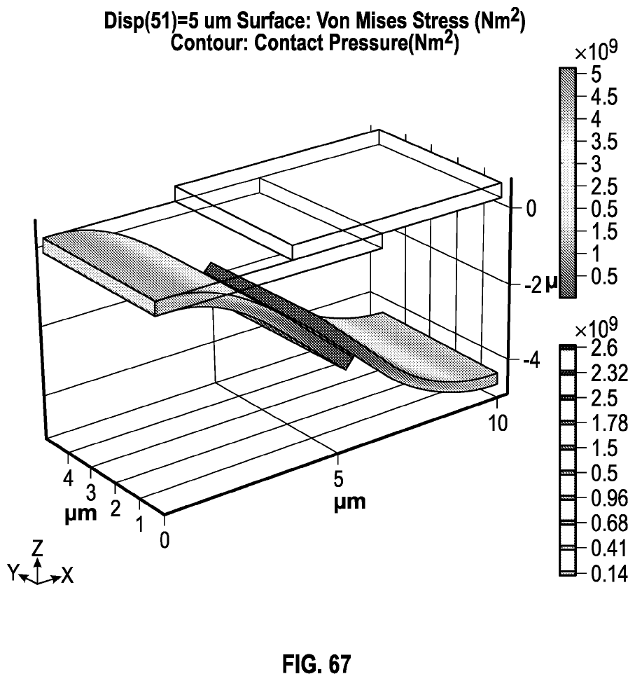

TABLE 4
Summary of designs for reusable attachment mechanisms.

| Design | FIG. | Purpose | Result | Conclusion |
|---|---|---|---|---|
| Flat | FIG. 7 | Set point of comparison | Von Mises stress of | Established baseline stress, |
| Cantilever(s) | | with new designs. | 2.38 FPa, plastic | contact force values and |
| | | | deformation. | basic understanding of |
| | | | | 2D simulation modeling. |
| 3D | FIG. 67 | Learn how to perform | Von Mises stress of | Learned differences |
| | | simulations in 3D. | 2.52 GPa, plastic | modeling and performing |
| | | | deformation. | simulations in 3D |
| | | | | versus 2D. |
| Angled | FIG. 13 | Test angled plates to | Pull out Von Mises | Reinforced notion that |
| Deflection | | replicate undergraduate | stress of 11.6 GPa, | angled cantilevers have high |
| | | testing. | plastic deformation. | contact force ideal for |
| | | | | single use applications. |
| Interacting L | FIG. 15 | Create a design within | Von Mises stress of | Behavior of a high push-in |
| | | the constraints of only | 1.66 GPa, plastic | force and low pull out force |
| | | vertical and horizontal | deformation. | was the opposite of what |
| | | structures. Simplest of | | was desired. Formed the |
| | | created designs. | | basis of the successful |
| | | | | “inverted S” design. |
| Chevron | FIG. 19 | Evolve design from | Von Mises stress of | Angled cantilevers are |
| | | previous undergraduate | 5.23 GPa, plastic | ideal for single use |
| | | work. | deformation with | mechanisms provided it is |
| | | | high contact force. | possible for the designer to |
| | | | | manufacture. |
| Hook | FIG. 20 | Evolve half cylinder | Unsuccessful | Future work will be done |
| | | design from | simulation. | to determine why the |
| | | undergraduate work. | | simulation failed and how |
| | | | | effectively this shape |
| | | | | functions as an interlocking |
| | | | | structure. |
| Inverted S | FIG. 21 | Inverting the interacting | Von Mises stress of | |
| | | L design to reduce | 428 MPa, plastically | |
| | | push-in force and increase | deforms but lowest | |
| | | pull out force. | of all designs. | |
| | | | Deemed a success | |
| | | | due to the | |
| | | | improvement in | |
| | | | increasing the pull | |
| | | | out force. Also | |
| | | | successful as some | |
| | | | of the design | |
| | | | considerations were | |
| | | | implemented to | |
| | | | improve upon the | |
| | | | interacting L design. | |
| Inverted S V2 | FIG. 22 | Increase radius and arc | Von Mises stress of | Increased stress |
| | | length from “inverted S” | 1.99 GPa, plastic | of mechanism, further |
| | | design. | deformation. | optimization required. |
| Inverted S V3 | FIG. 23 | Further increases arc | Von Mises stress of | Sticking with the first |
| | | length to reduce stress. | 1.41 GPa, plastic | “inverted S” design as it |
| | | | deformation. | had the lowest stress. |

In a testing/simulation user interface, the maximum contact force in the y direction over the entire domain was determined over the displacement interval. The maximum von Mises stress was also used to determine yielding. The first note was the 2D simulations resulted in the material plastically deforming despite reducing the thickness. To keep consistency over the simulations and later physical tests an aspect ratio implemented to account for the changes in thickness between materials used in the physical testing. An aspect ratio of 500 was desired but due to the thinness of the material the simulation would fail due to non-convergence. The main concern was the contact condition, which, as mentioned previously, may yield results with an error of around 10 percent. All of these non-converging simulations led to an extremely simplified model that worked but may not be completely accurate. To reduce this the mesh density was increased by decreasing the maximum element size to 0.001 μm. It would be assumed that the probe would show an increase in von Mises stress as well as contact force maximums. The probe showed a negligible difference in both categories which is incorrect to convention. This was a warning sign that the contact conditions may not be accurate. All of these non-converging simulations led to an extremely simplified model that worked but may not be completely accurate. To reduce this the mesh density was increased by decreasing the maximum element size to 0.001 μm. It would be assumed that the probe would show an increase in von Mises stress as well as contact force maxima. The probe showed a negligible difference in both categories which is incorrect to convention. This was a warning sign that the contact conditions may not be accurate.

In FIG. 8 the max C1 of 0.4161 occurs at a delta of 0.5 in both the single point and analytical model. The black dotted line of the contact condition exhibits a similar C1 maximum at 0.5 but the C1 value itself lacks. This also confirms an error in the contact condition of the simulation.

A single cantilever of the same dimensions was used in isolation to test a point load. A point load replicating the theoretical maximum force in the y direction was applied to the right end. The distance from the base of each cantilever is fixed so the contact length varies throughout the simulation. Additional surface probes were initially used in 0.1 μm increments. However, the displacement field of the points were inaccurate as they described the total displacement rather than the individual displacement of that specific point. Looking back at the simulation showed a distinct peak in contact force at a delta of approximately 0.5. It was rationalized that rather than trying to match the displacement exactly, the maximum peak and the corresponding delta will be matched.

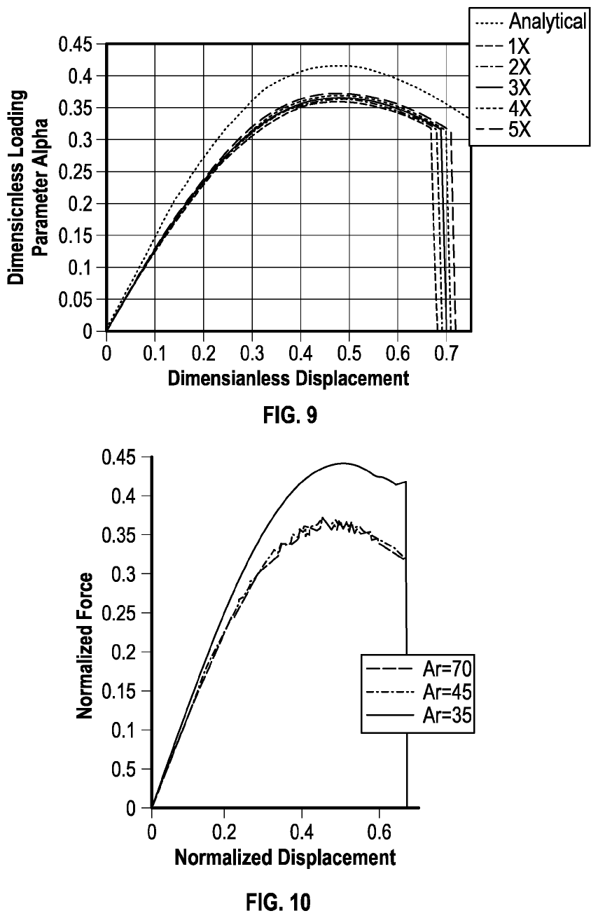

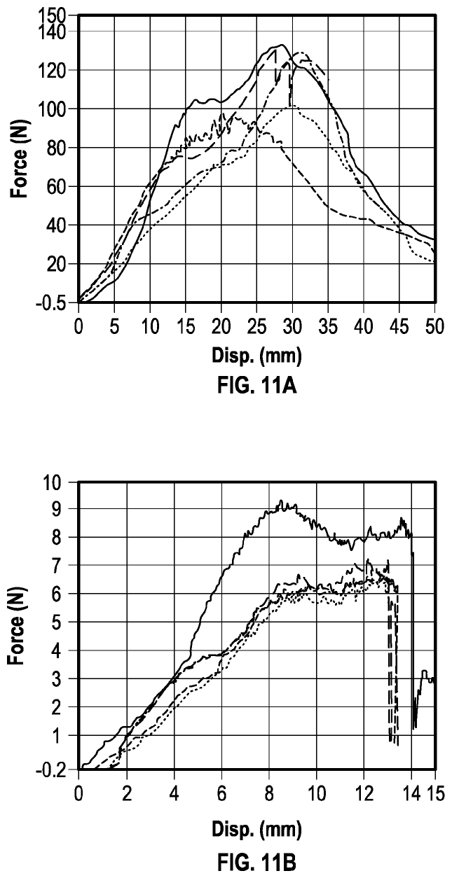

Previous FIG. 8 only demonstrated the non-dismensionalized force for a single thickness with two interacting cantilevers. FIG. 9 plots four other thicknesses compared to the analytical model testing the effects of the thickness. A model with 1× thickness had a non-dimensional force of 0.361 while the 5× thickness had a 0.372 non-dimensional force. Copper was used as the material designed to the specifications of the 100×100 μm with two interacting cantilevers.

Throughout the simulations performed there were also large overshoots in the data as well as shown in FIG. 10. This is the result from further changes to the aspect ratio of the 100×100 μm.

From these two simulations it can be concluded that the cantilever-on-cantilever simulations tend to undershoot the model while a single deflecting cantilever in contact with a vertically moving block can both undershoot and overshoot the model. From this point forward the models were only used on interacting structures to simplify testing and reduce testing errors.

Baseline Simulation with Two Cantilevers

A baseline was established with two rectangular 2D cantilevers to the corresponding specifications. A fixed constraint was added to the left edge of the left-hand cantilever. Form assembly was used to create the contact pair between the two cantilevers. This created a contact pair definition. The search method, mapping method, and extrapolation tolerance were set to their default settings at fast, deformed configuration and 1e-4 respectively. Only the mesh density was set to fine due to the extended time to perform all of the simulations. The same process was used for the progression to 3D cantilevers with the face instead of the edge constrained. A parametric sweep with displacement increments of 0.1 um were used. This increment was reduced in the case of an unsuccessful simulation.

Prescribed displacements were used in place of boundary loads due to non-convergence. This is due to the simulation being under constrained with only the right edge of the right cantilever experiencing the boundary load.

A comparison between the mesh densities along with mesh shapes was also made. It was concluded that both factors led to negligible disparities in the von Mises stress and contact forces. Discretization of the displacement field also showed negligible results changing from quadratic Lagrange mesh to quintic Lagrange mesh. Default solver configurations were also used with the addition of geometric nonlinearity. The von Mises stress for two-cantilever interaction was solved to be 2.38 GPa, implying the presence of plastic deformation. Therefore, it was determined that as a one-time use mechanism, it didn't meet the requirements.

### Baseline Simulation in Differing Unit Scales

The first simulation conducted was a test run in centimeter scale to gain familiarity with the contact condition. The scale was then reduced to the micron scale. In all simulations the displacement increment was 0.1 μm or cm and decreased if the simulations failed. The simplest deflection model is to have a single cantilever with a block displaced downward. This is a simple enough simulation that can be replicated with physical testing with comparisons to the non-dimensionalized forces. In the 3D simulation the maximum von Mises stress exceeded 5 GPa.

### Angled Deflection

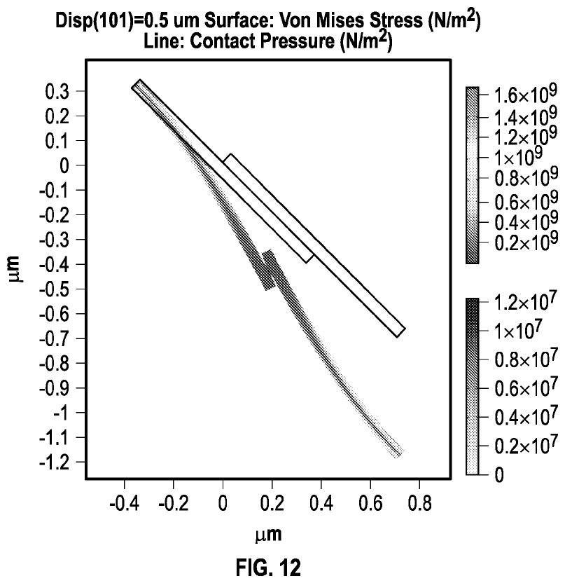

Further work pursued a progression in design to more complicated structures. The simulation in FIG. 12 was a test of the manipulation of the object in the sketch environment. This simulation also neglected any friction forces. This model also showed a high probability plastic deformation with a stress of 1.1 GPa exceeding the 33.3 MPa yield stress of copper. The dimensions were shrunk in consideration of how tall the supporting pillars would be if the cantilever length was the length in the 3D simulation.

An additional simulation was performed on the bottom cantilever being pulled upward in the positive y direction as shown in FIG. 13.

The push-in von Mises stress exceeded the yield stress of copper, implying that the copper would plastically deform, so it was expected that the pull-out stress would also do so. The measured maximum von Mises stress was 11.6 GPa. The takeaway from this experiment was the large contact forces in the x and y direction. A surface maximum of the contact force in the x direction registered a force of 41.5 μN and a y component of 3.27 μN. This compares to the flat contact force of 0.581 μN in the x component and 0.731 μN in the y component. From this simulation it can be concluded that angled cantilevers are preferred for single use applications due to the larger contact force components compared to the original flat cantilever design.

### Interacting L

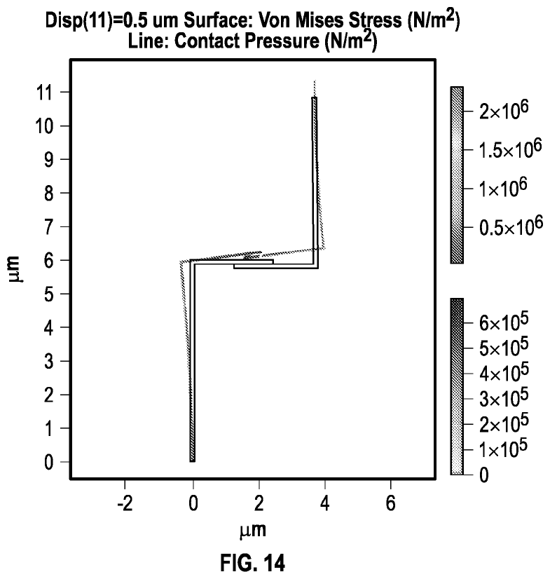

The first two simulations performed created a general understanding of how to use the testing/simulation program and how to perform post simulation data processing. The next step was to create a simplified interlocking structure. A simulation of an L-shaped structures was created interacting with a rectangle undergoing a displacement. This was done as there were initially errors on the full simulation of two L-shapes interacting. After decreasing the displacement increment to 0.005 μm and refining the mesh the simulation successfully ran in FIG. 14.

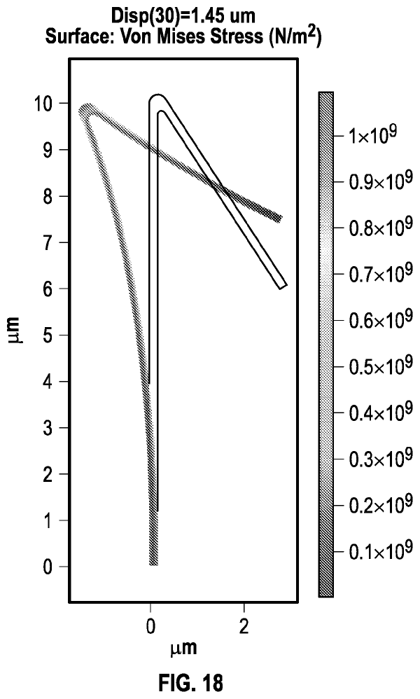

The push-in von Mises stress registered at 1.66 GPa. Therefore, this mechanism would plastically deform during the interlocking assembly. After this first test this mechanism didn't meet the requirements. The pull-out stress topped out at 395 MPa which also plastically deformed. The von Mises stress and displacement in FIG. 14 was over twice the pull out stress and displacement. This wasn't the desired effect of the mechanism. As a result, the next iteration combined the angle simulation with the L to create FIG. 18. This simulation performed the opposite of the desired interaction characteristics. This simulation provided a large push-in force and a smaller pull out force. However, this design was successfully modified to be the basis of the “inverted S” design in FIG. 20.

### Chevron

After the 100 by 100 μm simulations, other designs with increasing complexity were tested. The next progression was cantilevers interlocking at a set 45-degree angle shown in FIG. 18. Maintaining the same contact length from the flat 180-degree simulation was difficult due to the way sketches are drawn on the testing/simulation program. The rectangle was able to be drawn, but the point of rotation needed to be specified along with accounting for the thickness.

Adding the second cantilever was also difficult due to the coordinates of the point of rotation acting as the point of movement. It was also discovered that the form assembly contact condition also favored two faces that were already in contact with each other. This design was reserved for later research due to the yield stress exceeding that of copper and the difficulties in manufacturing an angled cantilever.

### Hooks

The contacting double-hook design was created out of inspiration from contacting half cylinders. The hook design successfully went through the push-in simulations. A maximum stress of 469 MPa was recorded. The pull-out simulation however was unsuccessful due to non-convergence. The follow up simulation reduced the opposing cantilever to just a quadrant of the same radii and thickness. However, upon contact with the stationary hook, the simulation still failed to converge. The next attempted fix was a changing the direct solver to an iterative solver. All iterative solvers were attempted with set boundary conditions failed to converge.

The following simulation eliminated the vertical beam which reduced the amount of undefined edges. The continuation method was used as well as reducing the max mesh element size from 0.075 μm to 0.05 μm but the simulation still failed with the incomplete matrix error. It was difficult to add more boundary conditions as there should be only one fixture point at the base of the geometry. The final iteration resulted in the second reduction in geometry. The simulation still failed so the thickness was increased from 0.3 to 0.35 μm. This design was reserved for later research.

### Inverted S

The final design was created by rotating the L design by 180 degrees. Since the design gave the opposite of the desired stress and displacement behavior. This “inverted S” design tested if flipping the model would flip the contact behavior too. This is defined as the push-in force being smaller than the pull-out force. Before performing the simulation, the floating base needed to be addressed. Chemical vapor deposition or photolithography are two possible methods of creating the pillars to suspend the new design. After the first simulation it was determined that radii are needed to reduce stress concentration in the corners. Utilizing a 0.5 um radius the created design is shown in FIG. 20. Like previous simulations there was fear of the simulation failing. To counteract this a rectangle block with a length the same as the interaction length between the two cantilevers. Creating the 6 um long flat section allowed for a simple contact condition that yielded a successful simulation. The only flaw of the simulation was the contact between the left-hand corner of the displaced rectangle and the design. It was expected that the stress would be lowest for this mechanism due to the thickness of the material, the incorporation of radii. Turning the L upside down and adding an additional length would create the desired low push-in force and high pull out force. A maximum von Mises stress of 4.28*10⁸ Pa at a max displacement of 2.25 μm was measured from the testing/simulation program. While this still plastically deformed it was the lowest stress seen in a design and warranted physical testing.

Building upon this first iteration the radii were increased to 1.5 μm as it was inferred that a larger radii reduced stress. As shown in FIG. 21, there was actually an increase in maximum von Mises stress to 1.02*10⁹ Pa at a maximum displacement of 1.9 μm.

This final design incorporated turning the quarter circle into a half circle. The pull-out simulation had a max von Mises stress of 1.99*10⁹ Pa at a maximum displacement of 4.35 μm.

As FIG. 20 was the best performing design that met the non-yielding requirement more simulations were performed. The next simulation performed was to ensure the middle square pillar section didn't buckle under the gathered contact force in the push-in and pull out forces. This square pillar was designed because of the need to suspend the design in the air. Verification required no plastic deformation within operational loading. Referencing the data from FIG. 20 the max push-in force was around 2.5 μN with a pull out force of approximately 9.5 μN.

A parametric sweep was performed on the structure loaded 1 to 10 μN in increments of 1 μN and applied to the top face in the z direction. The bottom face had a fixed constraint applied to it. Three von Mises stress probes were placed on the structure. The first was a point probe at the corner located at (7.5,−5.0). Another probe was placed on the face along the xz plane where y=−6. The final probe was placed over the entire domain to include the outside and inside faces along with the corners in case something was missed.

The yield strength of the copper is 33.3 MPa which is well above the gathered data. The displacement is also linear and almost negligible as well. If the structure is going to absorb more load an additional sputtering process may be added to reduce the stress and deformation. In conclusion this “inverted S” design was a successful evolution of the interacting L design. It confirmed the initial impression that flipping the L and suspending it in midair with a support pillar would reverse the manufacturing characteristics. The design now has a lower push-in force compared to the pull-out force. This design is also an improvement on the original flat interacting cantilever design because of the increased pull-out force. The design considerations made for this design are further discussed for future designers to use when creating structures like this. Versions two and three featured geometric changes that need future explanations to determine with certainty. There were challenges achieving convergence and repeatability with the versions two and three. This was another reason for choosing design one to physically test. Analysis of the potential for buckling remains a task for future engineering.

### Single Use Mechanisms

One time use mechanisms have been designated as plastic deformation attachment methods. These are mechanisms that were designed to have the highest retention force as possible and accommodate to plastic deformation. These simulations were created as preliminary experiments to give opportunities for future work. Before jumping into designs, it was important to gain an understanding of how plasticity works. Due to the short time frame not all of the features were implemented. Analysis of the potential for buckling remains a task for future engineering. The tangent modulus and hardening function were omitted. The tangent modulus is the slope of a line plotted tangent to the stress-strain curve at a defined point generally outside the elastic region. Assuming this to be zero means the shear stress is constant after yielding leading to a flat nondimensional force curve. Assuming the hardening function to be zero means there is no work or strain hardening within the material. This is defined as increasing the strength of the material as it is plastically deformed. The materials in these simulations are under-going plastic deformation so a hardening function of zero will eliminate any strength gains.

### Experimental Results

This section outlines the physical testing performed to verify the accuracy of simulations. Four experiments of flat cantilevers were created out of 3003 aluminum, brass, thin and thick sheets of copper. Characterization of these samples was performed on a mechanical testing machine. Five inter-action lengths were created for the aluminum, brass and thin copper samples. Three interaction length samples were made for the thicker sheet of copper. The experimental data outlined in this section is the average of five trials performed for each interaction length and compared to simulations. Some of the simulations were pure elastic while the others implemented plastic deformation based on the yield strength. Additional testing was performed on two designs called “interacting L” and “inverted S”. These experiments were aimed to test the accuracy of simulations in the millimeter scale verses physical testing. The experimental data for these two designs is also the average of five trials. A discussion of the “ideal” aspect ratio was created and outlined that maximizing the aspect ratio significantly reduces the bond strength. A testing/simulation program was utilized to quantify the maximum aspect ratio that could be successfully simulated within a one-hour time frame. This provides future users guidance on how large of an aspect ratio can be simulated within a reasonable time frame and the tradeoffs in mesh element size as well as shape.

Verification of Simulations with Physical Testing

The testing apparatuses were designed for the micro scale samples but have since been pivoted to macro scale. The designs have been simulated at the specific macro scale dimensions to verify the simulation. The setup on the simulations were created as closely to the original experiment as possible with the units changed. Material properties were given in the simulation program material library and double checked for similarity with other online resources for alloys. Brass, 302 stainless steel, 3003 series aluminum, thin and thick sheets of copper were used. Titanium and tungsten were also a planned material to be used due to its high yield strength however due to delays in funding, COVID and difficulty in manufacturing the material wasn't used. The physical testing was performed on a Shimadzu AGS-X mechanical testing machine with a 100 N load cell. In FIG. 15 an example of the experimental setup for the stainless-steel interacting L. The plastic clamp (c) in the figure can be exchanged with a different printed apparatus for cantilever experiments so there is no bottoming out on the base (a). Machined mounting block to mount to a (b) and (d) secondary 3D printed clamp to hold the top sample threaded into the load cell.

### 3003 Aluminum Cantilevers

The setup of the first experiment was a replication of the first contact simulation. Al 3003 with a H14 temper was clamped a set distance away from a fixed center piece of polylactic acid (PLA). This distance was defined as the interaction length. Tests were run at 2, 2.25, 2.5, 3, 3.5 and 4 in. The sample length was made to be 1.25 times longer than the interaction length. The tests were replicated in the same scale to test the validity of the contact condition. Each interaction length had five trials. Each of the plotted lines in all of the graphs below are averages taken of the five trials for each interaction length. The samples required minimal manufacturing as the aluminum was purchased in 0.5-inch by 12-inch-long samples. It was expected that shorter interaction lengths would have a lower nondimensional force due to the higher stress concentrations and possible plastic deformation. The increasing interaction length should move the corresponding curves higher as there should be less likelihood of plastic deformation. This first graph compares the experimentally gathered and averaged data to the elliptic integral model. The 4-inch interaction length was the only sample to overshoot the model with a 4.8% maximum overshoot and a minimum undershoot of 27.6%. Both errors were calculated at a dimensionless displacement value of 0.5.

In FIG. 54 Interaction length L1 has the highest force but lowest displacement. This is compared to the fifth interaction length with approximately half of the force but a 60 mm displacement. This set of data follows the expected results as the longer the cantilever is, the lower the expected contact force.

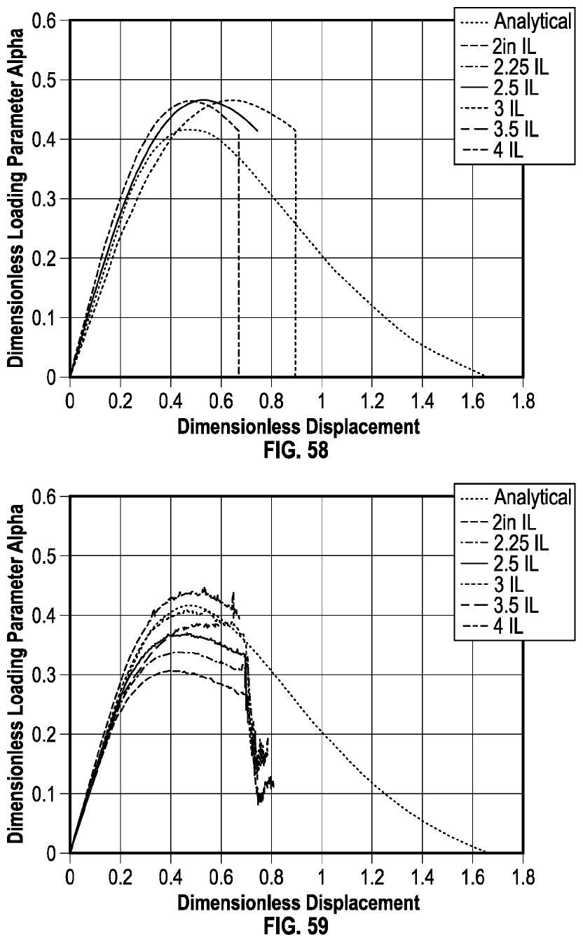

FIG. 58 is the plot of the aluminum physical testing compared to the analytical model. As expected the longest interaction length of 4 inches achieved the highest nondimensional force while the shortest interaction length had the lowest value. A 3.5-inch interaction length aluminum sample was tested under load. This interaction length was the closest to matching the analytical model. This makes sense because there was no visible plastic deformation of the sample after the test.

FIG. 58 is the plot of an experiment performed using the testing/simulation program. It should be noted that while it appears that some of the trials aren't graphed, some of the trials were so close that they appeared to be graphed on top of each other. In this simulation all of the interaction lengths overshot the model by a maximum of 11.3% and a minimum of 3.8%. Just like the previous FIG. 58 these values were calculated at a dimensionless displacement of 0.5.

This first experiment confirms the overshooting of the model from the testing/simulation program compared to the analytical model and the undershooting of the physical testing. Observation of the samples in the mechanical test machine showed some plastic deformation in the smaller samples while the longer cantilevers like the 3.5-inch interaction length aluminum sample experienced almost no deformation. This was highlighted by the lower nondimensional force values in FIG. 59.

### Brass Cantilever

The next material tested was 260 series brass. Five interaction lengths were tested at similar aspect ratios to account for the thickness difference in. These ratios may seem random but they were used to keep in accordance with the aspect ratios determined with the aluminum sample. The length was adjusted as the brass was the thickest material used.

TABLE 5
Detailed information of the brass samples used in physical testing.

| | | Sample | Interaction | Peak |
|---|---|---|---|---|
| | Aspect | Length | Length | Nondimensional |
| Sample | Ratio | (mm) | (mm) | Force |
| L1 | 174 | 44.54 | 35.63 | 0.371 |
| L2 | 193 | 49.41 | 39.53 | 0.399 |
| L3 | 232 | 59.39 | 47.51 | 0.407 |
| L4 | 271 | 69.74 | 55.5 | 0.444 |
| L5 | 309 | 79.10 | 63.28 | 0.512 |

It is observed that the simulation closely follows the model. This was expected due to the increase in the yield strength over the aluminum and especially copper.

Similar to FIG. 58 the trials appear to overlap each other, however when zoomed in there is a small error. The maximum overshoot of this simulation was 2.2% with a minimum overshoot of 2%. It can be inferred that the model didn't plastically deform. This result was expected because of the increased yield strength of the material.

The experimental data of the brass didn't match the simulation as closely. There was a maximum overshoot of 18% at a dimensionless displacement of 0.5 and a undershoot of 10.3%.

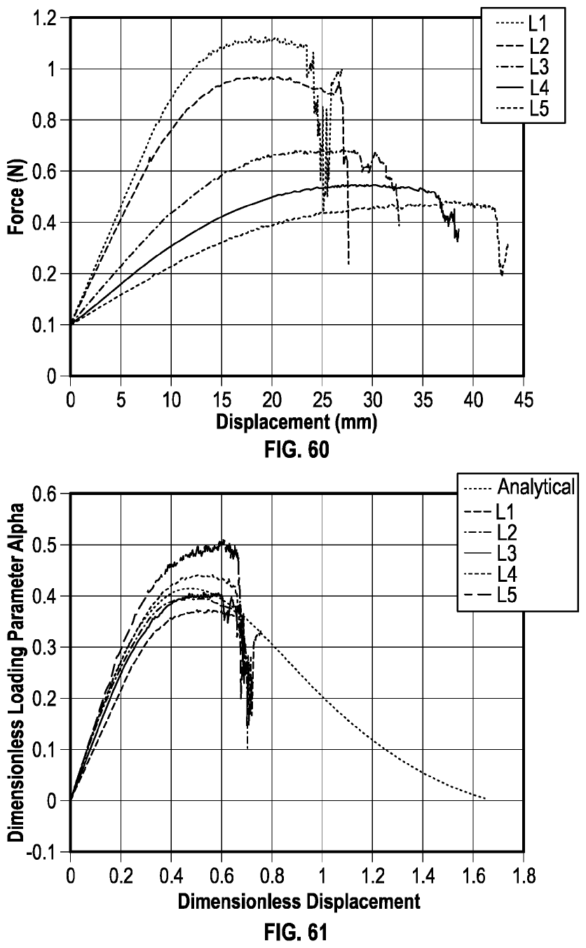

FIG. 60 follows the trend of previous tests where the force of the first interaction length is the greatest and the fifth interaction length has the lowest force. The general observation of a undershoot in physical testing is still observed. However, the difference in nondimensional force is smaller than the other materials tested.

The takeaway from this set of experiments is the matching of analytical to the experimental data. The assumption of pure elastic deformation is matched with the physical testing as no plastic deformation in the samples was observed. This set of data had the smallest error of only 2%.

### Thin Copper Cantilever

Thin copper was one of the potential microfabrication materials for the manufacturing of these cantilever designs and was explored here because of this. The thin copper samples were cut out using scissors and sanded using a high grit count to deburr the edges. Despite using calipers to measure the material, it was determined that a 0.001 precision wasn't feasible or realistic, so the values were all rounded to two decimal places.

TABLE 6
Detailed information of the thin copper
samples used in physical testing.

| | | Sample | Interaction | Peak |
|---|---|---|---|---|
| | Aspect | Length | Length | Nondimensional |
| Sample | Ratio | (mm) | (mm) | Force |
| L1 | 174 | 18.10 | 22.62 | 0.192 |
| L2 | 193 | 20.07 | 25.09 | 0.200 |
| L3 | 232 | 24.13 | 30.16 | 0.202 |
| L4 | 271 | 28.18 | 35.23 | 0.22 |
| L5 | 309 | 32.14 | 40.17 | 0.253 |

The thin copper had sharpie marks on where the clamps and the cross-head attachment were going to make contact. After the experiment, it was visible that the copper sample underwent a plastic deformation.

It was assumed that the experimental data would therefore also be flawed due to the material being so thin. There were two trials that had non-dimensional forces greater than 1. Removing those two from the set still shows a large error. Considering the malleability of the material when handling it to be cut, the plastic deformation was expected. The shape of the nondimensional force curve was expected to follow the analytical model until the yield stress was achieved. At this point the slope of the curve will be reduced to the tangent modulus and continue until the material folds back on itself or the 3D printed crosshead apparatus snaps through. The simulations also proved to be problematic due to the large deformation. The simulation was first performed assuming only elastic deformation showing a maximum overshoot of 35% with a minimum overshoot of 11%. This is also where errors started to appear in the simulations. At the start of the simulation there would be a spike in contact force as the simulation was trying to use the contact condition along with converging. It was also reasoned that this was happening due to how thin the material was.

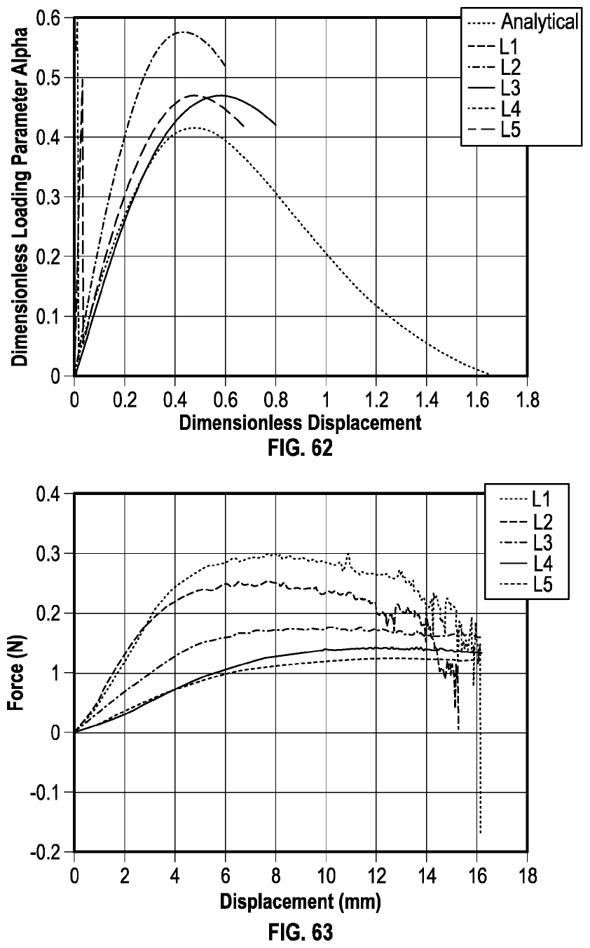

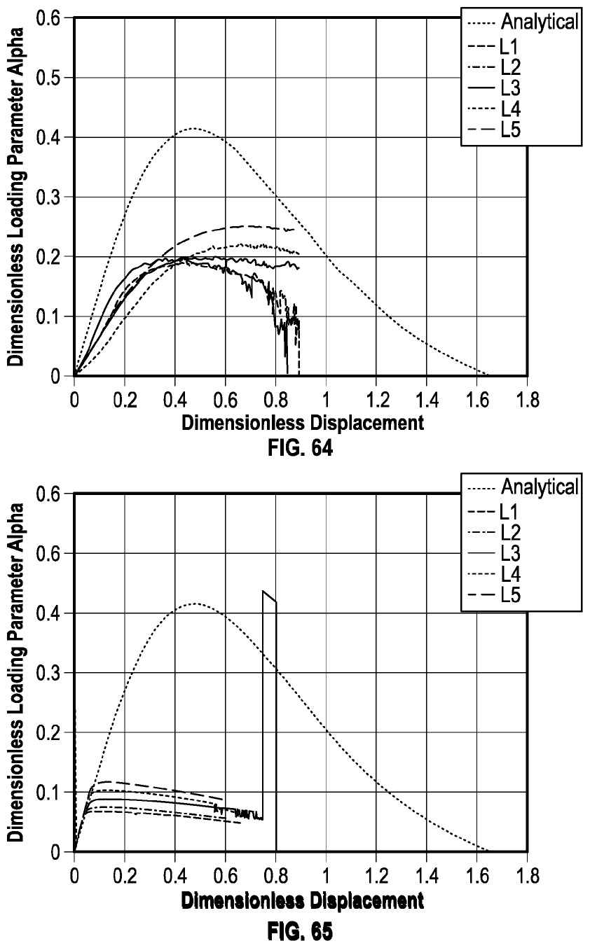

That is what would happen ideally with no plastic deformation. However, the experimental data clearly shows plastic deformation in all samples. Results from the simulation in FIG. 62 was expected due to how thin the material was and the plastic deformation that was ignored.

The experimental data in FIG. 63 shows a large amount of range of forces throughout the five trials. This was expected due to the difficulties cutting the copper to size. Despite the attempt to deburr the edges, there could have been some material curved upward or downward depending how the sample was oriented in the clamps.

Repeating this simulation with plasticity enabled used a yield stress of 33.3 MPa. The tangent modulus was set to zero as there were no finite values to use. There was no hardening function. Because of this, it was expected that the nondimensional force would flat line once that yield stress was reached. Similar artifacts were found in the data at the beginning of the simulation similar to FIG. 62. With the implementation of plastic deformation, the tolerance had to be decreased again to prevent the simulation from failing immediately. This led to larger force spikes at the beginning of the simulation.

Future testing will determine the effects that the assumptions have on the simulations. An observation of the physical testing is the nondimensional force immediately diverges from the analytical model. This is compared to the simulation where each cantilever matches the model until it yields.

### Thick Copper Cantilever

Thicker copper samples were manufactured to eliminate possible issues arising from sample cutting that may have contributed to variability in thin copper sample test results. This time the samples were 0.63 mm or 0.1 in thickness so it was possible to use a shear press and debur the edges. Reforming the samples was unnecessary as they held their shape throughout the process.

TABLE 7
Calculated aspect ratios, interaction and sample
lengths of the thicker copper samples.

| | | Interaction | Sample | Peak |
|---|---|---|---|---|
| | Aspect | Length | Length | Nondimensional |
| Sample | Ratio | (mm) | (mm) | Force |
| L1 | 174 | 87.70 | 109.62 | 0.399 |
| L2 | 193 | 97.27 | 121.59 | 0.372 |
| L3 | 232 | 116.93 | 146.16 | 0.371 |

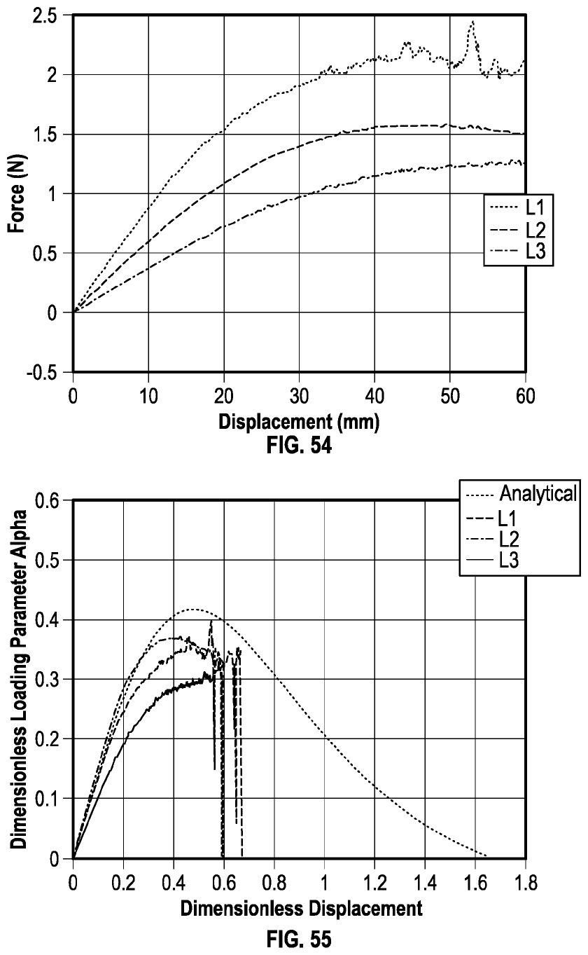

The notion of more consistent data with a thicker sample was confirmed with a more consistent set of data in FIG. 55. This chart also followed the trend of the experimental data undershooting the theoretical non-dimensional force. It is noted that the L3 trial did eventually achieve a max non-dimensional force of 0.371 but at a displacement of 0.689. There was a minimum undershoot of 12% error and a maximum undershoot by 31.9%.

The simulation in FIG. 56 again followed the other macro scale simulation trends showing an overshooting the theoretical non-dimensional force. It is noted that the L3 trial did eventually achieve the same force of 0.472 but at a displacement of 0.55. The samples overshot the theoretical maximum at 0.5 by a max of 13% and a minimum of 9.8%. L2 of the trials closely modeled the elliptic integral model until it flattened off. It is reasoned that the drop off in force is related to the size of the arm that needed to be 3D printed. Despite the attachment to the threaded rod being snug, there was still some play as the 3D printed threads deformed under the force.

This test emphasized the importance of stiff testing mechanisms. While the 3D printed arm was made with 100% infill, there was still movement. A larger bottom adjustable mount or a metal attachment to the cross head would have resulted in more accurate data.

### Experimental Testing of Non-Planar Designs

The simulations were run once as an elastic deformation only simulation and as a plastic plus elastic to verify simulations. An identical experiment was performed on the designs that wouldn't plastically deform according to the testing/simulation program. However simpler designs such as the original L design will be included as well to give a broader scope. The designs with increased geometry complexity were tested next. Due to their geometry there was be no pure analytical model to which to compare the simulations and experiments. These next tests compared the contact force of the simulation to the simulations in the same scale.

### Interacting L in Stainless Steel

The 90-degree L designs were tested next. It was assumed that incorporating any angle from horizontal would create a larger locking force. However, manufacturing a part like this is nearly impossible due to the layer-by-layer deposition or etching processes. Physical testing with the stainless steel and aluminum confirmed the simulations results that the pull-out force was less than the push-in force.

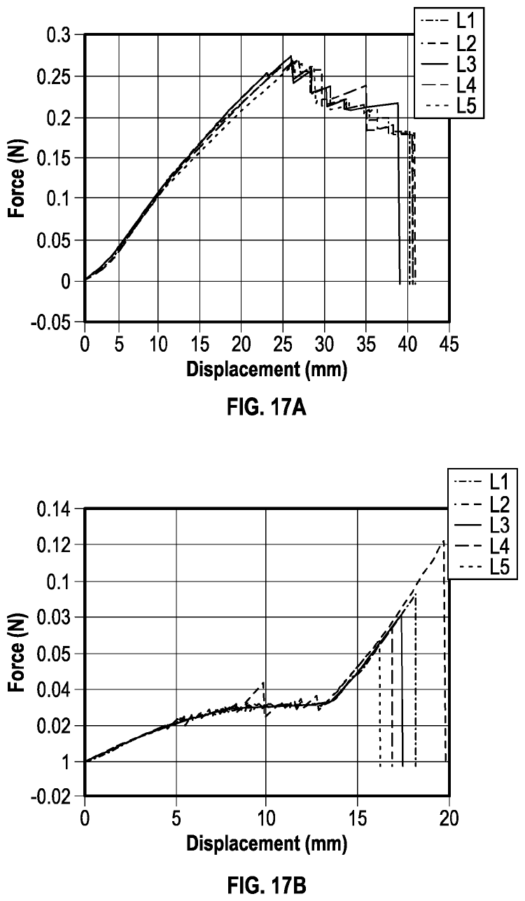

There were multiple errors with the downward simulation as there were failures due to non-convergence. The mitigation of the problem was to first decrease the density of the mesh and displacement increment. That approach failed as the mesh was set to the coarsest setting and 0.0001 mm increments. A new approach had to be taken with the construction of the geometry. The original shape was created forming a solid between two rectangles. This time in sketch mode each length of the L was sketched to form a bezler polygon. This allowed the simulation to converge for reasons unknown. In the FIG. 16 there was a large disparity between the push-in forces. This can be assumed to be due to plastic deformation in the samples. L1 to L5 represent the trial number for the samples in FIG. 17 and FIG. 18.

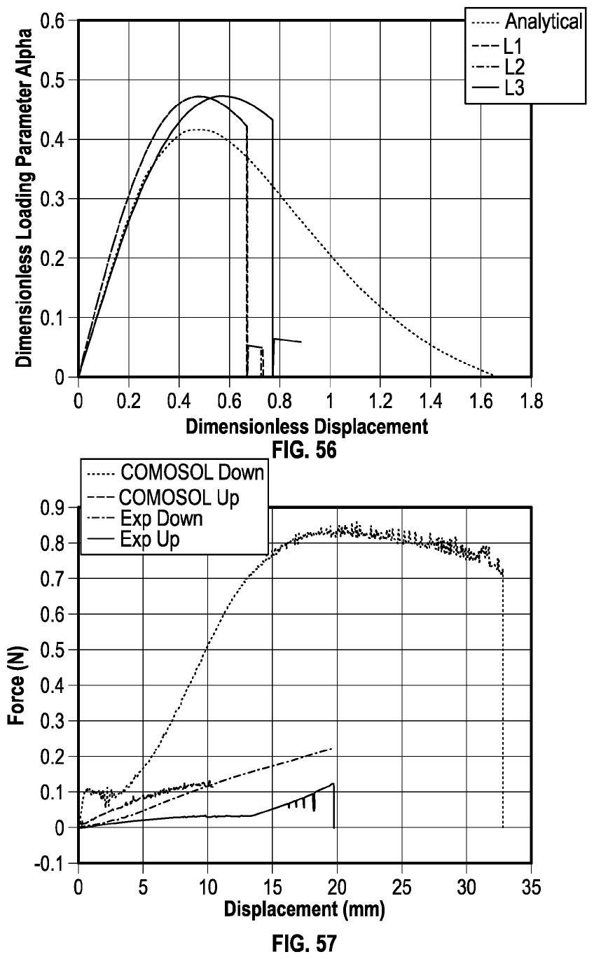

It is noted that the noise at the peak of the down simulation makes it appear to be physical data. The reason this noise happened was there were spikes in stress and contact force as the surfaces slid past each other in the simulation. This was shown as changes in color as the larger stresses turn red while the lower stressed areas remain blue. It was concluded that this was caused by the increase in error tolerance to 0.1 from 0.0001 to ensure that the simulation converged. In FIG. 57 the max displacement of the push-in experiment was 21.9 mm resulting in a 73.06% error. The pull out error was 72.29% error at a max displacement of 10.4 mm. The data from this experiment also shows that there were large discrepancies in the displacements for both push-in and pull out trials.

### Inverted S in 3003 Aluminum

The final design physically tested were comparable in design. The embodiment tested had radii included to reduce the stress concentrations in the corners and a different overlap length with the crosshead. It was decided that using strips of 3003 aluminum would be best for these experiments because they were premanufactured. Difficulties and variability from the copper test didn't instill confidence that the samples would be made defect free as they were hand formed and cut. This result would be compared to a full hard temper 302 stainless steel shim, which had modulus of elasticity of 200 GPa and was the highest of any material used. L1 to L5 represent the trial number for the experiment.

### Inverted S in Stainless Steel

The physical testing for the push-in force closely models the simulation with some artifacting due to friction. The pull-out force was inaccurate due to errors in the simulation. The push-in at a maximum displacement of 22.25 mm had an error of 35.39%. The pull-out had a smaller error of 24.18% at a maximum displacement of 50 mm. At the beginning there is a spike in the force because at the start the cantilever bent and conformed to the flat deflecting rectangle instead of angling and sliding. Examination of the samples post test showed that there was some plastic deformation occurring during the test. The same stainless steel was cut and formed into the shape and ran again.

During testing it was observed that the sample had minimal deflection and didn't plastically deform. There also weren't any sharp 90-degree angles that combined the normal force, friction, and manufacturing defects snowballing to create a larger error.

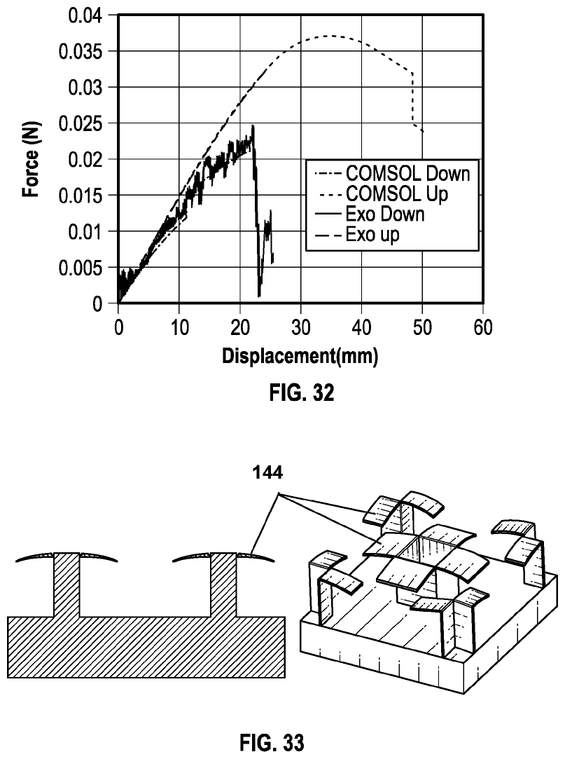

FIG. 32 provides the best verification of the accuracy of the testing/simulation program put up against physical testing. At the maximum experimental displacement of 21.9 mm for the push-in section there was a 6.78% error. However, for the pull up simulation there was an error at a maximum displacement of 25.25 mm of 0.006%. It should be noted however that there is still a large discrepancy in the total displacement of the mechanism. Looking through all of the tests and simulations showed two distinct patterns. The first pattern is the undershooting of experimental data compared to the testing/simulation program simulations. The second pattern is the increased accuracy of the simulations compared to the physical tests when no plastic deformation was observed. This is compounded by the limited nature of the plastic deformation simulations with no tangent modulus and a negligible hardening function.

### DISCUSSION

### Simulation and Modeling

To achieve converging simulations, it is important to consider the maximum mesh element size, mesh shape, displacement increment, relative tolerance, type of solver and the hardware resources available. The aspect ratio test demonstrated how changing the tolerance and displacement increment can aid in creating a converging simulation. The change from a triangular to free quad mesh with the same element sizes reduced the simulation by almost 28 minutes. This is valuable to users as they can achieve the same thing but in a shorter time. For more accurate results the mesh size could further be reduced matching the free triangular time. The determination of the mesh shape will depend on the geometry being analyzed. Within a one-hour timeframe a free triangular mesh of 200 was successfully completed and a free quad mesh of the same geometry between 250 and 300 can be completed within the hour.

The assumptions used in the reusable mechanisms were no friction, and no adhesion. This played a role in pushing the nondimensional force to a lower bound. Moving from macro to microscale the surface area exponentially increases. Therefore, the interaction forces won't scale linearly with the friction force. It can be assumed that microscale experiments involving friction will be increase the contact force and displacement before snap through, increasing the nondimensional force. The simulations that used these assumptions with the addition of no plastic deformation would only further increase the force. One time use or plastic deformation mechanisms used the assumptions that only the initial yield stress was used. The tangent modulus and hardening functions were assumed to be zero. This was due to the delayed time frame of gaining access to the full simulation suite. Future work would determine how large of a factor the hardening function and tangent modulus would be by comparing the simulation results with and without these factors to the physical testing.

Within the analytical model it was assumed that the deformation was purely elastic, and the bulk properties were the same in microscale. This assumption was made due to a lack of properties of thin films and limited work done. Therefore, it could be reasoned that if it was possible to vary the bulk properties, the analytical force curve would increase. If there was a second model made incorporating plastic deformation it is reasoned that the model will look similar to the thin copper example where after exceeding the yield stress, the slope will decrease.

Analytical modeling showed that the interaction force in a purely elastically deforming mechanism with a maximized aspect ratio had a contact force of only 250 Pa. This is two orders of magnitude smaller than the calculated upper bound stress of the “inverted S” at 19.82 kPa and five orders of magnitude smaller than the target specification of 10 MPa. While the reusability of the mechanism will be reduced, it is a tradeoff that should be made to achieve the most critical requirement of adhesion force. Future work to quantify the amount of plastic deformation required will provide users options for their choice of focusing on either bond strength or reusability of the mechanism.

### Aspect Ratio Limitations in Finite-Element Modeling

A maximum aspect ratio of 309 was successfully simulated with and without plastic deformation in the mm scale. This paper however focuses on the design and simulation strategies for the creation of microscale interlocking structures. As mentioned previously material and geometric properties may not scale linearly as they are reduced from bulk structures. It was assumed that there would be a different max aspect ratio that could be successfully ran in microscale. This section aims to define a maximum aspect of microscale simulations that would converge in a “reasonable” amount of time (less than or equal to one hour). The ability to solve these equations is based on the amount of cores as well as the core speed since the testing/simulation program didn't support multithreading or GPU solving. All of the interlocking structures tested at one point failed due to nonconvergence. Changes in the mesh and displacement increment were made with increases in error tolerance as a last choice. All of the simulations were performed with the extremely fine defined mesh. The maximum element size varied throughout the different geometries from 0.0795 μm to 0.1 μm and a minimum element size of 0.2 nm. The varying dimensions also lead to differing domain and edge elements. It is a mistake to limit the scope of designs because the testing/simulation program didn't converge. Simulation software like COMSOL, ANSYS, ABAQUS, etc. use systems of partial differential equations to analyze the component. It was up to the user deciding how much of their computational resources to dedicate along with time to create a mesh fine enough for the software to solve. Knowing the limitations of the software is valuable to the user for knowing with certainty that they will get a result that could verify their analytical work. Previous work was done with aspect ratios as mentioned in FIG. 10 ranging from 35 to 70. A singular rectangle with a square on top of it was simulated. The left-hand side edge of the cantilever has a fixed constraint applied. The square is 1 μm by 1 μm. As the maximum mesh element size is shrunken, the square it shrunken as well to reduce the number of total elements. The shape of the mesh remained the default of free triangular. This was decided over the use of varying mesh densities because it could create odd mesh shapes that make it difficult to solve. The study settings included geometric nonlinearity just like all other simulations.

The top edge of the square had a prescribed displacement in the negative y direction along with utilizing the form assembly contact pair. The length of the cantilever was set to 10 μm with the thickness set to be the length divided by the desired aspect ratio. The auxiliary sweep of the displacement started at zero, a displacement increment of 0.25 μm and an end condition of 3 μm. From previous simulations it was learned that after snapping through the simulation error would increase to the point where the simulation “failed” despite successfully performing the simulation. The mesh composition of this aspect ratio featured 668 domain elements and 242 boundary elements with 3160 degrees of freedom with a relative tolerance of 0.01. This simulation took four seconds to finish and converge successfully.

An aspect ratio of 200 was tested next. The maximum mesh element size was reduced to 0.005 μm at first along with the displacement increment to 0.05 μm. This was point where the number of elements and degrees of freedom were too large with the 0.1 μm square. The square was reduced to 0.1 μm in length and width. This was done to give the simulation the best chance to converge as there were still more elements than the aspect ratio of 100 with the larger square. This simulation with the reduced square had 204074 domain elements and 8200 boundary elements with 832700 degrees of freedom. Running the simulation with a tolerance of 0.01 lead to a non-converging solution even after increasing the number of iterations from 25 to 100. The displacement increment was then reduced to 0.1 μm. This resulted in the completion of the simulation but the small square teleported through the cantilever after a displacement of 0.7 μm which wasn't correct. The next step was to decrease the maximum mesh element size to 0.0025 m. This now caused the simulation to take too long to achieve the initial convergence to start the simulation. At three minutes and 37 seconds the simulation was stopped because the simulation wasn't converging. As a result, the relative tolerance was increased to 0.1 to guarantee convergence. With the same free triangular mesh element, the simulation was completed in 59 minutes and 11 seconds which was still within the time cut off.

An attempt to optimize the simulation was made by changing the element shape to tetrahedral as both geometries were made up of squares. The maximum element size was maintained and the simulation was run again. This time the geometry contained 81600 domain elements and 8200 boundary elements with 506004 degrees of freedom. This change in element shape reduced the simulation time to only 31 minutes and 40 seconds. This shows that the matching of the mesh shape to the geometry is an important simulation consideration. Moving to the 250 aspect ratio the free quad mesh geometry will be kept. The geometry contains 65600 domain elements and 8192 boundary elements with 409988 degrees of freedom. It successfully ran in 23 minutes and 49 seconds which is expected due to the decreased number of elements. Increasing the aspect ratio to 300 had the same teleportation problem. Therefore, the maximum mesh element size was decreased again to 0.00125 μm. This resulted in a mesh that contained 222400 domain elements and 16374 elements with 1367152 degrees of freedom. This simulation took one hour and 53 minutes to finish. If the block didn't teleport through the cantilever, it could have been completed in time. However due to the reduction in mesh size, it was guaranteed that the simulation would finish in two hours and nine minutes and successfully converge. Therefore, it is concluded that the maximum aspect ratio that can be simulated in under an hour is a ratio of 200 with free triangular mesh. With the free quad mesh an aspect ratio of between 250 and 300 could be solved within the one-hour time frame.

### Analytical Optimization

As discussed in previous sections, the performance of this design was evaluated with FEA, under pure elastic conditions (“inverted S”). The maximum von Mises stress was 428 MPa. Plastic deformation is expected to occur as the yield strength of copper and even titanium of 140 MPa is exceeded quickly. The maximum force required to interlock a pair of cantilevers was 2.5 N, and to separate required a force of 9 N. This corresponds to push-in and pull-out strengths of 8 kPa and 29 kPa respectively, higher than the maximum 6.3 kPa pull-out strength found earlier for arrays of simple flat cantilevers. The assumption of pure elastic deformation and constant bulk properties transitioning from macro to micro scale were also used which allowed the model to be solvable. This was why the testing/simulation program was needed as a verification of the model based on similar assumptions. The ability to perform plastic deformation simulations was something that couldn't be achieved with analytical modeling which further emphasizes the importance of the testing/simulation program. This modeling concludes that the design is promising for future work as it gives potentially high retention strength in a reworkable design, but much more optimization is required. Analytical work was performed on the cantilevers to create an “optimal design” to have the highest strength possible. This design can be seen in FIGS. 3A, 3B, 3C, and 3D. Equation 28 is the optimized equation for nominal strength utilizing N arrays of joints in area A.

$${σ}_{m} = \frac{2 N * 0.4 \; 17 EI}{{A ( \frac{d}{2} )}^{2}} \qquad ( 20 )$$

Later σₘ is changed to the interfacial strength. The unit cell pitch is defined as ρ=2(L₀+w+D) where D is the width of the supporting pillar, ω is the length of the rigid cantilever that extends from the right pillar and L₀ is the interaction length.

$${σ}_{m} = \frac{{C}_{1} {EDt}^{3}}{3 {( {L}_{0} )}^{2} {( {L}_{0} + ω + D )}^{2}} \qquad ( 21 )$$

In this situation titanium was used with a dimensionless displacement of 0.3 with a corresponding nondimensional force of 0.36. L* was set to 1.05 and the aspect ratio was set to 250 to maintain elastic behavior, ω was set to 4 μm, and D to 20 μm. This led to a very low contact force of 250 Pa.

It is clear from this analysis that designing interlocking structures that remain within the elastic regime of its material will lead a low-performing material. Pure elastic operation is required of patterned surfaces that can be separated and reattached repeatedly, but this comes at the price of adhesion strength. The condition of reworkability can be preserved if some plastic deformation is allowed in a single-use component. In this case the surface of patterned rigid structures enables attachment, removal, and replacement of components.

### Experiments

This work is classified as successful because of the improvement from the flat cantilevers in contact force and reduction in pull out force (snap through force in the positive y direction) backed up by physical testing. This design also improved the assembly process with a reduced push-in force and an increased pull out force. In the scope of the big picture, it can be concluded that simulations need physical testing to be verified with errors up to 73.06% for experiments in macro scale. This leads to speculation regarding the accuracy of the microscale experiments. The testing/simulation program was the only thing that could be used as the math for non-flat cantilevers was very complicated and also had limiting assumptions. No ability to physically manufacture designs to test meant the simulations had to be trusted but with the caveat of future physical testing being needed. Further improvements to the simulation can be made by placing a probe to track the displacement of tip of the cantilever in the x and y axis to compare to the physical testing.

The experimental setups aimed to create an environment where the test can be replicated and blocking as many noise causing factors as possible.

The 3003 aluminum had the least variation throughout the five trials as only one cut was made and filed down along the length. The brass, copper and stainless steel were cut via shears. This resulted in slight geometric discrepancies that contributed to the variation throughout all of the trials. An improvement to this would be to have the samples cut by either a CNC mill or water jet cutter.

### Mitigated Testing Errors

It was observed that the brass and thin copper models were on the edge of the modulus of elasticity for copper and within the titanium yield stress limit. It can't be said enough that the simulations were highly idealized environments that were tailored for the simulation to converge successfully and consistently. In an experimental setup there was uncertainty of staying within the yield stress as there was no friction in the simulation. A thin layer of grease was applied but that had a negligible effect. Looking through the raw data of all physical tests there was always some form of noise of friction on the steel and 3D printed apparatus. During the thin copper experiments the friction would cause a large enough fluctuation of force that the mechanical test system would stop the test because it interpreted the change in force from friction as the sample snapping through.

Another error during the physical testing was the manufacturing of samples. The copper foil was only 0.005 in thick so it wouldn't be cut using standard metal shears. A large experimental error was expected as the copper would deform from handling and cutting. To mitigate this the samples were placed between two aluminum plates and clamped in a vice to try and re-flatten the samples. They were remeasured as well to make sure the thickness hasn't changed. Removing the samples from the clamps still showed flaws such as misaligned cuts and curled corners. Previous attempts on a CNC machine in the carbon fiber experiment created samples that were the correct dimensions but there was significant damage done to the material going through all the bits on hand. The experimental noise due to friction was attempted to be mitigated by applying grease to the testing apparatus and samples. This had the opposite intended effect and actually increased the amount of noise for the interacting L simulation. It was reasoned that the adhesion due to the liquid nature of the grease caused the samples to stick together then slide. The same thing happened with the “inverted S” test with the 3D printed cross head attachment. Online resources were used instead of using the Shimadzu and extensometer to gather the data due to the material flexing due to the extensometers weight.

To combat the flexing the sample was put under load to try pull the material taught without plastically deforming the material. After loading the sample with the 3003-aluminum sample 0.016 inches thick it would be assumed that the copper sheet 0.005 in thick wouldn't hold up in for the duration of the test.

Concluding Design Considerations from Initial Experiments

From the initial simulations and physical testing performed, several design considerations can be made to optimize the system for cantilever-based interlocking to accommodate reworkable heterogenous integration that are discussed in the list below.

### (1) Base the Material Selection on Yield Strength.

Copper was the primary material of choice with an initial yield stress of 33.3 MPa. Each simulation was in the GPa range or in the case of the “inverted S”, a von Mises stress of 428 MPa. Plastic deformation can be prevented by using higher strength materials such as titanium, tungsten or tempered steel or stainless steels. These materials can range in yield strength of 500 to over 1000 MPa which would aid the design. AISI 4340 Alloy steel that is oil quenched and tempered at 315° has a yield strength of 1620 MPa. A higher yield strength entails a greater amount of contact force can be applied to the design without plastic deformation. Physical testing proved that keeping the aspect ratios constant, the materials with higher yield strengths (brass and stainless steel) matched the idealized elastic only analytical model closer compared to the thin copper or 3003 aluminum.

### (2) Include Radii Instead of Sharp Corners.

This consideration may be made to eliminate stress concentrations in the design. In the “inverted S” design, 0.5 μm radii were incorporated as it was observed during the interacting L simulation that there was a stress concentration at the corner where the vertical and horizontal members connected. The inclusion of a radii will allow the stress to be distributed along a larger area instead of a finite corner. It can be reasoned that the larger the radii, the less likely there will be stress concentrations in the design. However, the designer needs to ensure that the radii isn't too large to the point where it'll interfere with the interlocking mechanism or the base.

(3) Increase the Thickness of the Region that is Constrained.

This consideration is formed off the observation throughout the entirety of simulations. Whichever face, side, or edge was constrained, there was a stress concentration in that location. The left cantilever in the 3D embodiment tested is constrained to be fixed along the left rectangular face while the right cantilever has the prescribed displacement sweep applied. Increasing the amount of material with a small taper to the desired cantilever length will allow for an improved stress distribution along the shape without drastically increasing the manufacturing difficulty.

### (4) Include Angled Interacting Cantilevers if Possible.

This consideration comes with the caveat of the manufacturing capabilities available. Experiments such as the chevron and angled plates demonstrated high contact forces for the pull-out phase and low push-in force. This enables the user to easily attach the device without difficulty. The angled interaction length will prolong the contact length as the materials stress increases until it snaps through or plastically deforms.

### (4) Minimize the Aspect Ratio.

It should be a goal of the user to minimize the aspect ratio while staying as close to the elastic region as possible. When attempting to maximize the aspect ratio to the detriment of the bond strength it was calculated that the design would achieve a strength of only 250 Pa.

The maximum aspect ratio that can be solved within an hour on the testing/simulation program used in microscale is between 250 and 300 depending on the mesh geometry.

Further investigation of the limiting aspect ratio led to two different value ranges. Free triangular mesh geometries with an aspect ratio of 200 successfully remained within the one hour.

### Secondary Developments on Interlocking Structures for Heterogeneous Integration

### Overall Goal of the Work

The overall goal of the following examples was to develop arrays of microfabricated interlocking structures for heterogeneous integration. Further experimentation and design iteration utilizing the design considerations established by the initial experimentation with the inverted “S” embodiment as described in the previous sections was performed in pursuit of creating an array of microfabricated interlocking structures for heterogeneous integration. The work laid out in the previous sections was a proof-of-concept to show that this technology has potential and included the development of an analytical model that could be used in design. The work outlined in the following sections expands upon that work to develop optimal interlocking structures that can be manufactured with conventional microfabrication methods. As there are many challenges associated with the heterogeneous integration, the main challenge is mechanical retention, that is the ability to hold microdevices in place without falling off. All other factors like thermal and electrical properties will always be considered but are not specifically designed for. Another goal of the work outlined in the following sections is to design the structures such that they only require mechanical force to join the microdevices and may be used in conventional pick and place machinery.

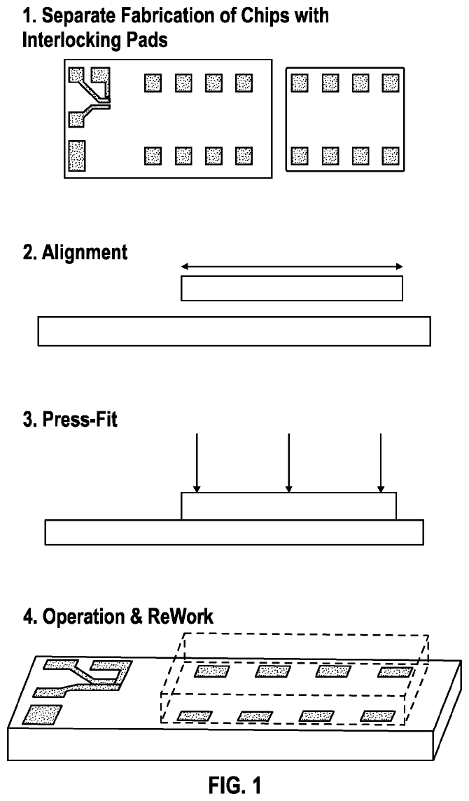

These microfabricated structures will enable the quick joining of chips as in FIG. 1. During assembly and joining of components an industry standard pick and place machine can be used to pick up the chip with the interlocking cantilever, position it, then press the chip with enough force for the cantilevers to snap past one another joining them. At this point the assembly can then be used.

For the assemblies to be used directly after joining, this suggests that the structures should be able to provide electrical connections between the components. Traditionally this has been done with the use of wire-bonds which are thin wires made of pure gold that are bonded directly to the devices. On the devices there are small pads of conducting material that serve as the places where the wire-bonds join. These require specialized machinery to provide bonding. This method for electrical connections are not ideal for RF applications due to degradation of the signal, and interference due to the wires acting like antennas.

Another method for joining micro devices is through the use of flip-chip bump grid arrays which use small balls of solder called bumps that provide electrical connection and serve to join the devices mechanically. Solder joints are not ideal as issues like voids forming in the solder decrease performance and can lead to failure. Failure of these solder joints can occur due to the large amounts of heat that is generated. The issue is that often the device and assembly substrate are made from different materials with different coefficients of thermal expansion. This can lead to large amounts of expansion, so much so that the solder will fail from fracture. The cracks can initiate at the edge where the solder flows onto the chip, and then the crack extends until the solder joint fails completely.

Much work has been done in the area of producing structures for mechanical attachment. Many have been inspired by natural plant hooks which use their hooks to attach to animals to disperse their seeds. One class of materials is known as hook and loop materials and work has been done to produce them at the micro and macro scale.

Prior inspiration led to the current approach that is outlined as follows, specifically the prior work of the proof-of-concept designs. Related to structures for direct mechanical attachment, include bundles of carbon nanotubes, wires, and tubes that rely on friction, and buckling to join components together. Another interesting method for attachment relies on Van der Waals bonding between structures. These are inspired by the hair-like structures on the bottoms of gecko-feet so called gecko tapes have use the structure to increase the surface area, and therefore increase the amount of bonding that can occur and can get bond strengths close to ˜1 MPa. Van der Waals bonding is an interesting approach which obviously has a great potential, this method is out of the scope of this work although it is desired to eventually consider Van der Waals effects into miniaturized designs.

Much work has been done towards heterogeneous integration, and the approaches that use microfabricated structures are all very promising. The main challenge this work seeks to overcome is to develop a design that can manufactured with conventional microfabrication techniques that is as strong as the other microfabricated structures and is comparable to current attachment methods like epoxy and solder. The biggest questions to be answered “what does an optimal design look like?”, “how does misalignment affect the performance of the interlocking structures and how to overcome this?” and “what are the materials that will be used?”.

### Design Constraints and Performance Targets

Many performance targets were set so there is a goal to work towards. Mechanical attachment would require patches of material on a chip to provide a mechanical joint in some unused portion of the chip footprint. Contact pads with the interlocking structures allow for the transfer of power and signal transfer in addition to providing mechanical attachment. In this work, several designs were developed based on constraining the structures to fit on an 100 μm×100 μm area, a size one could expect a typical electrical contact pad. A summary of desired characteristics is provided in Table 1.

In this work, the mechanical properties are of most interest and were the ones that were explored. Adhesion is the strength required to separate a chip from a substrate. Importantly alignment tolerance must be considered when designing. If the design requires a highly precise alignment, it will not be practical as machinery would not be able to position the chips accurately enough for them to be joined. Because a high bond strength is desired, if one were to make the structures symmetrical this would mean a very high force would be needed to join the chips. Therefore, it is desired to have force asymmetry, that is, the force to push the chips together is less than the force to separate the chips. This is done to be sure that pick and place machinery are capable of joining the chips.

Only the mechanical parts of the design considerations were evaluated. The thermal and electrical requirements were be assumed to be true. This does limit the materials and the process to manufacture that can be used, and further constrains the final designs.

### Fabrication and Material Selection

This section details the fabrication techniques that were selected to produce the proposed microfabricated interlocking structures as well as the materials that were selected.

### Proposed Microfabrication Process

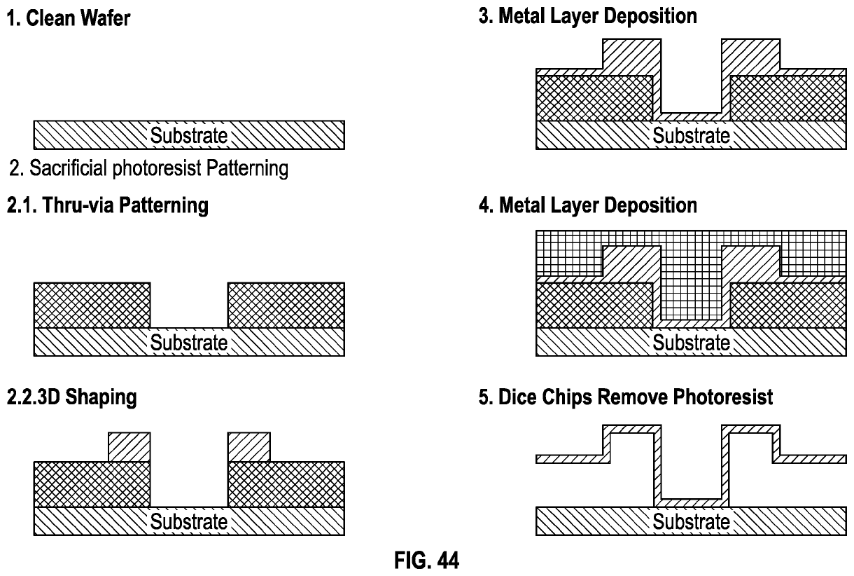

In this work, it is proposed to use the standard microfabrication methods one would use to manufacture microdevices. Mainly using photolithography to pattern the arrays of interlocking structures and then to evaporate nanometer thick layers of metal to form the structures. Formation of the freestanding cantilevers is utilizing a sacrificial layer of polymer or photoresist will act as a mold to shape the metallic film. A diagram showing the process flow can be seen in FIG. 44.

First the substrate is to be cleaned of all possible contaminants including residues from previous fabrication steps and small particles that may land on the surface from the environment. Next a layer of photoresist is spun onto the substrate, and then is exposed to UV light with the photomask in place. This step is to pattern the thru-via which is what will suspend the cantilevers from the substrate. The unexposed photoresist is then cleaned from the chip.

If one is to produce cantilevers that are flat in geometry, then the evaporation of the metal layer may proceed. The amount of time needed to evaporate the metal is dependent on the thickness of metal desired as well as the specific metal being used. Direct evaporation is possible if using a few select materials like gold and titanium. Other materials that could be considered like tungsten require the use of ALD (Atomic Layer Deposition) to first lay down a layer that is a few nanometers thick of alumina (Al₂O₃). This is to act as a layer for the tungsten to adhere to as well as to act as a barrier to prevent oxidation of the tungsten with oxygen readily found in the atmosphere. In the case of tungsten an additional layer of alumina should be deposited onto it to prevent oxidation of the top surface. The expected thickness to be deposited is in the range of 0.1 μm up to 1 μm.

Next final patterning and shaping of the cantilevers can be done. Once the metal layer is deposited, another layer of photoresist can be spun onto the substrate, and then can be exposed. The photomask is aligned, and then the UV light is shown onto the wafer. The unexposed photoresist is then removed. This is to provide a protective layer from the etching step. Etching is to remove the unwanted areas of the metal. Following this step, the individual chips can be cut from the wafer using a dicing saw. The chips are then cleaned of the cuttings. The exposed photoresist is then removed, releasing the cantilevers.

In this work 3D shaper for the cantilevers were explored. This in the form of a corrugated cross-section like that of cardboard where there are additional vertical sections to increase the moment of inertia. It was also explored if changing the shape along the length would affect performance. In exploring this, bends were introduced along the length of the cantilever rather than using a straight beam. This does not change manufacturing much as it would only introduce a few more steps in shaping the photoresist layer before the metal deposition step.

3D shaping continues after the previous step of forming the thru-via into the photoresist layer. In this step, photoresist is again spun onto the wafer, a photomask is aligned with the structures, and UV light is shown onto the photoresist. Depending on the complexity this would be needed for every feature that would require a change in height for the designed structure. The unexposed photoresist is then removed then metal deposition can occur. Final dicing and release can then proceed with the same steps mentioned previously.

### Material Selection and Considerations

Material selection is of the most important design considerations. In this work only the mechanical properties were explored as they are what determine the bond strength. Properties like electrical and thermal conductivity are reserved to be explored in future work when heat conductivity and electrical connections will be explored. It should also be mentioned that certain materials like gold will spontaneously cold weld with itself, where when it contacts itself the gold atoms will metallically bond with itself leading to an increase in strength as well as thermal and electrical conductivity, but this will also be assumed negligible and all strength will only be considered from the mechanical retention force of the cantilevers.

The main materials that were considered in this work were copper, gold, nickel, titanium, and tungsten. These are chosen because of their common use in micro electronics manufacturing. Other materials like Silver were initially explored but was not chosen for this work as it does not work well when used in microelectronics. The mechanical properties considered were the Youngs modulus, Yield strength, and Poisson ratio. The Youngs modulus for the considered materials can be seen in Table 8.

TABLE 8
Selected materials with mechanical material
properties needed for design and modeling

| | Youngs | Yield |
|---|---|---|
| | modulus | Strength |
| Material | (GPa) | (MPa) |
| copper | 110 | 33 |
| gold | 77 | 205 |
| nickel | 207 | 59 |
| titanium | 116 | 140 |
| tungsten | 400 | 750 |

From Table 8 it can be seen that the copper and titanium have a similar Youngs modulus and will therefore produce similar bond strengths. Tungsten has the highest Youngs modulus as well as the highest Yield strength. The initial choice should then be to use Titanium due mainly to its high yield strength. Titanium also has good compatibility with the substrate materials and is readily used in microfabrication processes. On inspection tungsten has the best properties of all the considered materials being the strongest of all of them. However, tungsten requires the use of Atomic Layer Deposition (ALD) which is a difficult process requiring additional layers of Alumina to prevent oxidation. Critically tungsten ALD produces extremely hazardous byproducts that must be dealt with. This complex processing makes it highly undesirable for producing these structures. For these reasons, both gold and titanium will be the materials that were selected for the interlocking structures to be made from. In the future, more materials will be selected if other properties become more desirable such as thermal and electrical conduction. An additional embodiment of the non-flat cantilevers includes creating curved cantilevers by evaporation of two materials. In order to accomplish the curved cantilevers, materials with different rates of thermal expansion will have to be selected.

### Design of Interlocking Cantilevers Using Analytical Methods

This section outlines the design methodology of interlocking structures and presents several designs as well as their expected performance.

### General Design 1-1D Linear Arrays

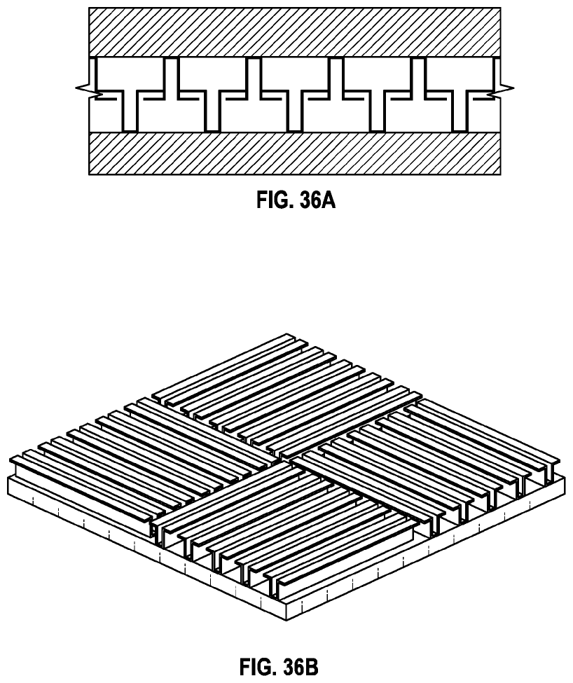

One of the first designs explored was a single 1D array. It was wondered what the performance would be like if one restricts the interlocking structures to be very long with only two cantilevers per individual structure. This 1D design is where cantilevers would only interact within a single direction parallel to the substrate. What is meant by 1D is that one only needs to look at a single cross-section to examine it, whereas a structure with three or four cantilevers would have some rotational symmetry. The cross-section of a proposed 1D array can be seen in FIG. 36A, an isometric view of a tiled 100 μm×100 μm 1D array can be seen in FIG. 36B. To facilitate easy manufacturing, the structures should require the use of the fewest number of masks possible. This design requires the use of 2 masks, the first of which is necessary to produce a rectangular thru-via structure where material bonds directly to the substrate and serves as a mechanism to anchor the cantilevers. The second mask is required for the final shaping of the cantilevers.

To normalize the dimensions and develop further insight for design choices, two parameters are introduced, pitch and aspect ratio. Pitch ρ will be used to define the size of the unit cells of the interlocking cantilevers. For the proposed 1D array, it is the distance from one point on an interlocking structure to the same point on the next repeated structure. Pitch will be a measure of the unit cell length in pm. A pitch of 10 will mean that the unit cell is 10 μm in characteristic length. Aspect ratio Aᵣ is the other parameter which will be needed to fully define the geometry of the interlocking structures. It is defined as a nondimensional measure of the total cantilever length divided by the cantilever thickness.

The beam parameters are the same as those discussed above, where bonding strength is still determined primarily through the interacting distance, thickness, and number of the cantilevers. One proposed design using the 1D cantilevers was to create staggered structures where the 1D arrays are in square sections, which are then rotated in a tiled design. This would allow the design to keep the same cantilever density, and restrict movement within the plane of the substrate, whereas a non-tiled array would still allow movement in one direction. The design can be specified with several parameters defined below and can be used in the scaling Eq. (22) to easily change parameters when designing. These parameters are defined as fractions of the pitch, which was chosen for simplicity and for considerations of the tolerances in manufacturing. It is possible to further optimize the beam geometries to either increase the maximum bonding strength or for misalignment tolerance. In Eq. (22), h is the height of the pillared thru-via structure, W is the width of the thru-via, L₀ is the distance between to edges of thru-vias on opposing chips, L is the length of the cantilever, and t is the thickness of the metallic film.

$$h = 0 \text{.5} ρ \qquad ( 22 a )$$

$$W = 0. 25 ρ \qquad ( 22 b )$$

$${L}_{0} = \frac{ρ - 2 D}{4} \qquad ( 22 c )$$

$$L = 0. 75 d \qquad ( 22 d )$$

$$t = \frac{L}{{A}_{r}} \qquad ( 22 e )$$

### General Design 2-2D Square Tiled Array

Expanding on the 1D array, a 2D array was proposed where cantilevers would extend in two directions on the substrate. That is on a structure, the cantilevers extend in two directions. The cantilevers on the 2D arrays are the same as the 1D where it is a thin rectangular cross-section. The difference between the two is the 1D arrays are long cantilevers which extend out of a plane, whereas the 2D arrays are small-pillared structures with the cantilevers branching off of the center pillar. The main advantage with this design over that of the 1D array is that it is able to be moved translationally and still interlock. That is, it has better misalignment characteristics. Analysis techniques are also the same as the 1D arrays, now accounting for the second direction. The main difference between the two designs is in the unit cell, where the width of the 1D array can be selected independently, the 2D array is driven entirely by the chosen pitch.

As with the 1D array, the design of the 2D array can be defined in terms of the pitch and is shown in Eq. (23). For the 2D arrays, the pitch corresponds to the distance from the center of one pillar structure to its nearest neighbor directly in the x and y directions. The scaling equations remain the same between the two variations with the pillar diameter D replacing the channel width W. This leaves the thickness of the cantilever which can be selected depending on the balance between bond strength requirements, maximum bending stress within the cantilever.

$$D = 0.25 ρ \qquad ( 23 )$$

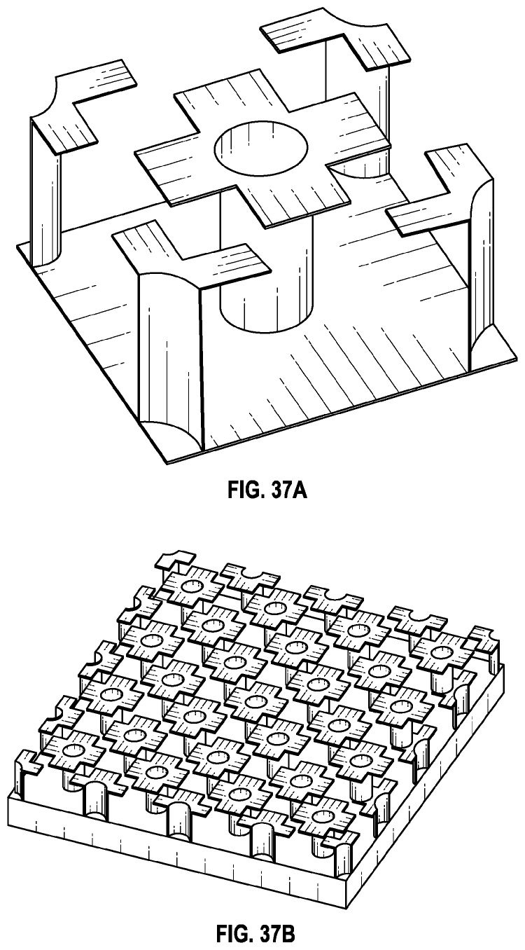

The basic shape of the 2D tiled arrays can be seen in FIG. 37A and FIG. 37B where the basic unit cell is shown, along with a 100 μm×100 μm array respectively.

Optimized 2D Interlocking Structures with Flat Cantilevers

When interlocking cantilever structures, the bending stress greatly limits the performance and life of these interlocking structures. Because of this an optimization scheme was developed to reduce the stress. This section details the design choices based on the optimization scheme. This analysis is based on the large deflection analysis. First it is selected to use a snap-through nondimensional displacement of 0.30, with a corresponding snap-through nondimensional force of 0.36. These values lead to an L* value of 1.05. Because of the resolution of the manufacturing techniques, it is proposed to have and L and L₀ value of 20 μm and 19 μm respectively.

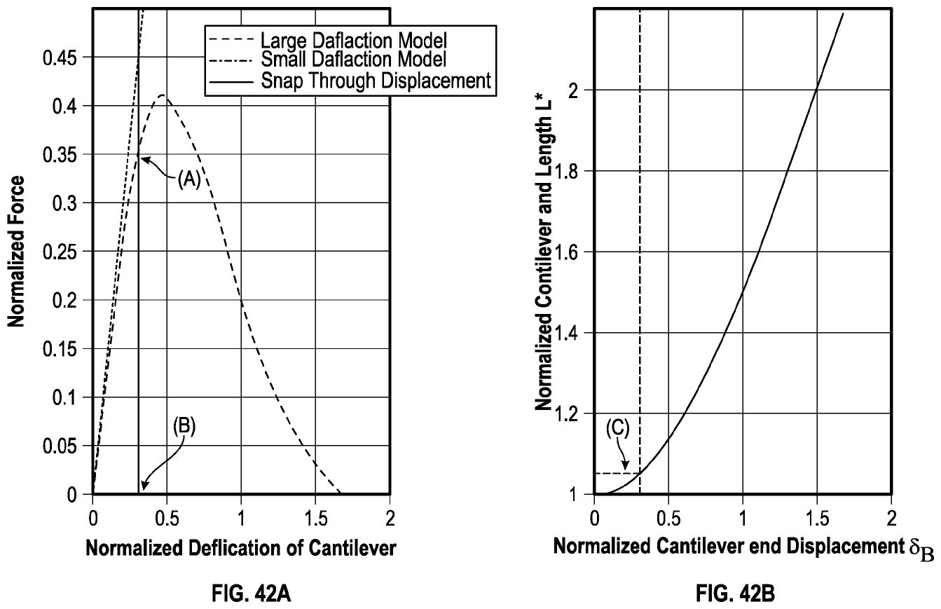

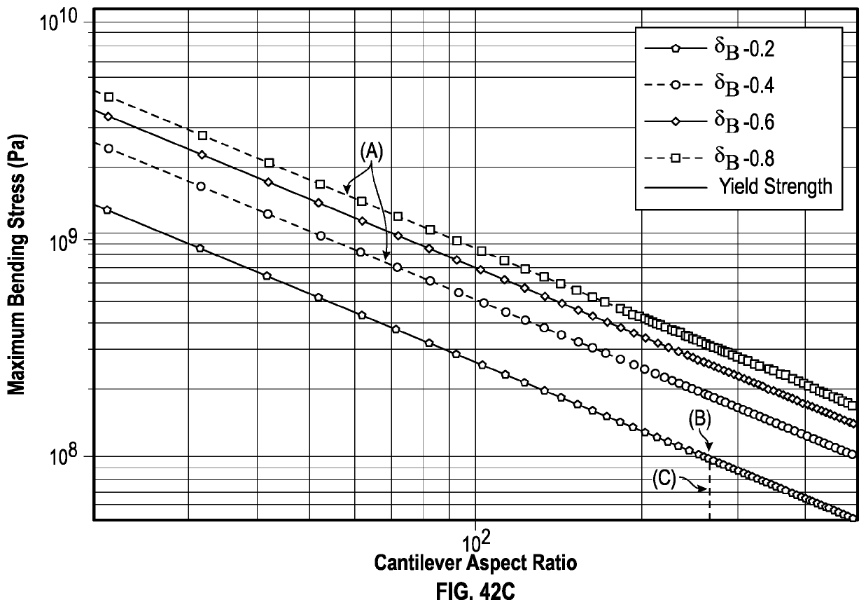

These are chosen due to the proposed fabrication method having a resolution of 1 μm. 20 μm and 19 μm is a ratio that is very close to 1.05 with an integer value for the lengths. To avoid plastic deformation an aspect ratio of 250 is selected, as shown in FIG. 42C. These parameters are shown on a cross-sectional view of half of a repeating cell on FIG. 3C. Finally, the pitch ρ is left to be obtained. Utilizing the parameters from above and selecting an ω value of 4 μm, D is selected to be 20 μm and leads to a ρ of 42 μm. This configuration then leads to a maximum bond strength of 250 Pa. It is clear from this analysis that designing interlocking structures to remain within the elastic regime of its material will lead a low performing design.

With purely elastic designs shown to not be viable, we now relax the condition for elasticity and now we will allow for some plastic deformation to occur. We can conclude that this will be an acceptable approach because it is expected that the device will only need to be removed several times. In final assemblies it is expected that the devices will only be removed to replace dead components, meaning that the life span of the interlocking structures is irrelevant if the component is already being disposed of. This leads to the question about the structures on the assembly to be reused. It is now proposed to use two different structures, one which is compliant that provides the interlocking force and another rigid structure that allows the compliant structures a place to join to.

Following the design and optimization strategy above with the assumption that plastic deformation is occurring, a design for interlocking structures is now presented. First an L and L₀ are selected to be 10 μm and 8 μm respectively. This gives an L* of 1.25, which means it will reach the maximum nondimensional force of 0.417. Aᵣ is selected to be 100, using the relations presented above all other parameters are presented in Table 9. CAD models of the compliant interlocking structure can be seen in FIG. 3A, and the rigid interlocking structure can be seen in FIG. 3B. These parameters produce a bonding strength of 6.3 kPa. This theoretical maximum is comparable to commercially available hook and loop materials. This shows that these micro interlocking structures have great promise in improving integration methods of chips, but more work is required to better refine their design through improved modeling methods coupled with physical testing of the metallic films that will comprise these structures. A cross-sectional view diagram of the compliant and rigid interlocking structures with the labeled dimensions can be seen in FIG. 3C.

TABLE 9
Dimensions for proposed interlocking
structures with flat cantilevers

| L | 10 | μm |
|---|---|---|
| L₀ | 9 | μm |
| Aᵣ | 100 | |
| t | 100 | μm |
| D | 12 | μm |
| Δ | 12 | μm |
| H | 15 | μm |
| ρ | 50 | μm |
| ω | 2 | μm |

Interlocking Structures with Non-Flat Cantilevers

It is proposed to use a modified version of the above interlocking structures, where the cantilevers are optimized not only for a high strength but also to obtain the desired force asymmetry. It is proposed to change the shape of the cantilever from a flat rectangle, to one with a bend. CAD models of the repeating unit cell of the proposed designs can be seen in FIG. 23A. The added bend also changes the conditions in such a way that upon insertion the cantilever will tend to bend outward causing a low push-in force, and upon separation the cantilever will tend to move inwards, and increasing the force required to separate the components. The proposed permanent structure is similar to that of the reusable design proposed herein where a thin metallic film is suspended on a hollow thru-via pillar to the substrate. With the added shape it is necessary to include another parameter for design which is the length of the cantilever that extends down from the top of the thru-via pillar. A cross section of the cantilevers with the labeled parameters can be seen in FIG. 23B. The variable HB shall be used to represent the length that is suspended from the top of the pillar. These rest of the dimensions are presented in Table 10.

TABLE 10
Dimensions for proposed interlocking
structures with non-flat cantilevers

| | | |
|---|---|---|
| L_{C} | 3 | μm |
| L₀ | 11 | μm |
| t | 100 | μm |
| D | 12 | μm |
| Δ | 12 | μm |
| H | 15 | μm |
| H_{B} | 5 | μm |
| ρ | 50 | μm |
| ω | 4 | μm |

The performance of this design was evaluated through the use of FEA, using a solid mechanics module. It was found that the maximum force required to interlock a pair of cantilevers was 2.5 μN, and to separate required a force of 9 μN. This corresponds to a push-in and pullout stress of 8 kPa and 28.8 kPa respectively. A plot of the maximum bending stress versus cantilever tip displacement can be seen in FIG. 23C, and the force versus displacement for a single interlocking cantilever can be seen in FIG. 23D. As seen previously, plastic deformation is expected to occur. This design is the most promising for future work as it gives the desired force asymmetry response.

### Extended Cantilevers for Anti-Vibration, and High Retention

From observation of the geometry of the structures when joined it is evident that while the cantilevers stop the bonded chip from moving away from the substrate, there is nothing to stop motion parallel to the substrate. This is not ideal as it could affect the performance of the device by interfering with the electrical connections. To solve this issue, it is proposed to extend the interlocking cantilevers beyond the square ends as in FIG. 24.

Once the structure snaps through, the extended tabs will keep the cantilevers in contact with the opposing rigid pillar. A diagram showing this can be seen in FIG. 25. Keeping the cantilever in contact with the rigid structures will mean there is a constant force trying to push the chips towards the ideal center position. This is advantageous as wiggling of the chips will not be as severe. This will allow for constant electrical and thermal conduction. Under thermal loading the chips can freely expand and contract, as changes in distances will be taken up by the interlocking cantilevers.

### Designs of Masks for Interlocking Structures

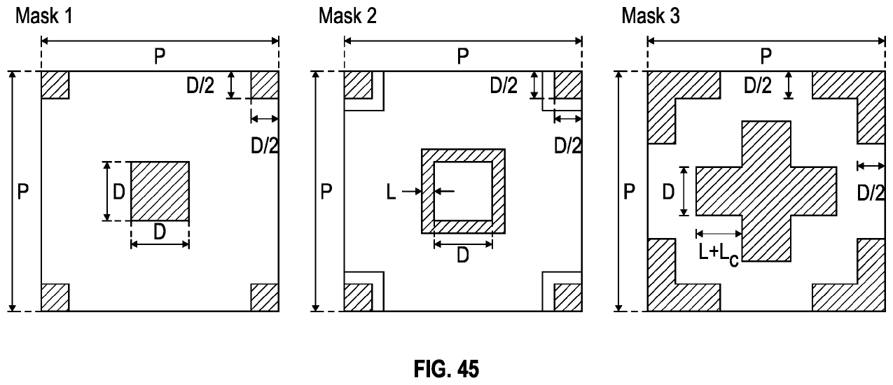

With the dimensions obtained, the photo masks can then be designed. Mentioned previously there will need to be a total of 3 masks for the structures. In the case of flat cantilevers, mask 2 is omitted from the process. Because of the periodic repeating nature, the masks can be shown as simple repeating cells as in FIG. 45.

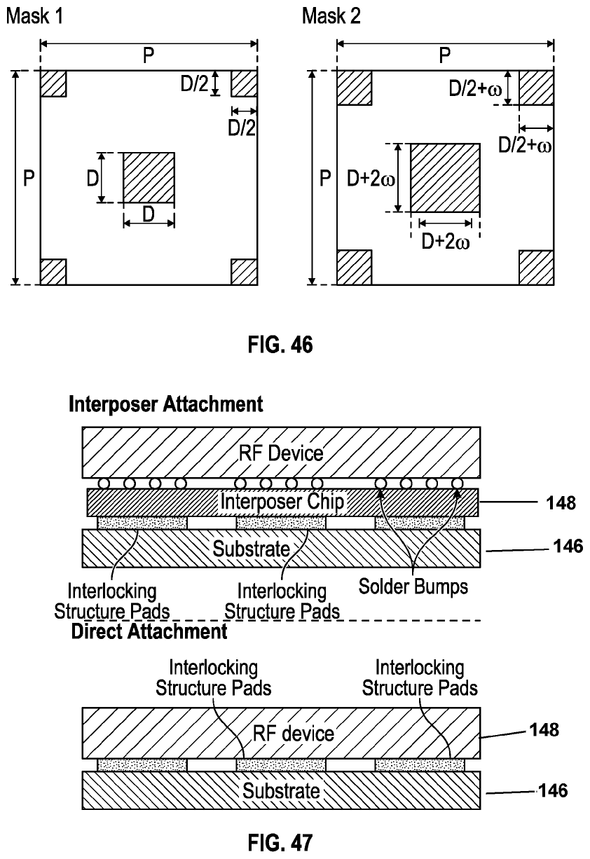

The rigid structures will have the same pitch and pillar size as the compliant structure, so mask 1 can be reused. This means only 1 additional mask is required to form the rigid cantilevers, for a total of 4 masks to produce both the rigid and compliant structures. The masks to produce the rigid structures are shown in FIG. 46.

### Rigid Interlocking Structures

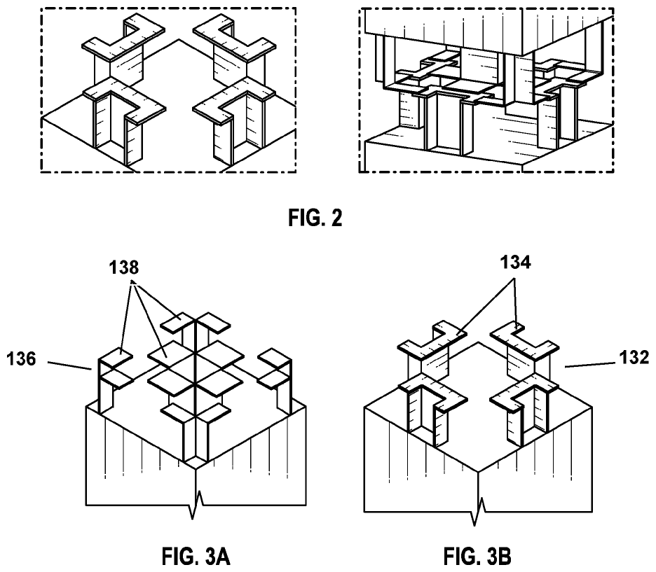

Design of the rigid interlocking structure is similar to that of the compliant structure. The difference is in the shape of the cantilever, now instead of individual ones it is one large structure on the perimeter of the pillar. It is also formed by depositing a layer of metal sufficiently thick that there is no bending. An image of the proposed rigid structures can be seen in FIG. 2. There could be issues if the required thickness is greater than 1 μm, as metal evaporation has difficulty in these thick layers but a process using electroplating could be used instead. The shape of the rigid cantilever was chosen so that in the case of misalignment, there would still be full contact on the compliant cantilever and no torsion would be applied to the cantilever.

The use of rigid cantilevers also has the added benefit of increasing the theoretical bond strength that is possible. The rigid cantilevers can be made much shorter than interlocking ones, as seen in FIG. 2. The rigid cantilevers are ˜4 μm long whereas the bending cantilevers are ˜10 μm to ˜15 μm in length. This decreases the distance between the fixed edges of the cantilevers and thus reduces the area that the cantilevers would take up. Previously it was shown that the bond strength is dependent on the number of cantilever pairs per a unit area.

### Strength and Stability of Thru-Via Structure

All work to this point has been in investigating the strength of the interlocking cantilevers. It was assumed that the thru-vias would be rigid, but it was questioned whether this was the case, or were they going to fail by buckling or tearing. The stress in the structure can be taken to nominally be the force of all cantilevers divided by the cross-sectional area of the thru-via, or σ=F/A where A is the cross-sectional area of the thru-via and is defined as A−4Dt−4t². Using the dimensions proposed, and the maximum force from the simulations of 9 μN, the expect stress is 7.56 MPa which is an order of magnitude smaller than the yield strength of titanium at 140 MPa, so there is no concern about failure. In the future, the structures can be optimized to sustain higher forces by sputtering an additional later of metal into them.

### Strategies for Optimal Structure and Cantilever Designs

With so many parameters to define these interlocking cantilevers it is then desirable to develop a scheme so that the optimal design is found. Optimal means that the maximum force should designed for. Two different approaches were developed, one which is based off the pitch, and the other based on working backwards from the maximum allowable stress. Because of the limitations in manufacturing techniques the sizes of the features that can be made is on the order of 1 μm. So, it would be desirable to work from what is possible to be made. The other method is start from the yield strength of the material being used, and then to work backwards from this value to obtain dimensions for a cantilever wouldn't yield to derive the rest of the parameters.

### Pitch Driven Parameters

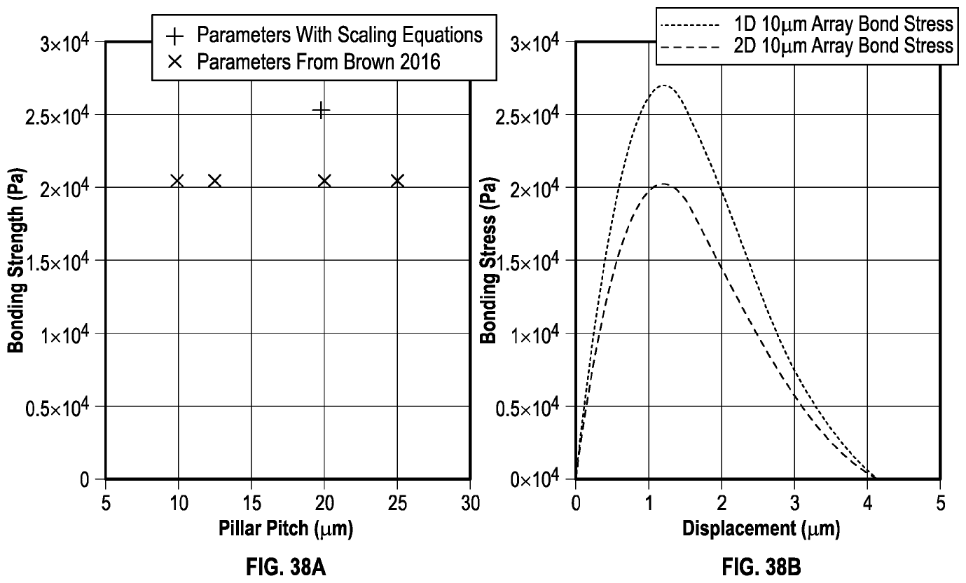

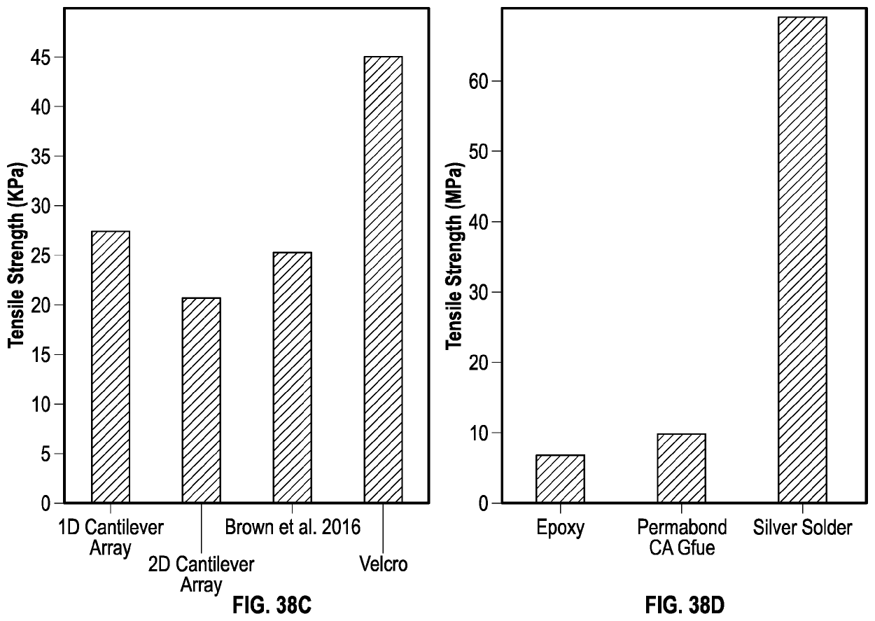

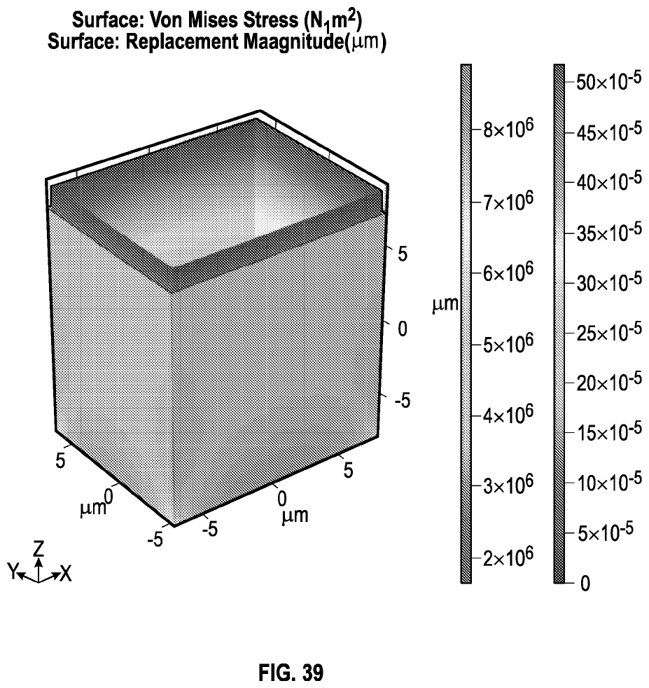

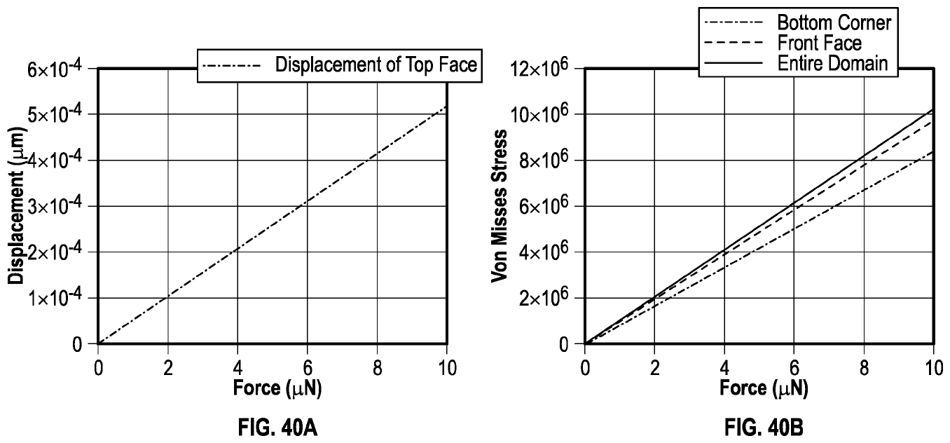

Basing the dimensions based on the pitch driven parameters may be easier for design, but optimizations are needed to determine the best interaction distances, thickness, and number of cantilevers per unit area. While one could choose to seek maximum bonding strength, this would require short interaction distances, thick beams, and the largest possible number of cantilevers per unit area. This would have drawbacks and one will run into issues of bending stresses exceeding the yield and ultimate tensile strengths of the material at the bases of the cantilevers and low misalignment tolerance. Using the scaling relations, the dimensions for several different pitches were calculated for and are presented in Table 11. The pitches were selected because they represent an integer number of unit cells which can fit onto a 100 μm×100 μm pad. All of the cantilever thickness determined with an aspect ratio of 65. The bond strengths for these designs & dimensions are shown in FIG. 38A. To see how the difference in performance between a 1D and 2D structure, the bond strengths for both are shown in FIG. 38B. To see how the presented pitch driven designs compare with commercially available adhesives, the bond strengths are plotted in FIG. 38C and FIG. 38D.

TABLE 11
Parameters for 2D interlocking structures based on pitch

| | Cantilever | Cantilever | Cantilever | Interaction | Bonding |
|---|---|---|---|---|---|
| Pitch | width | Length | thickness | Distance | strength |
| (μm) | (μm) | (μm) | (nm) | (μm) | (kPa) |
| 10 | 2 | 1.88 | 28.8 | 2.5 | 20.4 |
| 12.5 | 3.13 | 2.34 | 36.1 | 3.125 | 20.4 |
| 20 | 5 | 3.75 | 57.7 | 5 | 20.4 |
| 25 | 6.25 | 4.69 | 72.1 | 6.25 | 20.4 |
| 19.8a | 7.4 | 2.2 | 34 | 2.5 | 25.3 |

Surprisingly, it was found that using fixed scaling relations the bond strength remained constant as pitch was increased. The theoretical bonding strength of the 2D array design was also plotted, it shows that improvements can be made to the maximum bonding strength, and changes to the scaling relations can be made. As seen in FIG. 38B, both stress versus displacement curves follow the same general shape of the nondimensional curve. It can also be seen that the 1D arrays greatly outperform the 2D arrays in terms of the maximum bonding strength as would be expected as the 1D arrays have a larger density of cantilevers per area.

### Optimization Scheme for Maximizing Bond Strength of Purely Elastically Bending Interlocking Cantilevers

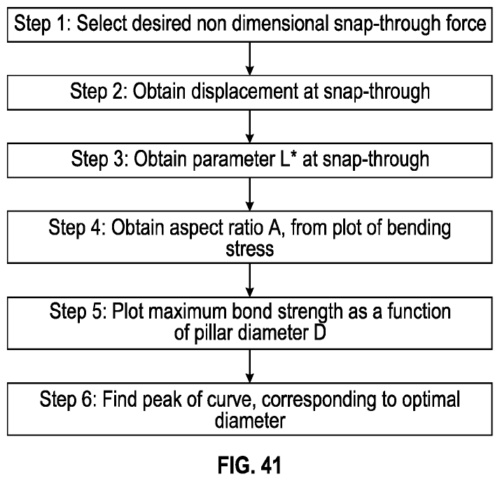

With the elliptic model developed to predict the force versus displacement of cantilevers, it is then desired to adapt it to obtain an optimal design. What is meant by optimal design is a design which has the maximum possible bond strength, while staying in the elastic regime of the material. A process flow outlining the steps to optimize the cantilevers is shown in FIG. 41.

Design begins by first selecting a desired force to displace the cantilevers. In the large-deflection analysis, it was assumed that the cantilevers would always be long enough so that the cantilevers would experience the peak nondimensional force of 0.417. Selecting a nondimensional force before reaching the peak will give similar performance with less deflection and internal stress occurring. In FIG. 42A this is shown where a snap-through displacement is selected at 0.3, which produces a snap-through force of 0.36, this is nearly 80% of the maximum, but importantly is 50% of the displacement of the peak force.

A new nondimensional term L* is then introduced, which is the arc length of the beam which extends from the anchor point to the loading point divided by the distance of the loading point to the anchor point and can be found with Eq. (24a). Another nondimensional term Aᵣ is introduced, it is the aspect ratio and is defined as the dimensionless measure of the total cantilever length to its thickness and is defined by Eq. (24b). This term is important for further analysis and becomes one of the most important parameters that will determine many of the other parameters.

$${L}^{*} = \frac{L}{{L}_{0}} = \frac{L}{{x}_{B}} \qquad ( 24 a )$$

$${A}_{r} = \frac{L}{t} \qquad ( 24 b )$$

Using FIG. 42B, L* can be found with the deflection from FIG. 42A. From FIG. 42B a vertical line is drawn up from the selected displacement the intersection with this line and the plot of L* determines the optimal value. The length L and L₀ can be selected based on manufacturing techniques available and the resolution of the process being used.

This leaves the final parameter be determined which can be found using FIG. 42C. Here plots of stress at given displacements as functions of Aᵣ are plotted. These lines are evaluated at the end angle θ_{B} at a given displacement delta. In the FIG. 42C these lines are shown by (C). The yield strength of the material is plotted as a horizontal line. At the intersection of the stress plots (C) with the yield strength, the minimum Aᵣ is obtained. Selecting an Aᵣ lower than this value will result in the bending stresses exceeding the yield strength and will result in permanent deformation of the structures.

The final parameter to be obtained from pitch ρ and is determined by the sum of the parameters shown in FIG. 3C and can be determined with Eq. (25). These parameters are D, Δ, ω, and L₀. The term D is the width of the pillar that suspends the cantilevers in free space. Related to D, Δ is the width of the rigid pillar to simplify the design Δ will be set equal to D. The term ω is the length of the rigid cantilever that extends from the rigid pillar.

$$ρ = 2 ( {L}_{0} + ω + D ) \qquad ( 25 )$$

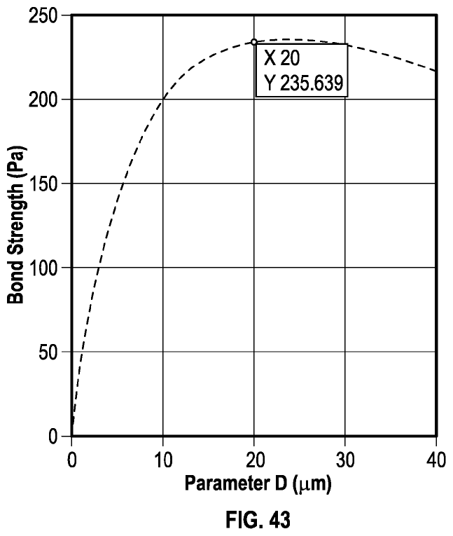

The optimal pillar and beam width D can be obtained by plotting Eq. (25) as a function of D. Doing so will result in a graph that peaks at some value then decrease towards 0 at large values of D. The peak of this graph is the maximum possible bond strength for the given parameters. The bond strength of the cantilevers can be predicted by using Eq. (26), and then plotted in FIG. 43 using the Young's modulus of titanium.

$${σ}_{m} = \frac{{C}_{1} {EDt}^{2}}{3 {{L}_{0}^{2} ( {L}_{0} + ω + D )}^{2}} \qquad ( 26 )$$

From FIG. 43. It can be seen that the plot peaks at a value of 20 μm.

Following these steps, an optimal interlocking structure geometry is obtained. Critically this is done under the constraint that no plastic yielding is to occur. This has great ramifications for design as typically the yield strength of materials used in microfabrication have low yield strengths. Which reduces the strength needed to separate the chips, thus reducing performance. From FIG. 43 it can be seen that the bond strength at the optimal dimensions is 235 Pa, which is very small and may not provide any attachment at all.

It is clear from this analysis that designing interlocking structures that remain within the elastic regime of its material will lead a low performing material. Pure elastic operation is required of patterned surfaces that can be separated and reattached repeatedly, but this comes at the price of adhesion strength. The condition of reworkability can be preserved if the die bearing the compliant cantilevers is afforded some plastic deformation and treated as a single-use component. In this case the surface of patterned rigid structures enables attachment, removal, and replacement of components. Following the design and optimization strategy above while allowing plastic deformation, a design for interlocking flat cantilevers shows the possibility of significantly better performance. First, L and L₀ are selected to be 10 μm and 8 μm, respectively. This gives L*=1.25, which means it will reach the maximum C₁=0.417 and Aᵣ=100. These parameters produce a snap-through force per cantilever of 0.81 μN, which leads to a bond strength of 6.3 kPa, which is a theoretical maximum comparable to the performance of commercially available hook and loop materials. This shows that these micro interlocking structures have great promise in improving integration methods of chips, but more work is required to better refine their design through improved modeling of plastic behavior coupled with physical testing of the metallic films that will comprise these structures.

### Alternative Cantilever Geometries Explored for Maximal Stress Reduction and Force Asymmetry

One proposed alternate design for interlocking cantilevers is to use curved cantilevers. Curving of the cantilevers can be achieved by depositing two materials with different coefficients of thermal expansion (COTE). Sputtering and evaporation will heat up whatever the metal is being deposited onto. First depositing a material with a high COTE and then a material with a low COTE would mean the first material would contract more that the second material and inducing curvature as can be seen in FIG. 33, depicting both a cross-sectional view and an isometric view of a unit cell of a 2D structure array. Thermal induced curvature can even be seen where the cantilevers are slightly curved upwards. The previous analysis above derived for beams with curvature can then be used for these cantilevers, albeit with modifications to account for the inhomogeneous cross-section. Further exploration into this proposed design is reserved for future work. Inducing this kind of curvature for the designs presented herein could further reduce the insertion force and increase the retention force.

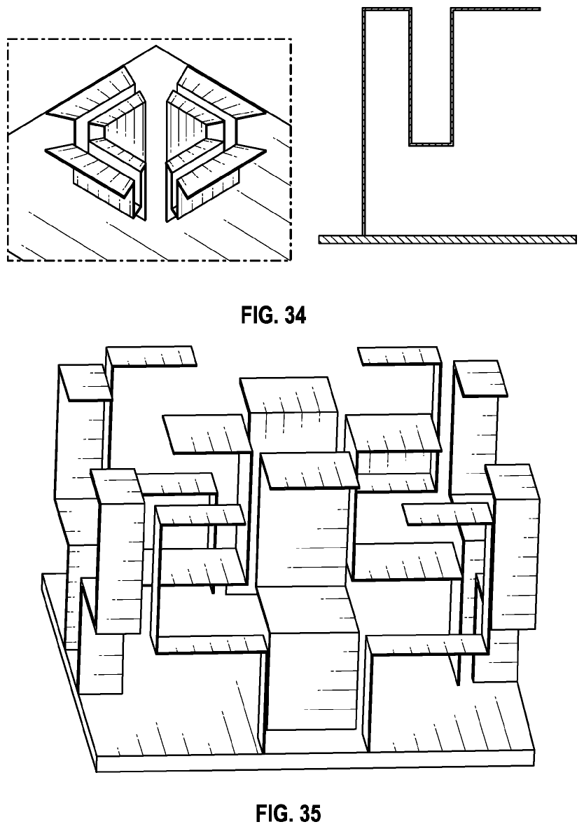

When it became clear that bending stresses exceeding the yield strength of the material, alternatives to the flat cantilever were explored. Taking inspiration from springs, and the corrugated design, it was proposed to change the direction of the corrugations from being parallel to perpendicular to the length of the beam. This produces a serpentine like design as shown in FIG. 34.

Building off of this idea of using 3D shaping on the cantilevers, from the above design it was then suggested to build the cantilevers vertically. Such that cantilevers bends and continues upward as in FIG. 35. Interesting in shape, from simulations it was found that this structure performed worse than expected as the very tops of the cantilevers would tend to move inwards resulting in a high joining force and a low retention force. From this insight the proposed design was then developed. The model shown in FIG. 35 is not ideal as it would require many more masks to fabricate making it not ideal from a manufacturing standpoint.

### Implementation Methods of Interlocking Structures

Several options are open when implementing the use of these interlocking structures, first the direct patterning of the structures onto both the micro device and onto a substrate, second is to use an interposer chip as an intermediary between a chip, device, or substrate. Direct patterning of the interlocking cantilevers can be done directly onto existing electrical pads where electrical connections are desired, and onto the entire surface to retain the component.

This method is favorable when used with prototype chips, as the structures can be produced with the same fabrication methods as the devices themselves. Producing the structures onto a premade device may prove to be difficult, which is where an interposer chip might be used. Interposer chips are a common method of joining micro devices, usually a chip with pads with electrical traces. This can be done in two methods, one a direct soldering to a device, and the other using it to connect to devices which have interlocking structures deposited on them.

It is proposed to implement the interlocking structure in two ways. One way is to build the structures directly onto both the device and assembly substrate, and the other is to use an interposer chip as an in between the device and assembly. This can be seen in FIG. 47. As discussed previously the permanent structures can be deposited onto the assembly substrate and the device has the bending cantilevers. The interposer chip could have the permanent structures deposited to the top surface to allow interfacing with the device. To interface with the rest of the assembly on the bottom of the chip, solder bumps are used to provide mechanical attachment and for electrical connections. The interposer chip is needed when the assembly is premade or is made from components which make use of solder bump grids. This will greatly allow for easy attachment during prototyping. During final production the permanent structures can be produced directly onto the assembly.

### Physical Testing to Verify Analytical Studies and to Give Estimations on Expected Force Including Plasticity

To verify the elliptic models, several tests were performed using macroscale manufactured cantilevers. To show that the model dealing with curved cantilevers are correct, a curved cantilever was tested in a similar manner to the flat cantilevers. In both flat and curved cantilevers, they were fabricated from stainless steel and aluminum. Stainless steel can sustain large deflections without permanent yielding and will serve as a good way to validate the models and the aluminum was selected to see how plasticity would affect the performance of the cantilevers as it was expected to occur in the flat cantilevers.

The analytical modeling of bending stress showed that plastic deformation is inevitable. The expected performance of the interlocking structures presented earlier were all done under the assumption of elastic bending only. Therefore, the actual performance will be lower than the expected. The question then becomes lower by how much? To answer this, a series of physical tests at the macroscale are performed with the same geometry as the presented designs. This physical testing will allow for estimation of the true performance of the structures. Analytical modeling, and computational modeling were considered before physical testing, but as shown previously the analytical model became incredibly difficult and required an iterative approach to solve it. Simulations were performed, but it became clear it would be more difficult to perform as often the simulations would not converge on a solution. The models also require properties like the tangent modulus and hardening functions. These properties are difficult to find for bulk materials, may require experimental determination, and may vary from bulk values for microscale and nanoscale materials, due to dimensional constraints.

Analytical models were developed and were used mainly for the design of the flat interlocking cantilevers for heterogeneous integration as well as the development of the large deflection model for hooks and curved cantilevers. Simulations were performed for the interlocking cantilevers, first as another method of verification that the analytical large deflection model was correct, and secondly to develop geometries of interlocking cantilevers that were difficult to model analytical like the presented non-flat cantilevers. The experimental data for the hooks is to verify that the analytical models for the large hook deflection is correct. Experimental data gathered for the non-flat cantilevers is to show that the simulations could accurately predict force versus deflection for this geometry, which would give confidence when designing the cantilevers for microfabrication. The non-flat cantilever designs are much more difficult to model analytically so the testing/simulation program was used, and it was not known how accurate it was, so a test on the macro scale would show if the testing/simulation program could solve such complicated geometry. The final set of data gathered was a test which was developed to see the affect that plasticity would have on the final microfabricated interlocking cantilevers. The current analytical models only account for elastic bending, and so are not able to capture the effect of plasticity. This physical data will be used to develop the models further and will qualitatively give insight in what we could expect from the final microfabricated interlocking cantilevers.

### Experimental Test Setup

The specific analytical models being tested are the nondimensional force and displacement models. From the theory the cantilevers are held at a constant distance away from the applied force. The cantilevers then move past until the end is reached and then the cantilevers snap past.

The clamp on the base plate is measured from the center point of the base plate. This number is to vary based on the interaction distance being tested. The interaction distance is to be varied in the range of 2″ to 4″, in increments of 0.5″. The dimensionless value of L* is to be held constant at 1.25. That is the length of the beam is 25% longer than the interaction distance. Doing so will mean the force versus displacement should reach the theoretical maximum value.

Samples are to be fabricated from thin sheets of metal on the order of ˜0.016″ thickness. The samples are to be cut into rectangles that are 0.5″ wide, and 5″ long. The metal to be used should deform plastically. For each L* value 3 tests should be run meaning a total of 6 samples will be needed for each value of L*. The dimensions of the different aluminum cantilevers are presented in Table 12.

TABLE 12
Dimensions of cantilevers made from aluminum to test plasticity

| Cantilever | Interaction | Aspect |
|---|---|---|
| length L | length L₀ | ratio Aᵣ |
| 2.8125″ | 2.25″ | 174 |
| 3.125″ | 2.5″ | 193 |
| 3.75″ | 3″ | 232 |
| 4.375 | 3.5″ | 271 |
| 5″ | 4″ | 309 |

Because of the symmetry of a flat cantilever that does not have angling, there is no need to do up and down trials as they would be the same.

The brass samples were manufactured to have the same aspect ratio Aᵣ as the aluminum cantilevers. Doing so would mean that once the results are normalized the effect of different yield strengths and hardening functions can be directly observed. The brass samples were fabricated from sheet stock that measured (mm) in thickness. The lengths and interaction distances for the brass cantilevers are presented in Table 11.

TABLE 13
Aspect ratios and lengths for cantilevers produced from brass

| | Cantilever | Interaction |
|---|---|---|
| Aspect | length | distance |
| ratio Aᵣ | L (mm) | L₀ (mm) |
| 174 | 44.5 | 35.6 |
| 193 | 49.4 | 39.5 |
| 232 | 59.4 | 47.5 |
| 271 | 69.4 | 55.5 |
| 309 | 79.1 | 63.3 |

Like the brass, the copper cantilevers are manufactured to have the same aspect ratio Aᵣ as the aluminum cantilevers. The copper cantilevers were fabricated from sheet stock that measured 0.025% (0.63 mm) in thickness, and the resulting lengths and interaction distances are presented in Table 14.

TABLE 14
Aspect ratios and lengths for cantilevers produced from copper

| | Cantilever | Interaction |
|---|---|---|
| Aspect | length | distance |
| ratio Aᵣ | L (mm) | L₀ (mm) |
| 174 | 109.0 | 87.2 |
| 193 | 121.0 | 97.3 |
| 232 | 146.2 | 116.9 |

### Performing the Experiment

From the interaction distances listed in Table 12 the base plate is adjusted to match the interaction lengths starting with 2″. The interaction length is measured with digital micrometers and is measured from the base of the fixed cantilever to the point that would be pressing down on the cantilever. This is repeated for the interaction distances listed in Table 13, and Table 14. For each interaction length a total of 10 cantilevers are fabricated to the proper length. Where the length is simply 1.25 times the interaction length. The cantilevers are fabricated slightly longer than the length, so that they can be clamped in the specimen holder. The cantilevers are cut roughly 0.5″ longer than the required length, then the end is measured away from the base using digital calipers.

Once the cantilevers are clamped in the sample holder and adjusted the testing begins. The crosshead is adjusted so that the bar that presses onto the cantilever is nearly touching the cantilever. The test can then begin, where the crosshead moved down at a constant rate of extension. The test ends automatically once the cantilevers snaps past the bar. The data is then exported and analyzed with MATLAB.

### Plasticity in Flat Cantilevers

It is evident that the yield strength is perhaps the most important factor that holds back the performance of the interlocking structures. The elliptic model developed does not incorporate this and plasticity is not considered. Simulations were not reliable and finding material properties that deal with plasticity was challenging. Therefore, tests on the macroscale were explored for give insight into effects on the performance of the interlocking structure due to plastic bending. This physical testing can also be used in the future to further refine the analytical models, but that is out of the scope of this work and only a qualitative comparison was desired.

In parallel with the physical work exploring plasticity, work was performed using the testing/simulation program and utilizing its built-in modules dealing with plasticity. As metals undergo strain in the plastic regime the stresses stiffness of the material increases. This means that there is no longer a linear relation between stress and strain increasing the difficulty in computation. This plastic deformation is compounded by the fact that very little data exists on the plastic stress-strain of nanometer thick layers of microfabricated metallic films. The studies that have been done that have explored these thin metallic films have discovered that these films are actually much stronger than in their bulk form. This has good implications for the overall goals of this work in producing interlocking cantilevers, but it means that the models have been developed are expected to have significant differences between what is expected and what will be measured. It also has bad implications because while the films may be stronger it is also possible for the films to become more brittle, failing at lower displacements.

The tests performed utilized thin strips of various metals clamped in place while the crosshead of the tensile tester pulled up on the free end of the cantilevers. The metals used varied from stainless steel to aluminum, brass, and copper. These materials were chosen because of they are readily available. More importantly, these different materials have different values for their yield strength. The Young's Modulus is not important, as nondimensionalizing the force will remove this dependency. As it was shown previously that in the case of purely elastic bending the elliptic model gave good agreement. Any deviation between the analytical model and physical data will be due to plastic deformation. This means that the yield strength, and plastic hardening of the material is the cause of the deviation. Using metals with different values for yield strength and plastic hardening will allow for further refinement of the analytical model and will give a rough estimate of a lower bound of the performance of the final fabricated micro interlocking structures.

### Testing Plasticity of Flat Cantilevers

It was shown experimentally that the elliptic model derived for flat cantilevers was able to predict the force versus displacement for flat and angled cantilevers. The cantilevers remained completely in the elastic range. As such, no additional work is needed to prove it, but the setup was replicated anyways to show that we could obtain the same result. This test showed good agreement with the model and the data collected previously.

Earlier it was shown analytically that the yield strength of the material would be the limiting factor of the bond strength of the interlocking cantilevers. The yield strength of most engineering materials is less than 1 GPa, as in Table 8. Therefore, plastic deformation is inevitable. In the tensile curve of most engineering materials, once the material reaches the yield point the stiffness of the material is drastically reduced, meaning for any given displacement during plastic regime, the rate of change of stress is lower than during the elastic regime. Because of the stiffness in the plastic regime, it can be inferred that the force to displace the cantilever in the plastic regime will be lower. This would mean that the performance of the interlocking structures will also reduce. The experiment was modified by switching from a cantilever-cantilever contact to a single cantilever contacted by a rigid probe. This experiment replicates the geometry of the designs where a single cantilever is deflected by the rigid interlocking structure. In the experiment there is a 3D-printed solid block pushing down on the cantilever. This was used because there had been a concern that the non-zero diameter of the stainless steel rod in the previous test would contribute to error by changing the distance between the cantilever and loading point. The experimental method developed here provided approaches as misalignment of the cantilevers and base were a larger source of experimental variation.

After completion of the test, it was clear that plastic deformation had occurred. Before it was completely flat, and after at the base of the cantilever there was a clear deformation. Further processing and information can be extracted from this image, as an image processing software or other implementations of image tracking code can be used to find when plastic deformations begin. The magnitude of the permanent bend can be determined using this method. One of the first things that can be done is to see if there is a uniform curvature. An image of a stainless steel cantilever can also be overlayed with the same aspect ratio to determine how much the shape deviates from a case where only elastic bending occurs.

Data Gathered from Flat Cantilevers

This section details the data gathered from the physical testing of cantilevers undergoing plastic deformation. This is done as previously it was shown that the elliptic model was able to predict the force versus displacement very well for a cantilever that undergoes elastic deformation only. Here cantilevers were fabricated from aluminum, brass, and copper. This series of tests were performed so that it can be seen how plasticity would affect the performance of the microfabricated interlocking structures. As mentioned previously, the elliptic model only accounts for elastic bending and plasticity would greatly increase the complexity of the model. Initial simulations were found to be unreliable as often the simulations would not converge. These issues make physical testing a good way to gauge the importance of plastic deformation.

Data for Flat Cantilever Fabricated from Aluminum

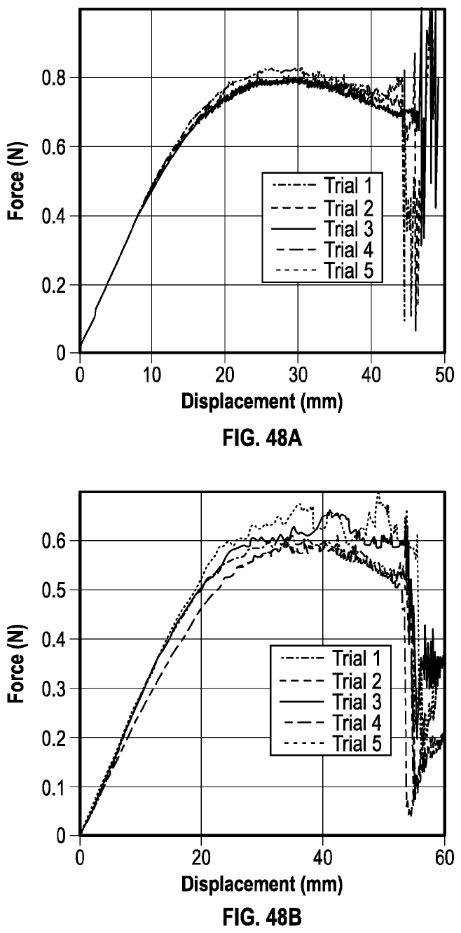

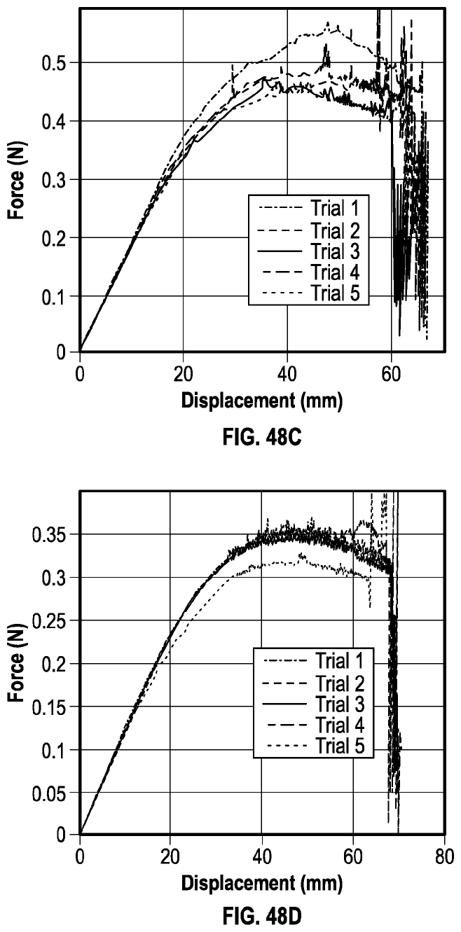

The data for plastically deforming flat cantilevers can be seen in FIG. 48 and is organized in terms of increasing interaction length corresponding to an increase in the aspect ratio.

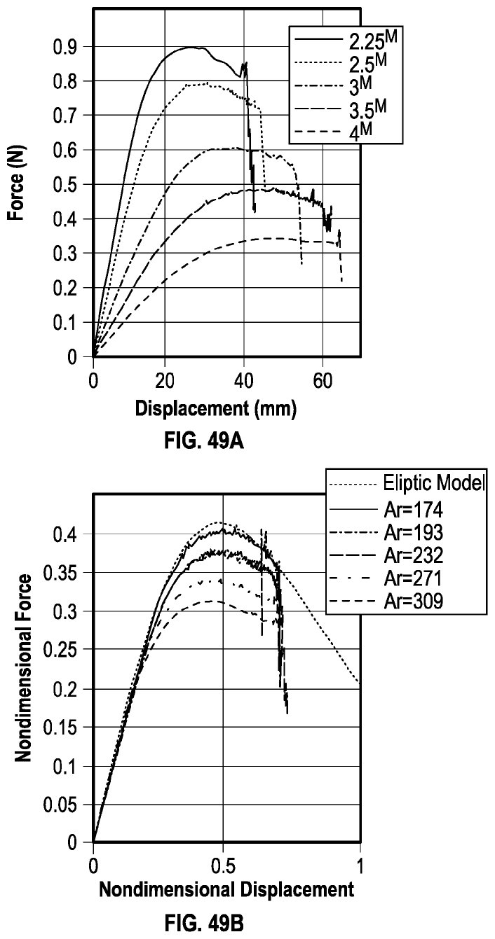

The data from FIG. 48 is averaged and then plotted in FIG. 49A, this makes it easier to see how the force changes with the aspect ratio changing. This is not very useful in seeing how the force deviates from the elliptic model. The data is then nondimensionalized and can be seen in FIG. 49B. From the figure it is clear that the as the aspect ratio decreases the normalized force also decreases. From FIG. 49B it can be seen that the peak of the nondimensional force decreases as the aspect ratio decreases. The aluminum used was 3003 H-14 half temper and the Youngs modulus was 68.9 GPa.

This data gives a rough idea of what can be expected in the real microfabricated samples, but further testing with other materials will be needed to build a better model of what is occurring. With plastic deformation, the yield strength, and work hardening function, and tangent modulus must all be known to create a proper model and is reserved for future work. More data must be collected to verify these results as strangely in FIG. 49B the 232 and 309 aspect ratios produce roughly the same curve, but the 271 aspect-ratio matches very closely to the elliptic model.

Data for Flat Cantilevers Fabricated from Brass

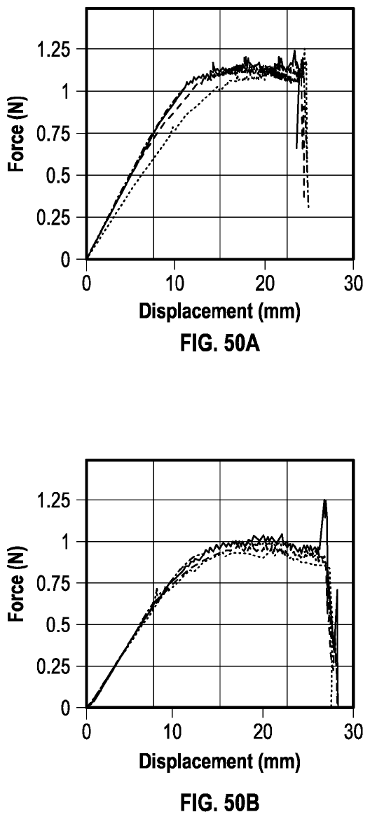

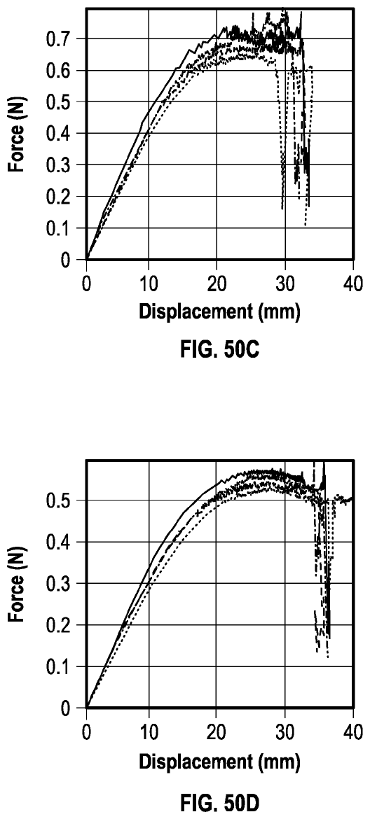

The data from four of brass cantilever tests are presented in FIG. 50.

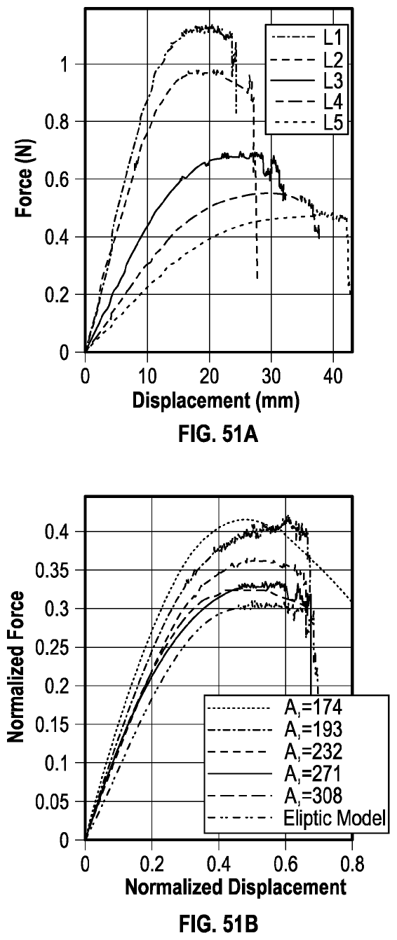

The averages of all 5 are plotted in FIG. 51A, which are then normalized and then plotted in FIG. 51B. For analysis, the Youngs modulus of the brass was taken to be 125 GPa.

Data for Flat Cantilevers Fabricated from Copper

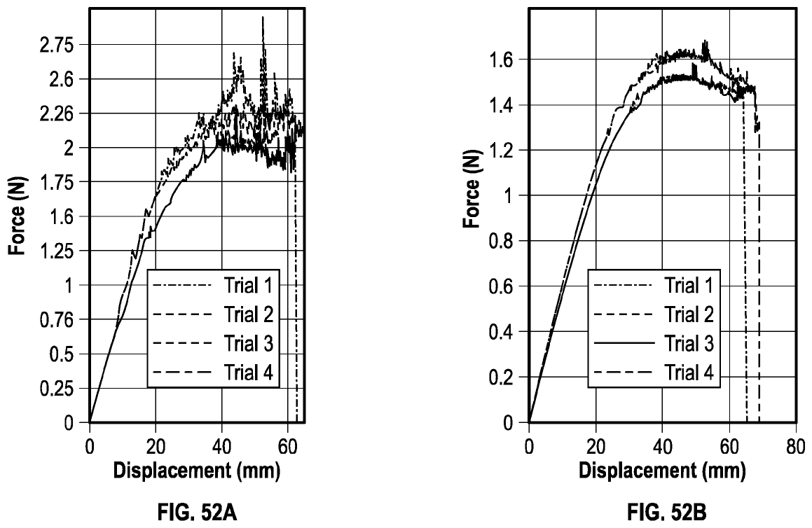

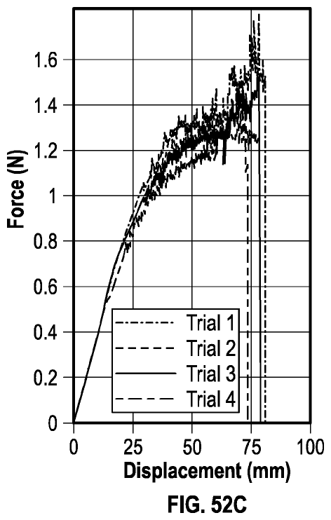

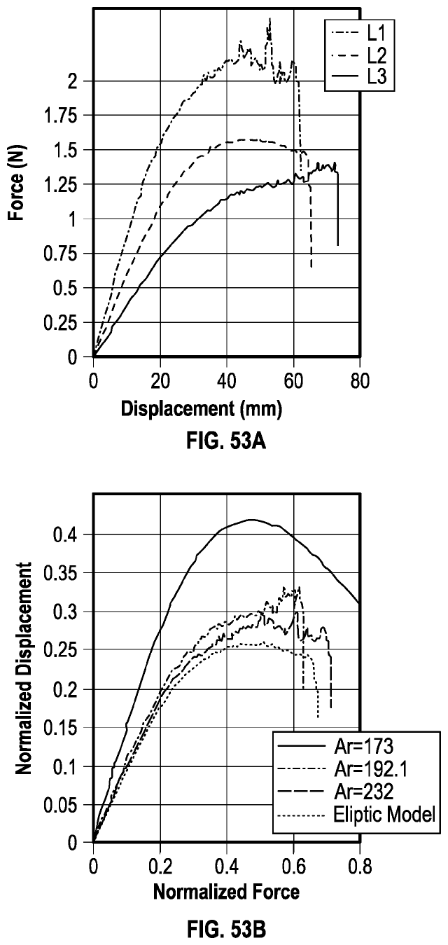

Due to a lack of materials, only three aspect ratios were tested with copper cantilevers. For each of these aspect ratios, only 4 cantilevers were made. This data is presented in FIG. 52. The averages of the trials are plotted in FIG. 53A then normalized in FIG. 53B. For further analysis and normalization, the Youngs modulus was taken to be the 110 GPa using a table of known values.

### Physical Testing of Macro Scaled Non-Flat Cantilevers

The non-flat cantilevers presented herein are difficult to model and especially analytically. As with the flat and curved cantilevers, it was decided to test how accurately the simulations could predict the force for the non-flat cantilevers. This could give a good estimate of what to expect for microfabricated non-flat cantilevers. Using the same test equipment and test procedures for the flat cantilevers. From the same material as the flat can curved cantilevers, the cantilevers are bent into the final shape. The dimensions for the non-flat cantilevers are shown in Table 15. The dimensions labels are the same as those in FIG. 23B.

TABLE 15
Dimensions used for non-flat cantilevers

| Dimension | Value (mm) |
|---|---|
| L | 15 |
| Lc | 50 |
| Hb | 26 |
| t (stainless steel) | 0.11 |
| t (aluminum) | 0.42 |

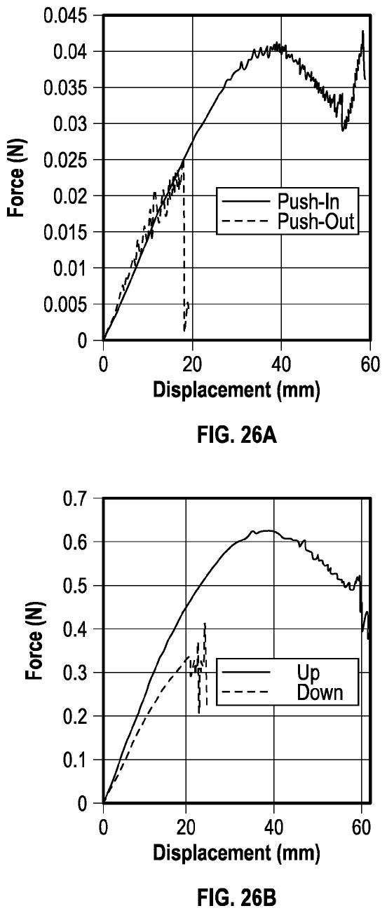

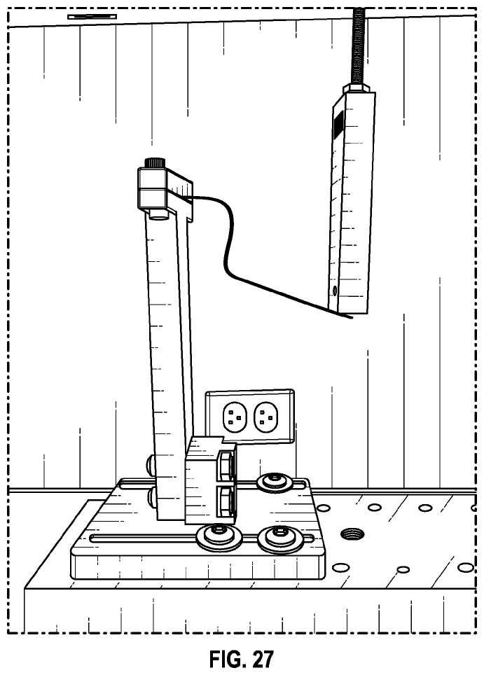

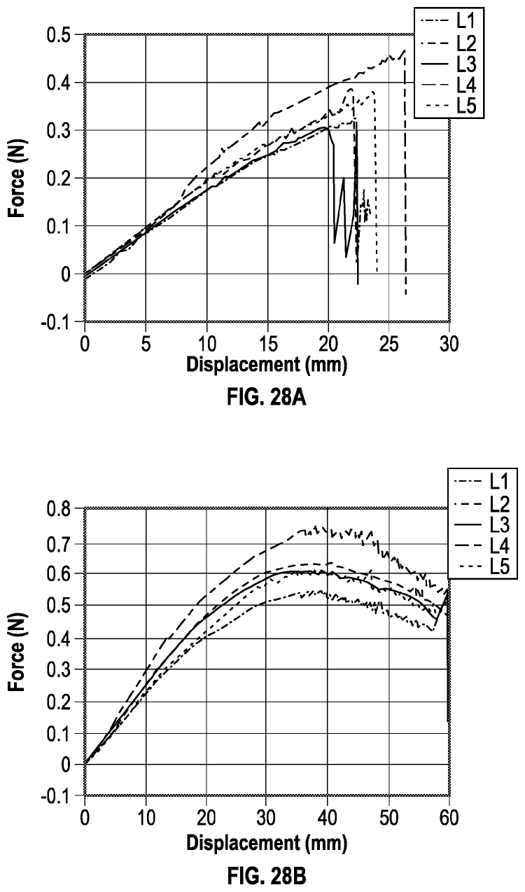

The non-flat cantilevers were tested in the tensile tester in both ‘Up’ and ‘Down’ configurations. The ‘Up’ configuration models the structure being pulled out of place. That is the structures were joined together, and now the structures are being separated. The ‘Down’ is the configuration is meant to model the structures being pushed together. The trials from the stainless steel non-flat cantilevers were averaged and plotted in FIG. 26A.

It is apparent from the stainless steel non-flat cantilevers that this configuration leads to the desired force asymmetry where the push-in force is less than the pull-out force. Surprisingly the pull-out force is only twice the push-in force. In the simulations, the non-flat pull-out force is over 3 times that of the push-in force. This could mainly be due to plastic bending. As seen previously in the flat and curved cantilevers the maximum force is significantly less than what is predicted in the elliptic model. The plot of the data for the aluminum non-flat cantilevers can be seen in FIG. 26B. Interestingly, the up test is roughly twice that of the down test similar to the stainless steel. This was not expected as shown previously plastic deformation decreases the maximum force.

Further experimentation is needed for the non-flat cantilevers with extended tabs. This is because it was found that the testing/simulation program once the cantilever snapped past the rigid structure the cantilever would teleport through the rigid structure and then the simulation would fail. A new test and apparatus would have to be produced, as the extending tabs changes the geometry of the problem drastically by changing where loading occurs, and changes from a sliding contact condition to a point end loading for the case of pull-out.

### Verification of Elliptic Model Developed for Curved Cantilevers and Hook and Loop Materials

The study of curved cantilevers is of great interest to this work as in the previous work by Brown et al. under examination by electron microscopy the cantilevers were slightly curved. This was caused by residual stresses induced during ALD fabrication of Al₂O₃—W layers and in turn stiffened the force versus displacement behavior from what was expected from a simple flat cantilever.

Physical testing was performed to verify that the elliptic model developed for the cantilevers is correct. Although the work was developed for a hook with the sliding condition and in the angle of the arc is in the range of π<θ<π/2, the model can be easily adapted for the previously considered geometry which utilizes a bimetallic cantilever to induce a curvature.

As with the flat cantilevers, the curved cantilevers were fabricated using the same stainless steel and aluminum. Although this time, there the cantilevers are formed into arcs by bending the flat samples around a round mandrel. In this case the mandrel is a round piece of stainless steel. The final dimensions were not planned as we do not have data or models to drive this. Rather final shape was used to predict the force, as opposed to the flat cantilevers where the dimensions were selected beforehand and then fabricated to those dimensions. The resulting radius of curvature was then measured and used in the calculations to predict the force versus displacement.

Procedurally the test for the curved cantilevers is nearly identical to that of the flat cantilevers. With the known radius of the cantilever, the specimen holder is then placed the exact distance away from the center of the plate. Because the hook does not yield and springs back the same hook is reused and tested multiple times. Curved cantilevers made from aluminum were also tested to see how plasticity would affect the performance.

Data from Physical Testing of Elastic Curved Cantilevers

The data from the 10 stainless steel hook trials are averaged and then plotted along with the elliptic model. Because of manufacturing tolerances and difficulty in measuring the radius accurately the elliptic model was calculated with the known radius of 43.5 mm±1 mm. This shows that a small change in the radius has a considerable effect on force at higher displacements. It is evident that the elliptic model gives good agreement with the physical data across the entire range. The physical data shows that the hook snaps through further than what is predicted by the elliptic model and is due to manufacturing the hooks longer than a half circle, as well as the very end of the hook being still in contact with the horizontal bar pulling up on the hook. From this it is evident that the elliptic model for curved cantilevers was able to predict the force versus displacement very well. The Youngs modulus for the stainless steel was 200 GPa.

Testing of Hooks Fabricated from Aluminum

For the cantilevers produced from aluminum, two different widths were used. That is the width of the cantilever out of the page were different. This was done to get verify that only the width does not affect the shape of the force versus deflection curve and that it only changes the scaling of the maximum force. One groups of cantilevers were 12.7 mm wide and the other group where 19.05 mm wide. The aluminum used was 3003 H-14 half temper and the Youngs modulus was 68.9 GPa. After bending, it was clear that there had been plastic deformation as it was no longer circular throughout the entire length.

### Tensile Data of Aluminum Hooks

It was noticed from testing of the curved aluminum cantilevers that the plastic deformation greatly reduces the force needed to further deform the cantilevers in an apparent plastic softening behavior. This would be expected as stiffness of the material decreases as plastic deformations continue. On inspection of both the actual cantilevers deviate greatly, the maximum force being approximately half of what is expected from the elliptic model. One thing to note is the behavior where the force does not peak rather hitting an asymptotic limit like in the elliptic model. Another deviation between the two is that the 12.7 mm wide cantilevers will begin to deviate from the elliptic model at a lower displacement, which could be due to some systematic error in the testing or manufacturing of the cantilevers.

### DISCUSSION

Major Issues Remaining with Interlocking Cantilevers

Several issues with this technology must be addressed for it to be practical. Chief among these is the magnitude of the internal stresses in the material when the cantilevers are undergoing deflection. From the stress analysis presented above it is clear that the yield stress is quickly exceeded for most materials. New designs which are far more resistant to plastic deformation are needed. Ideally for a given thickness of cantilever, the maximum local curvature can be solved for so that the material does not yield. From the numerical and analytical stress analysis presented above it is clear that the yield stress is quickly exceeded for most materials.

As shown previously, the maximum bending stresses that develop in the cantilever are a major concern because they can far exceed the yield strength of the material and permanent deformation would be expected. Plastic deformation would both constrain the methods and theories presented, as well as impact performance of the interlocking structures by cantilevers breaking off on insertion or through fatigue wear when used in reworkable designs. Methods to mitigate this will have to be further developed as currently the only way would be to reduce the thickness of the beams, which would reduce maximum bonding strength.

Residual stress effects in manufactured interlocking cantilevers have an impact on the performance of the interlocking structure. Experimentally it was shown that the cantilevers required much more force than expected to displace a certain amount. Under an SEM it was found that the cantilevers were not perfectly flat, instead taking on a bowl like shape. This difference in geometry between actual and expected is believed to be where the error between experimental and theoretical arises. A phenomenon which arises in materials at nanoscale lengths is an apparent size effect, where the stiffness and yield strength are much higher than what would be expected in a macroscale bulk sample of the same material.

### Reworkable Joints & Permanent Joints

Prototyping of microchips means that there are situations where it would be favorable to change components mounted to a substrate. This imposes a condition where the interlocking structures must not be deformed permanently. It also suggests that the force required to join components should be the same as the force to separate.

The use of flat cantilevers with no 3D reinforcing, and horizontal angle at the base would be needed for this, as the force would be symmetric for pull-in/pull-out. The aspect ratio would also have to be very large, at least ˜100, this comes with the downside of having a low bond strength. In the case of a permanent joint, exceeding the yield strength may not be as much of a concern. Effects such as cold welding could play an important role in the feasibility of this technology, these regions could increase the amount of heat transfer and electrical conductivity.

### Thermal Effects

High Thermal Loads, and High Heat Dissipation Requirements Lead to challenges in the reliability of devices. With high temperature differences, combined with materials which have different coefficients of thermal expansion leads to high thermal stresses which develop and can cause components to “pop off” of the substrate. Interlocking structures have an advantage over traditional adhesives because they are not fixed in place, this means they do not significantly resist movement parallel to the surface, so thermally induced stresses are significantly lower. Future work in thermal analysis can be done to determine the stresses that develop due to differences in thermal expansion between devices, combined with the large changes in temperature.

Application to RF devices

One area where this technology could be used is in RF applications. A typical problem in RF microelectronics components is the high heat that needs to be dissipated by the devices, and issues that stem from wire bonds used to connect chips to peripheral devices. RF devices typically operate at high frequencies on the order of GHz. Attachment methods like wire bonds are not ideal for this as the signal can become degraded, and the wires can have interference issues being closely packed next to one another.

High thermal loads and high operating temperatures combined with differences in thermal expansion coefficients between different components and substrates lead to problems in epoxies which hold them together. The device and substrate will typically be made of different materials and will have different coefficients of thermal expansion. Increasing the temperature substantially means the difference in thermal expansion is large. This leads to issues like the epoxies breaking and the chips falling off. Having the chips not rigidly connected means they can expand and contract without having to worry about fracture from thermal expansion.

RF devices are also seeing the use of materials like Gallium Arsenide, and Gallium Nitride. These semiconductors are difficult to work with because they do not bond well with other semiconductors. Mechanical retention means any material will be able to be joined without worrying about chemical adhesion.

### Discussion of Physical Testing of Macroscale Flat Cantilevers

For the physical testing of the flat cantilevers undergoing plastic deformations, it is clear that there is a considerable deviation from the ideal elastic bending, and the lowest aspect ratio. In the plots of normalized aluminum and brass cantilevers in FIG. 49B and FIG. 51B respectively, the cantilevers manufactured to have an aspect ratio of 174 peaked at a nondimensional loading value of 0.3, which is ˜72% of purely elastic bending. In both the aluminum and brass, the highest aspect ratio produced a peak nondimensional load of ˜0.38, which is ˜90% of the purely elastic hook. Strangely, once the data was normalized one of the aspect ratio curves would not follow the trend where increasing aspect ratio increases peak force. It would be expected that there would be a trend where the data should match the analytical model more closely as the aspect ratio increases due to the lower stress. This shows that the analytical model is not able to fully capture the effects of plasticity. With decreasing aspect ratio, the bending stress along the cantilevers increases. Because the stiffness of the material during plastic deformation is less than the stiffness during elastic bending, the force to push down decreases which is reflected in the data.

For the three trials of copper cantilevers, the peaks of the nondimensional force all were ˜0.3 again ˜72% of purely elastic bending. This result is similar to that of the aluminum and brass results. This test could be improved by testing more cantilevers, as currently there is a small sample size of four cantilevers for each aspect ratio. Testing more cantilevers will give better confidence of the average.

From this series of tests with plasticity, a rough estimate can now be made for the final performance of the microfabricated interlocking structures. That is, it is expected that the interlocking structures will be upwards of 70% of the ideal maximum, but with the selected aspect ratios, that estimate could be pushed higher to ˜80% of the ideal maximum. While this is still an estimate, it is better than the alternatives from analytical and computational modeling. The analytical approach is very challenging, and while theoretically possible has still not been fully tested. The computational approach was also challenging as often times it would not converge and the material properties dealing with plasticity were difficult to find meaning that the results would have an additional error on top of the error that one would expect from a numerical approach. This work dealing with physical testing to get around limitations in modeling approaches to plasticity is expected to be written up as a conference paper, once more reliable data can be obtained. Factors like friction were neglected in the formulation of the model for cantilevers, this would have an effect on the difference between the model and data. The effects of friction can be clearly seen in the raw data where at the peak of the graph, the force data becomes very jagged and not very smooth. This is caused by the cantilevers slipping, introducing this noise into the data. The model should be refined to include this, as friction will be present in the microfabricated interlocking structures.

### Discussion of Curved Cantilever Modeling and Results

Hook and loop materials were the inspiration for the microfabricated interlocking structures which were developed in this work. From a search of literature regarding models for hook deformation, it was found that force versus large deformation models for hook and loop materials did not exist previously. It was then thought that the models developed for the interlocking cantilevers could be adapted to model hook and loop materials. After the model was developed, and a theoretical force versus displacement curve was obtained, physical testing was performed to verify that the models were correct. Physical testing had indeed shown that the models were correct. The most interesting part of this work modeling hooks, it was found that all the parameters for hook and loop materials apparently are linear functions of the nondimensional displacement which allowed for linear fits, and a simple equation based on these fits for further calculations. This work is a great contribution to the field of mechanics, with great utility however it can still be improved. In the setup of the geometry for this problem, only the curved section was solved for. This model could be extended by accounting for the straight section. This model is also only the 2D planar case, further work could be done which could account for a cantilever that bends out of the page.

### Heterogeneous Integration

The impact of self-interlocking structures on nanoscale and microscale designs will enable greater interfacing and adaptability of sensors within microsystem packaging. Such 2D nanomaterials as graphene or boron nitride could be used to achieve mechanical bonding of atomically thin films. This leads to questions that pertain to surface effects, van der Waals bonding, and cold welding that could then be applied in other areas that deal with mechanical bonding of metamaterials. Synthetic gecko tapes have been shown experimentally to exceed the performance of Velcro™ materials reaching 360 kPa of adhesion. Schemes to include van der Waals bonding to increase performance as in gecko tapes are worth exploring. This comes with its own challenges as gecko tapes require nanoscale deformation to maximize the contact area between the tape and surface, and the use of polymer materials may limit high temperature operation. Rigid materials like gold and titanium can't do this. Other areas which can be explored include the mechanisms of load, phonon propagation, electron transfer, and scaling effects which can affect larger systems.

Bending stresses in the cantilevers are the limiting constraint in the maximum forces that can be developed, and the longevity of their repeated use. From analytical and numerical modeling this technology is a viable solution as results show that the presented designs meet many of the stated criteria for success. The challenge then is to improve the performance to match more competitively against other existing technology or permanent bonding schemes. Exploration of different materials which can sustain large displacements without permanent deformations is one way that performance can be increased. For instance, certain formulations of shape memory alloys such as Nitinol display potentially relevant hyperelastic behavior, where the elastic region of the material is much higher than in typical engineering materials.

To reduce the bending stresses, one approach is to process the films such that the sharp corners will be smoothed out into a curve or fillet. This can be done by heating the polymer and photoresist layers such they deform to reduce the corners, but not enough to lose the larger features. Von Mises stresses have been proven to be kept below the yield stress of copper and titanium. Interlocking the hook designs had a max. push-in von Mises stress of 88.5 MPa at a 0.3 μm thickness. The L design with a 0.05-μm thickness and 0.75-μm radius curve had promising simulation results. A maximum von Mises stress of 239.3 MPa is within the yield strength of pure titanium. The flat cantilevers with the same interaction distance and thickness resulted in a higher stress of 342.9 MPa.

Plastic deformation complicates the methods and theories presented as well as impacts performance and longevity of the interlocking structures as cantilevers would break off or through fatigue wear when used in reworkable designs. The presented 2D tiled array with circular pillars will deform permanently for most materials, this does not mean design is not viable so long as the cantilevers do not fracture or break off completely, there will still be retention of components. Given the small size of the components and the strength of the interlocking structures the component will most likely still hold in place. Future work in thermal analysis can be done to determine the stresses that develop due to differences in thermal expansion between devices, combined with the large changes in temperature. Once the interlocking structures have been joined together, one concern is the free movement of the chip. This wiggling could be a concern when used where electrical contact between the chip and substrate is required. To stop this free movement, the cantilevers can be designed so that their lengths are longer than the interaction distance d. This would imply the cantilevers would always be in contact with the opposing pillar.

Currently, the proposed interlocking cantilever designs are very promising for purely mechanical attachment. Although we had initially set out with the goal of having the structures provide mechanical and electrical contact, the electrical contact must still be shown. The current designs are still viable mechanical attachment, as they can be used in place of epoxy joints, albeit with lower bond strength. This would mean that current designs would still require the use of wire bonds to provide electrical connections to peripheral devices and to the assembly. Future iterations of this technology will hopefully be designed to eventually remedy this.

Fabrication and Experimentation with Microscale Samples

Fabrication of the interlocking structures outlined in this paper is reserved for future work due to limited resource access. The structures are planned for fabrication using the facilities located at the Airforce Research Laboratory (AFRL) in Dayton Ohio, in collaboration with the MEMS group there.

Physical testing of the microfabricated structures will be done at the University of Hawaii at Manoa using the Shimadzu AGS-X 5 kN tensile tester. These tests include tensile and compression, fatigue tests, pure shear loading, and mixed axial shear tests. Tensile and compression tests will be performed to measure the force to join and to separate the chips. A fatigue test will need to be performed to ensure that chips can be reworked. This will be done by performing the compression and tensile tests until the samples will no longer join.

Direct measurement of the stiffness of individual cantilevers is possible and is a test that will need to be formed at the AFRL. This will be done with the use of a probe profilometer. Using the profilometer, the interlocking cantilevers can be directly interacted with by using the scanning tip to press directly upon the cantilever. This will obtain data on the force versus displacement behavior. This is necessary to predict the final performance of the interlocking structures and to verify that the models developed in this paper are correct. From the work presented it will more be a case that the data gathered will be able to develop and refine the models to then further the development of the structures.

### Microscale Data to Guide Future Design

The manufactured cantilevers will be expected to have some kind of curvature due to residual stresses. The cantilevers take on a slight bowl like shape and curls upwards. This is important for development can have a drastic effect on the performance. For these bowl-like cantilevers, it is expected that the push-in force will be higher than the pull-out force. This is not ideal for the structures as it is the opposite of what is desired. This can be gathered by producing free standing cantilevers with varying length width, and thickness and measured with the use of a profilometer. This can be used to further refine the shape and importantly the process used to avoid this type of residual stress induced curvature.

The Young's modulus is one of the two most important material properties needed in design. While it would be expected that the material properties would be the same as a bulk material, recent work in the area of material characterization at the micro and nanoscale has revealed in fact that materials properties change at the nanoscale. This is known as an apparent size effect, and the reason for it is still not known. Its description can be done using relations gathered from data to predict it. The yield strength of the material can also change due to size effects. For these reasons microscale material characterization will be crucial in the future to refine the structures into something that can be used in final assemblies. In the meantime, bulk properties coupled with physical testing will be the main way to drive development.

Throughout this work it has been suggested that these structures will be able to provide electrical connections to attached devices and allow for high rates of heat transfer to dissipate heat generated by the devices. This must still be shown experimentally and is reserved for future work. Electrical conductivity must also be shown experimentally and is also reserved for future work.

### Improvements to Macroscale Cantilever Tests

In this work, the initial steps towards understanding plasticity have been taken but more work is still needed to refine the analytical models. So far only two materials have been used to see how plasticity affects the force produced by an interlocking cantilever, naturally more materials should be tested. More specifically materials should be selected with different strain hardening functions, and different yield strengths. This can be done by selecting materials with the same composition but with different tempers.

After processing of data, it was noticed that there could be a considerable difference when using the same material and same dimensions. This is to be expected as there would naturally be some variations, although coming up with a better process for fabrication of the samples should be devised as currently, they are all cut from large sheets of material using a mechanical shear. The shearing process is done manually and the widths are marked out and cut. This meant that the width of the cantilevers could vary to within 1 mm of the desired width, translating to up to ˜±10% of the desired width.

Cantilevers were also formed from copper foil that was 0.004% thick. However, the results from these tests were inconclusive as there was no clear trend due to amount of difference between the different trials. For those reasons this test was not included into this thesis. This lends credence to the need of more control of the process of fabrication.

Some parts of the test equipment were also 3D printed from materials like ABS and PLA. This was due to the inability to access machining equipment to produce them from more rigid materials like aluminum and Steel. This could be a source of error as the compliance of the equipment means the displacement for any force would be higher. This is akin to having springs in series, and the displacement of the equipment is large enough to affect the measured displacement. Future experiments with macro scale cantilevers should use materials that are stiffer.

### Macro Scale Testing & Characterization of Microfabricated Interlocking Structures

Once the interlocking structures are fabricated, testing must be done on the macroscale. This will again make use of the Shimadzu AGS-X 5 kN tensile tester used for the macroscale testing. Work will have to be done to develop methods of holding the samples in the tensile tester. Equipment to attach to tensile tester will have to be designed and fabricated. Test procedures will also have to be developed to handle the specimens, and how to correctly push them together.

Characterization will also need to be done using SEM facilities at UHM. Using the SEM, the samples will be inspected before and after testing in the tensile tester. SEM will allow for direct examination of the cantilevers, and to see how damaged the cantilevers are. This will give insight into how much the structures can be used. It is expected that the flat cantilevers will have little to no damage, but non-flat and curved cantilevers will have some damage.

### Extension of Current Work to Include Plastic Deformation

Following the same approach of including inflection points, plasticity can be included in the same way where the cantilever is composed of two sections one where elastic bending is occurring and the other where plastic deformation is occurring. This can be shown below in Eq. (27) where a point sp is the distance along the arc where the transition between the two regimes occurs.

$${\int }_{{S}_{A}}^{{S}_{B}} ds = {\int }_{{S}_{P}}^{{S}_{B}} ds + {\int }_{{S}_{A}}^{{S}_{P}} ds \qquad ( 27 a )$$

$${\int }_{{S}_{P}}^{{S}_{B}} ds + {\int }_{{S}_{A}}^{{S}_{P}} ds = {\int }_{{θ}_{P}}^{{θ}_{B}} d θ + {\int }_{{θ}_{A}}^{{θ}_{P}} d θ \qquad ( 27 b )$$

In the case of the curved cantilevers, and the expected loading conditions, there is the expectation that an inflection point will eventually occur as in Eq. (28).

$${\int }_{{S}_{A}}^{{S}_{B}} d s = {\int }_{{S}_{P}}^{{S}_{B}} ds + {\int }_{{S}_{j}}^{{S}_{P}} ds + {\int }_{{S}_{A}}^{{S}_{j}} ds \qquad ( 28 )$$

The trouble with this though is that there are now many more free parameters that must be accounted for including the yield strength, hardening coefficient, and the thickness into the cross-section that plastic deformation occurs. As the curvature is due to rotation of the cross-section about the planar neutral axis, the further out from the neutral axis the more elastic strain and plastic strain occurs. The increased number of mutually undefined parameters would lead to an intense computation that must be performed iteratively unless some fundamental relation can be found. Inclusion of inflection points on top of plasticity would be an even greater challenge and may not even be possible with the elliptic integral approach. Overall, it may prove to be too difficult to try and model all of these analytically.

For the purposes of developing interlocking structures for heterogeneous integration, analytical models may not be necessary as the beam geometries can vary greatly, and new geometries can drastically change the boundary conditions for the problem leading to greater difficulty. Computational methods can then be used to compute obtain predicted results because of its speed and ease of setting geometry and boundary conditions. However, the current work shows that this approach has challenges. For example, it was observed that contact conditions lead to considerable but manageable error. This issue lies at the heart of computational methods as the sliding contact condition in this work is an active area of research in computation. Thin films like used here also produce meshes with high aspect ratios, requiring a high number of elements and therefore a long time to compute. Often results would not converge leading to further complications. Adding plasticity into the simulations would then be an even greater challenge, and so is reserved for future work.

### Contribution of Novel Work

Relating to the design of microfabricated interlocking structures for heterogeneous integration, these novel ideas are the use of an asymmetrical interlocking structure design, non-flat interlocking cantilevers, and curved cantilevers. One important novel idea was to use a rigid interlocking structure and a compliant interlocking structure. This allows for an assembly to be continually used without fear of the interlocking structures wearing out due to fatigue of the structures. The device to be attached can include the compliant structures meaning only it will have a finite life. This means that the interlocking structures will be a viable design.

The other novel idea for interlocking structures was in the design of the interlocking cantilevers themselves. To obtain an asymmetric force ratio, where the force to push-in is less than the force to pullout it was suggested to use a cantilever design which is bent or non-flat. Where the cantilever extends horizontally out from the pillar then bends downward, then bends out horizontally again as in FIG. 25A. This produces a cantilever which produces the desired force asymmetry but is also possible to manufacture with current microfabrication techniques.

These two innovations greatly improve the original design of interlocking cantilevers and makes the technology very promising, needing only small refinement before it can be used in a commercial setting.

Previously it was suggested to use a single material to fabricate the cantilevers which would result in a flat cantilever. It was then suggested to make cantilevers from two materials with different coefficients of thermal expansion. This would result in cantilevers which are curved. This curvature changes the geometry in such a way that the cantilevers would be easier to push-in and harder to pull-out. This approach is simpler than the non-flat cantilevers as it would simply require the deposition of a metal on top of another metal, which skips the additional photoresist layer needed for the non-flat cantilevers.

In conclusion, the work presented here has provided several significant novel contributions advancing the fields of microengineering and applied mechanics. In the design of microfabricated interlocking structures for heterogeneous integration, analytical models and optimization schemes were developed to guide optimal design and give insight into what parameters affect performance. Those parameters being a ratio of the cantilever length divided by its thickness, and the pitch or the distance between repeated interlocking structures. The most important and novel outcome of this work is the development of a method to obtain the desired force asymmetry by changing the geometry of the cantilever from a flat cantilever to having a bend, becoming non-flat. The other most important development is the novel idea of using a compliant interlocking structure to provide interlocking, and a rigid interlocking structure that provides a surface with which the cantilevers may interlock. The proposed manufacturing techniques use existing methods, which implies feasibility of electrical and thermal conduction as initially desired but still must be shown either experimentally or through modeling.

Modeling efforts showed that the designs have a usable strength, up to 6.3 kPa for flat symmetrical structures, and structures with non-flat cantilevers are proposed which require 8 kPa to join chips and require 29 kPa to separate them. With design methodology, the remaining step towards a successful design is to gather data on material properties of microfabricated metallic films. From this work, it is evident that there is still much work to do but only a few more steps are required for a fully functional interlocking structure. This is very exciting as it is a step closer towards realizing the main goal of heterogeneous integration of microelectronics.

This work also presents a breakthrough in the problem setup for applying contact loads to constrained curved cantilevers because through solution of this problem it was that discovered that there was a simple linear dimensionless behavior for contact loading in pre-curved cantilevers. From this, a simple equation based on linear fits to the parameters was derived which allows for future calculations without the need of using the complicated elliptic model developed, another first of its kind.

Plastic deformation is the main issue that limits the performance of interlocking structures for heterogeneous integration. The analytical models developed thus far only deal with elastic bending, including plastic bending complicates the models greatly. There is little work in the area of large deflection modeling and plastic deformation, so cantilevers of various metals which underwent plastic deformation were tested and nondimensionalized to see the difference between the elastic elliptic model and data. This will eventually be used to guide future modeling efforts to make better interlocking structures.

### Additional Details for Exploration of Reworkable Heterogeneous Integration

### Introduction to Reworkable Heterogeneous Integration

The following sections through discuss in detail the novel development of using a compliant and a rigid interlocking cantilever pair in addition to the usage of non-flat cantilevers for form an interlocking mechanism that accommodates reworkable heterogenous integration.

### Heterogeneous Integration

Integration of separately manufactured microelectronic components into a larger assembly requires new strategies as devices have miniaturized and pushed operation to increasingly higher frequencies. These heterogeneous integration challenges include standard packaging concerns such as mechanical joining, rework, thermal expansion mismatch, thermal management, and electrical connections, and additional unique challenges such as alignment, coupling of radio frequency (RF) signals, accommodation of unique material constraints, small contact points, and assembly and manufacturing time. Conventional approaches to chip integration such as wire bonding, solder, epoxy, and cold welding (Au Au joints, etc.) or brazing face limitations of messiness, accuracy, temperature, signal loss, and process time, motivate the search for novel technologies for heterogeneous integration. The present disclosure examines the potential for microfabricated interlocking structures to achieve manufacturing integration of heterogeneous components as seen in FIG. 1.

During the process of developing new packaging for micro electronic devices, or in creation of specialized systems integrating several unique components, it is often desirable to remove and replace components. Such reworkability becomes a desirable feature because allows custom assemblies to be saved and reused in the event a bonded peripheral device fails. Using a traditional bonding method such as soldering and epoxy requires a tedious and difficult reworking process, which can result in damage to the components. A method of joining where components could be removed simply with mechanical force could be highly advantageous to prototyping. Mechanical interlocking poses one potential solution to these problems. Mechanical interlocking relies on small structures which join or “hook together” and bending of the interlocking structures is where strength and stiffness come from, e.g., where the hooks attach to some complementary attachment, and the hooks bend as the two opposing sides are separated. This differs from typical adhesives which rely on some form of chemical bonding, dry adhesive brushes using van der Waals bonding, or intermetallic bonding as with solder.

For chip attachment, there are two types of attachment tasks. There may be purely mechanical attachment; this would require patches of material on a chip to provide a mechanical joint in some unused portion of the chip footprint. Alternatively, bonding on chip contact pads adds electrical signal transfer to the mechanical attachment. In both cases, it is advantageous to consider the properties of some typical attachment patch as a means to draw abstract mathematical analysis into practical design choices.

### Microfabricated Interlocking Structures

In micro and nanoscale systems, many compliant interface technologies have been considered for electrical and mechanical interconnects. Earlier published work with related microfabricated designs had not used compliant systems and had observed limited effectiveness due to brittle material failure. In contrast, our approach here enables controllable manufacturability, electrical conduction, and the potential for high bond strength. Many considerations guide an effective design. These are presented in Table 1, and to establish feasibility of a reworkable bonding system, this paper focuses particularly on the first three specifications: adhesion, alignment, and force asymmetry.

Mechanical retention by interlocking compliant structures is a subset of “integral attachment” fastening systems. Integral attachments use mechanical parts built into assembling components. A classic example of such systems are snap fit components such as hook and latch systems, and a wide variety of designs have been explored. These components present advantages in mechanical design such as low insertion force, high retention force, simple insertion motion by pushing, and easy automation of assembly. They have been suggested for joining polymer matrix composite structures, explored for fabrication in three-dimensional printing, and explored for heat activated modification as design for disassembly.

Nano-indenter-based measurement of the cantilever spring constant in the earlier proof of concept paper suggested that the deflection forces and bonding stresses of interlocking microfabricated joints could be up to 15 MPa, nearly an order of magnitude better than typical values for dry adhesives based on van der Waals force. This result strongly suggested the presence of additional stiffening effects acting on cantilever deflection such as through residual stress induced curvature of cantilevers. For the present analysis, we assume no residual stress and instead focus on the consequences of large deflection bending of flat cantilevers.

### Mathematics of Interlocking Cantilevers

Recent developments in analytical modeling of compliant mechanisms have allowed a framework for modeling of interlocking systems, including the contributions disclosed herein, a general solution to the analysis of geometrically nonlinear elastic mechanics problems of large deflection bending under contact boundary conditions, which create a statically indeterminate problem. These advances based on elliptic integral calculations may be used in place of more cumbersome finite element or iterative methods in order to provide a theoretical prediction for this class of large deflection mechanics problems. Here, this mathematical theory is extended to analysis and design of compliant retention systems for application in heterogeneous integration.

### Modeling and Design

In exploration of this design problem, it became evident that reworkability did not require identical parts on mating surfaces, and particularly the areal density of compliant joints, and the strength of individual joints, could be maximized if one surface presented rigid parts or quasi rigid parts, while the complementary surface retained compliant parts to enable snap through interlocking. This insight drives the implementation of compliant joints as a surface adhesive metamaterial array, and the analysis presented below.

### Small-Deflection Analysis

Analytical modeling of the deflection of a cantilever begins with the Euler Bernoulli beam theory. The theory states that curvature κ=dθ/ds at any distance s along the curve is a function of the bending moment at that point along the beam and is modulated by the flexural rigidity EI, Eq. 29. All analytical models here also assume that cantilever contact points are frictionless, and the cantilevers are inextensible, thus all deflections are due to bending. The flexural rigidity is assumed to be constant along the length, and the thickness of the beam is much smaller than the length. Solving Eq. 29 for a flat beam subjected to a point load at the end results in Eq. 30, which models small cantilever deflections, where the end displacement δ is proportional to the applied load P. This model works well for small displacements but is no longer valid once the end of the beam is deflected ˜10 deg or more.

$$\frac{d θ}{d s} = \frac{M ( s )}{EI} \qquad ( 29 )$$

$$δ = \frac{{PL}^{3}}{3 EI} \qquad ( 30 )$$

### Large-Deflection Analysis

Thin film interlocking structures may deflect to an extent beyond the customary small angle assumption of a few degrees, thereby requiring a large displacement model. Previous work presented an approach to modeling interlocking cantilevers subject to large deflections; this model was implemented here with specific geometric choices for device design. Comparison of the large deflection and small deflection models for interlocking horizontal cantilevers subject to vertical displacement is provided in FIG. 66B.

FIG. 66B demonstrates that the large deflection model peaks at a dimensionless value of 0.417; this corresponds to the peak force that can be delivered by a horizontal cantilever contacting an interlocking constraint. Note that interlocking cantilevers that are too short may trace the force curve but will slip past one another before reaching this peak value. Nonetheless, this peak value can be used directly to predict the maximum force from a pair of interlocked cantilevers and the nominal bond strength σₘ from an array of N of these joints in an area A, Eq. 31.

$${σ}_{m} = \frac{{NP}_{max}}{A} = \frac{N ( 0.417 ) ( 2 EI )}{{A ( \frac{d}{2} )}^{2}} \qquad ( 31 )$$

Relatedly, the material stresses within the cantilever can be determined analytically.

### Finite Element Modeling

Finite element analysis (FEA) was performed using commercial testing/simulation software to verify the analytical methods as well as to enable analysis of more complicated geometries that may add tedious complication to a purely analytical approach. A stationary study was performed using the solid mechanics module, approximating a quasistatic testing of an elastic material. “Form assembly” was used to create a frictionless contact pair between the two cantilevers. The maximum von Mises stress and contact force were found from surface maxima in postprocessing of model results. In simple contacting flat cantilever studies, we observed a divergence, FIG. 66B, of about 10% from the peak value of the large deflection analytical model. In previous work, the analytical flat cantilever model was observed to match well with macroscale experimentation and FEA based on point loading perpendicular to the cantilever end. Several potential sources were examined for the error in the contacting cantilever FEA used in this study, along with more details of the FEA model. Reproducing the previous point load FEA produced good agreement with the analytical model, indicating that the newer FEA is not intrinsically a source of error. Furthermore, mesh and cantilever aspect ratio showed no significant effect on the error. Therefore, the error was most likely due to implementation of the contact boundary condition in the present FEA model. From this, we anticipate that FEA using the contact condition may imply a 10% deviation from analytical and experimental results.

### Misalignment and Self-Alignment

The force and bond strength analyses above assume that the interlocking structures are perfectly aligned. When attempting to join the interlocking structures with one another, it would be reasonable to assume that there would be some deviation of the positioning of the chips from the ideal location. To assess effects of any deviations from this ideal, the model was modified to include a translational misalignment factor μ, whereby the amount of deviation from the ideal center would factor into the amount of force holding the cantilevers together. This factor is important to the performance of the structures and helps in understanding the requirements for the precision of equipment needed to assemble devices. With joining methods such as epoxy and solder this factor is not as important as a poorly misaligned chip will still function the same, whereas with these periodic structures, misalignment could have a drastic effect on the performance.

Even small translational misalignments may consume a large fraction of the cantilever interaction lengths, leading to significant deviation from the perfectly aligned model. Other misalignments are less important, and other design factors such as the specific shape of the cantilevers, pitch, material thickness, and residual stresses all play a role in the strength of system but are intrinsic to design and manufacturing, and relationships among these are considered throughout this paper. The implementation of fabricated structures in device assembly depends on the resilience to rotational and translational misalignments between joining surfaces, which affect the final assembly and have the potential to determine whether the interlocking structures are a viable solution toward heterogeneous integration. The joining mechanism operates through out of plane motion; therefore, out of plane translational and rotational misalignments are accommodated through the joining mechanism. For the analysis presented here, these are not limiting factors to the viability of the mechanism. In plane rotational misalignment is also not a significant factor for initial design considerations. Rectilinear objects such as microchips can be rotationally aligned to a good degree of accuracy through even simple techniques such as contact with a flat surface. Furthermore, the rotation giving a 10 μm misalignment at the edge of a 1 cm² chip is only about 0.11 deg (=tan¹ (10⁻⁵ m/5×10⁻³ m)); this is not enough to significantly modify the cantilevers from basic rectangular geometry. Across an array of interlocking structures, small rotational misalignments would manifest locally as translational effects on the contact force, with only minor effects due to small rotation of the contacting cantilevers. It should be noted that any large rotational misalignment that would cause any of the structures to not align would mean the structure as a whole could not be inserted or it means damage to those structures.

A diagram of in plane misalignment can be seen in FIG. 4. The original formulation of the maximum bonding strength can then be modified to account for the translational mismatch. As shown in FIG. 4, the mismatch is quantified as a single value μ. This results in the interaction distance between two cantilevers to either grow or shrink the amount μ. The snap through force for two pairs of cantilevers on the same interlocking structure with some mis-alignment can be found with Eq. 32. The maximum bonding strength can then be formulated as Eq. 33. It should be noted that these formulations are approximations, with misalignment one pair will slip before the other, at which point the entire structure will snap through.

$${P}_{m} = \frac{0.4 \; 17 EI}{{( {L}_{o} + μ )}^{2}} + \frac{0.417 EI}{{( {L}_{0} μ )}^{2}} \qquad ( 32 )$$

$${σ}_{m} = \frac{0.417 NEI}{{A ( {L}_{0} + μ )}^{2}} + \frac{0.417 NEI}{{A ( {L}_{0} μ )}^{2}} \qquad ( 33 )$$

From FIG. 4D, the net maximum bonding strength increases as misalignment increases. It should be noted that percent change is relatively small, and the figure has been drawn to enable visualization of the relationship. The net horizontal force also increases as the misalignment increases, FIG. 4E, which suggests that there is an inherent self-alignment behavior where the chips will be pushed toward the ideal center position.

Periodic Array Designs with Interlocking Cantilevers

### Design Implementation for Reworkable Interlocking Structures

As mentioned previously, there is a balance among the beam parameters for the structures to prevent permanent deformation but also maximize bond strength. Under loading, the bending stresses may quickly exceed the yield strength of the material, becoming permanently deformed, thus making it unsuitable for reusable attachment.

Design begins by first selecting a desired force to displace the cantilevers. In the large deflection analysis from Sec. 18.2, it was assumed that the cantilevers would always be sufficiently long that the cantilevers would experience the peak nondimensional force of 0.417. Selecting a nondimensional force before reaching the peak will give similar performance with less deflection and internal stress occurring. In FIG. 5A, this is shown with label (A) where a snap through displacement is selected at 0.3, which produces a snap through force of 0.36, this is nearly 80% of the maximum, but importantly necessitates only 63% of the displacement required for the peak force.

A new nondimensional term L*=L/L₀ is then introduced, which is the arc length L of the beam from the anchor point to the loading point, as drawn in FIG. 66A, divided by the horizontal distance L₀ of the loading point to the anchor point. Another nondimensional term Aᵣ=L/t is introduced; this is the aspect ratio and is defined as the dimensionless measure of the total cantilever length L (which is defined by the arc length at snap through) to its thickness t. This term is important for further analysis and becomes one of the most important parameters that will determine many parameters in the design.

Using FIG. 5B, L* can be found with the deflection from FIG. 5A, as indicated with label (B). Next, Aᵣ can be found using FIG. 5C. Here, plots of the maximum material stress at given displacements as functions of Aᵣ are plotted. These lines are Eq. 34 evaluated at the end angle θ_{B} at a given dimensionless displacement δ_{B} [51]. In FIG. 5C, these lines are shown by label (C).

$${σ}_{B} = {\frac{Ef}{2 {A}_{r}} [ sin ( {θ}_{B} ) ]}^{\frac{1}{2}} \qquad ( 34 )$$

The yield strength of the material is plotted as a horizontal line. At the intersection of the stress plots (C) with the yield strength, the minimum A, is obtained. Selecting an Aᵣ lower than this value will result in the bending stresses exceeding the yield strength and will result in permanent deformation of the structures.

The aspect ratio constraint interacts with constraints of lithography and fabrication processes to define the geometry for a repeating unit in an array of interlocking cantilevers, illustrated in FIG. 3. Geometric parameters in the unit cell are D, Δ, ω, L, and L₀, where D is the width of the pillar that suspends the cantilevers in free space, A is the width of the rigid pillar (here set equal to D, for simplicity), and ω is the length of the rigid cantilever that extends from the rigid pillar. Unit cell pitch ρ=2(L₀+w+D) is determined by the sum of other parameters as shown in FIG. 3C.

An optimal pillar and beam width D can be obtained by plotting interfacial strength σₘ, as a function of D, Eq. 35, FIG. 3D. Doing so will result in a graph that peaks at some value of D, then decrease toward 0 as D continues to increase. The peak of this graph is the maximum possible bond strength for the given parameters. Following these steps, the optimal interlocking structure geometry is obtained.

$${σ}_{m} = \frac{{C}_{1} {EDt}^{3}}{3 {{L}_{0}^{2} ( {L}_{0} + ω + D )}^{2}} \qquad ( 35 )$$

As a specific example following this procedure, consider titanium as a fabrication material, due to compatibility with common mate rials in microelectronics coupled with high stiffness and high yield strength. With δ_{B}=0.30 and corresponding snap through nondimensional force C₁=0.36, L* is then 1.05 and Aᵣ=250 (FIG. 5C) to maintain operation under elastic behavior. Applying Eq. 35 with the parameters from above and selecting an ω value of 4 μm, D is selected to be 20 μm and leads to a ρ of 42 μm. This configuration then leads to a maximum bond strength of 250 Pa as shown in FIG. 3D.

It is clear from this analysis that designing interlocking structures that remain within the elastic regime of its material will lead a low performing material. Pure elastic operation is required of patterned surfaces that can be separated and reattached repeatedly, but this comes at the price of adhesion strength. The condition of reworkability can be preserved if the die bearing the compliant cantilevers is afforded some plastic deformation and treated as a single use component. In this case, the surface of patterned rigid structures enables attachment, removal, and replacement of components.

Following the design and optimization strategy above while allowing some plastic deformation, a design for interlocking flat cantilevers shows the possibility of significantly better performance. First, L and L₀ are selected to be 10 μm and 8 μm, respectively. This gives L*=1.25, which means it will reach the maximum C₁=0.417 and Aᵣ=100. These design parameters feed into the relations above all to generate the resulting parameters in Table 16, which are illustrated as the specific models in FIGS. 3A and 3B. These parameters produce a snap through force per cantilever of 0.81 μN, which leads to a bond strength of 6.3 kPa, which is a theoretical maximum comparable to the performance of commercially available hook and loop materials. This shows that these micro interlocking structures have great promise in improving integration methods of chips, but more work is required to better refine their design through improved modeling of plastic behavior coupled with physical testing of the metallic films that will comprise these structures.

### Design of Interlocking Arrays of Non-Flat Interlocking Cantilevers

While exploring the mechanical behavior of design variations seeking to reduce internal material stresses, the development of force asymmetry in interlocking “L” shapes was observed similar to FIG. 3C while allowing compliance in the vertical support of the compliant cantilever. Unfortunately, the result was opposite of ideal for the attachment problem: L shapes created high insertion force and low retention force, with corresponding high and low probabilities of exceeding the yield stress. It was hypothesized that this result could be applied to improve performance by flipping the L structure and attaching it to a rigid support; this resulted in a concept for a non-flat cantilever design. A model of the repeating unit cell of the proposed design can be seen in FIG. 23A. Finite element simulation confirmed that the added bend allows a low push in force, and relatively higher force required to separate the components. For implementation in a specific design, a rigid permanent structure is again provided similar to above. With the added shape, it is necessary to include additional parameters for design, seen in FIG. 23B and specified in Table 17.

The performance of this design was evaluated with FEA, under pure elastic conditions. The maximum von Mises material stresses are shown in FIG. 23C. Plastic deformation is expected to occur as the yield strength of titanium is 140 MPa is exceeded quickly. The maximum force required to interlock a pair of cantilevers was 2.5 μN and to separate required a force of 9 μN, FIG. 23D. This corresponds to push in and pull out strengths of 8 kPa and 29 kPa, respectively, higher than the maximum 6.3 kPa pull out strength found earlier for arrays of simple flat cantilevers. This design is promising for future work as it gives potentially high retention strength in a reworkable design, but much more optimization is required.

### DISCUSSION

Traditional methods of joining chips such as epoxy and solder can be problematic because of material cleanup, failure under thermal cycling, and reworkability requiring elevated temperatures or chemical solvents to remove the bonding material. Compliant attachment presents the potential for die to expand freely without creating high thermal stresses that could cause failure of the joint. Electrical connections can also be potentially made using these structures, meaning techniques like wire bonding can be avoided, reducing packaging complexity and potentially improving performance of devices such as RF devices which operate at high frequencies.

The analysis and design efforts in Sec. 19 support the potential for compliant mechanical die attachment systems, but consideration of the internal bending stresses in the cantilever material is critical for successful design. The yield stress is quickly exceeded for most materials; designs which rely on purely elastic bending are maybe expected only to have weak performance. Much more work will need to be performed to include plastic deformation and other considerations such as fatigue studies and non-flat or curved designs, and further design optimization may be possible through sensitivity analysis and virtual design of experiments modeling considering material and geometry variability. Interlocking cantilever array metamaterial attachment systems show promise for mechanical connection, but further studies must be performed to show acceptable electrical and thermal performance. In RF applications, it must also be shown that they can outperform other methods for electrical connections, and that signals do not degrade and experience little to no interference.

TABLE 16
Design parameters for interlocking unit cell with flat cantilevers

| L | 10 | μm |
|---|---|---|
| L₀ | 9 | μm |
| Aᵣ | 100 | |
| D | 10 | μm |
| Δ | 10 | μm |
| H | 15 | μm |
| ρ | 40 | μm |
| ω | 2 | μm |

TABLE 17
Design parameters for interlocking unit cell with nonflat cantilevers

| | | |
|---|---|---|
| L_{C} | 3 | μm |
| L₀ | 11 | μm |
| t | 100 | nm |
| D | 12 | μm |
| Δ | 12 | μm |
| H | 15 | μm |
| H_{B} | 5 | μm |
| ρ | 50 | μm |
| ω | 4 | μm |

The challenge then is to improve the performance to match more permanent attachment methods. Exploration of different materials which can sustain large displacements without permanent deformations is one way that performance can be increased. For example, certain formulations of shape memory alloys such as Nitinol display hyperelastic behavior, where the elastic region of the material is much higher than in typical engineering materials. To reduce the bending stresses, one approach is to process the films such that the sharp corners will be smoothed out into curves. Once the interlocking surfaces have been joined, another concern is the free movement of the chips, i.e., whether the joint experiences any “play.” To stop this free movement, the cantilevers can be designed so that their lengths are longer than the interaction distance D. This would imply the cantilevers would always be in contact with the opposing pillar.

The impact of interlocking structures on nanoscale and micro scale designs will be to enable greater interfacing and adaptability of sensors within microsystem and nano-system packaging. It could be possible to scale this technology down from the micro scale to the nanoscale, possibly even to atomically thin films such as two-dimensional nanomaterials like graphene or boron nitride. With reduction to the nanoscale, surface effects such as van der Waals bonding and cold welding arise and may require consideration in design. Other areas which can be explored include the mechanisms of load, phonon propagation, electron transfer, and scaling effects which can affect larger systems.

### Conclusions on Microfabricated Mechanically Interlocking Metamaterials for Reworkable Heterogeneous Integration

Mechanically interlocking structures present a promising technology for heterogeneous integration. The ability to remove microdevices from larger assemblies has the possibility to make microdevices simpler to service and reuse when prototyping or when replacing dead components on a final product. This disclosure explored the elastic constraints on design of arrays of mechanically interlocking cantilevers, forming complementary metamaterial surfaces for mechanical adhesion. Interlocking structures with flat cantilevers may have a theoretical bond strength up to 6.3 kPa. Structures with non-flat cantilevers are proposed which require 8 kPa to join chips and require 29 kPa to separate them. Applications in RF and reworkability are the main areas where this technology provides the most distinct advantage over current state of the art. Remaining issues with this technology are low bonding strengths and accommodation of plastic deformation from internal stresses during die attachment and in modeling. Designs which operate in the purely elastic regime will allow reuse at the cost of low performance. If plastic deformation is allowed to occur on the interlocking surface supported on a replaceable component, the performance may increase significantly to the point of being competitive with other surface bonding technologies.

### Nomenclature

A=area of a unit cell of an interlocking array
Aᵣ=aspect ratio, nondimensional measure of total cantilever length divided by cantilever thickness
b=cantilever width
d=cantilever interaction distance, distance between the two fixed ends of a pair of interlocking cantilevers
D=pillar width, width of interlocking cantilever
E=Young's modulus of the material
EI=flexural rigidity, the product of the Young's modulus and the moment of inertia
ƒ=a function of elliptic integrals and θ_{B}, defined in Ref. [51]
FEM=finite element modeling
H=pillar height
H_{B}=height of bend in nonflat cantilever
I=moment of inertia of the beam cross section
L=arc length of cantilever between anchor point and contact point
L=distance from loading point to cantilever fixed end
L*=dimensionless measure of L and L₀
L_{c}=length of nonflat cantilever extending from anchor point before vertical wall downwards
L₀=horizontal distance from cantilever end to contact point
M=bending moment at point s along cantilever
N=number of cantilever pairs in a unit cell
P=vertical force applied to the tip of the horizontal cantilever
P₁=interlocking cantilever pair with an increasing interaction distance as misalignment increases
P₂=interlocking cantilever pair with a decreasing interaction distance as misalignment increases
RF=radio frequency
s=arc length, used to parametrize the points of the beam
t=cantilever thickness
δ=vertical displacement of the tip of a horizontal cantilever
Δ=width of pillar of rigid interlocking structure
θ=tangent angle at point s along cantilever
θ_{B}=cantilever end angle
κ=curvature
μ=measure of array misalignment from ideal center
ρ=pitch
σ_{b}=maximum bending stress within the cantilever
σₘ=maximum snap through strength
ω=length of overhang of rigid interlocking structure

### Further Examples

Referring to FIGS. 25A-25B, one example of a system 100 for mechanical attachment is illustrated. In general, the system 100 can be implemented for interlocking various components in electronics manufacturing and can include reworkable heterogenous integration as described herein. The components of the system 100 can be microfabricated, but the mechanical attachment mechanisms shown and described herein are independent of size and can also be implemented at a macro level and at the nanoscale.

In the example shown, the system 100 includes a first structure 102, and a second structure 114 configured for engagement with the first structure 102. The first structure 102 includes a first body 104 defining a first end 106 and a second end 108 opposite the first end 106, with the first end 106 configured to be fixed to, mounted to, coupled to, or positioned along a first supporting surface 110. The first structure 102 further includes a member 112 extending from the second end 108 of the first body 104.

The system 100 further includes second structure 114 configured for engagement with the first structure 102. The second structure 114 includes a second body 116 defining a first end 118 and a second end 120 opposite the first end 118, with the first end 118 configured to be fixed to a second supporting surface 122 (example in FIG. 23A). The second structure 114 further includes a compliant member 124 extending from the second end 120 of the second body 116, with the compliant member 124 being configured for deformation.

In general, the second structure 114 is configured to form a connection with the first structure 102 by deformation of at least a portion of the compliant member 124 relative to the first structure 102.

In some examples, the formation of the first structure 102 and second structure 114 is configured to accommodate a first force to form the connection and shift the portion of the compliant member 124 along the first structure 102, the first force being of a smaller magnitude than the magnitude of a second force to disengage the first structure 102 from the second structure 114 and remove the connection.

In some examples, the compliant member 124 of the second structure 114 includes a first region 126 extending from the second end 120 of the second body 116, and a second region 128 extending from the first region 126. The first region 126 can extend horizontally away from the second body 116, and the second region 128 can extend vertically from the first region 126 such that the second region 128 is in general parallel orientation relative to the second body 116 as indicated in FIG. 25A. The parallel orientation is not specifically required, instead, one important aspect of this invention is that as the second region 128 extends further from the attachment point at 120, it moves closer to the substrate 124. In addition, the compliant member 114 can include a third region 130 extending from the second region 128 as indicated. In the example of FIGS. 25A-25B, the compliant member 124 can include such regions having orthogonal orientations relative to each other. The compliant member 124 can further form a general s-shape configuration, a hook, or can take the form of any of the shape/design configurations described herein with respect to the “compliant cantilever.” In other words, examples of the compliant member 124 include the compliant cantilever described herein. The first body 104 and the second body 116 of the system 100 can include the pillars described herein, but can further take any suitable base structure configuration. Relatedly, the second surfaces 108 and 120 for member attachment on bodies 104 and 116 do not need to be at the ends of the bodies, but rather some distance removed from the first surfaces 106 and 118 of the bodies.

In some examples, a length of the compliant member 124 is greater than a length of the member 112 of the first structure 102 to accommodate variations in thermal expansion or transient motion between the first and second structures (102 and 114).

In some examples, the first structure 102 is configured for engagement with a first substrate 146 (see FIG. 47) and the second structure 114 is configured for engagement with a second substrate 148 (see FIG. 47) such that the connection interconnects the second substrate 148 with the first substrate 146.

In some examples, the compliant member 124 is formed from a material having a yield strength lower than a stress that would be experienced were the compliant member 124 comprised of a purely elastic material. In some examples, the compliant member 124 is formed from a metal.

In some examples, the member 112 of the first structure 102 is a rigid cantilever, and the compliant member 124 of the second structure 114 is a compliant cantilever. Numerous examples of the rigid cantilever and the compliant cantilever are provided herein.

In some examples, the first structure 102 is a component of a first array 132 (FIG. 3B); i.e., the first array 132 includes a plurality of the first structures 102. Further, the system 100 includes a second array 136, the second array 136 including a plurality of the second structures 114. In these examples, the first array 132 and the second array 136 are configured for heterogeneous integration.

In some examples, the member 112 of the first structure 102 is rigid and reusable such that the member 112 does not experience irreversible deformation to form the connection. In some examples, the first structure 102 is rigid and reusable such that the first structure 102 does not experience irreversible deformation to form the connection.

In some examples, the connection between the first structure 102 and the second structure 114 is a releasable connection. In other words, the second structure 114 can be removed from the first structure 102 by moving the second structure 114 away from the first structure 102. As this action occurs, the compliant member 124 shifts to accommodate this release/removal of the connection, and/or portions of the compliant member 124 permanently deform, break away, or change shape to accommodate a release of the second structure 114 from the first structure 102.

In some examples, the compliant member 124 of the second structure 114 is configured to undergo permanent deformation to remove the connection and separate the first structure 102 from the second structure 114 after formation of the connection.

In some examples, the first structure 102 and the second structure 114 are formed from conducting materials to accommodate electrical connection between the first structure 102 and the second structure 114.

In some examples, the first structure 102 includes a proximal side 140 facing towards the second structure 114, and a distal side 142 opposite the proximal side 140 and facing away from the second structure 114, with the compliant member 124 engaging at least a portion of the proximal side 140 of the first structure 102 upon the deformation to form the connection.

In some examples, the compliant member 124 of the second structure 114 includes a curved portion configured to engage the first structure 102 to form the connection.

### STATEMENT SECTION

The description of the disclosure is provided to enable a person skilled in the art to make or use the disclosure. Various modifications to the disclosure will be readily apparent to those skilled in the art, and the generic principles defined herein may be applied to other variations without departing from the spirit or scope of the disclosure. Throughout this disclosure the term “example” or “exemplary” indicates an example or instance and does not imply or require any preference for the noted example. Thus, the disclosure is not to be limited to the examples and designs described herein but is to be accorded the widest scope consistent with the principles and novel features disclosed herein. Illustrative aspects of this disclosure include:
Statement 1. A system that includes a first structure, and a second structure configured for engagement with the first structure. The first structure includes a first body defining a first end and a second end opposite the first end, with the first end configured to be fixed to, mounted to, coupled to, or positioned along a first supporting surface. The first structure further includes a member extending from the second end of the first body. The system further includes second structure configured for engagement with the first structure. The second structure includes a second body defining a first end and a second end opposite the first end, with the first end configured to be fixed to a second supporting surface. The second structure further includes a compliant member extending from the second end of the second body, with the compliant member being configured for deformation. In general, the second structure is configured to form a connection with the first structure by deformation of at least a portion of the compliant member relative to the first structure.
Statement 2. The system of statement 1, wherein formation of the first structure and second structure is configured to accommodate a first force to form the connection and shift the portion of the compliant member along the first structure, the first force being of a smaller magnitude than the magnitude of a second force to disengage the first structure from the second structure and remove the connection.
Statement 3. The system of any one of statements 1-2, the compliant member of the second structure includes a plurality of regions, such as a first region extending from the second end of the second body 116, and a second region extending from the first region. The regions of the compliant member can further form a general s-shape configuration, a hook, or can take the form of any of the shape/design configurations described herein.
Statement 4. The system of any one of the statements 1-3, wherein a length of the compliant member is greater than a length of the member of the first structure to accommodate variations in thermal expansion or transient motion between the first and second structures.
Statement 5. The system of any one of the statements 1-4, wherein the first structure is configured for engagement with a first substrate and the second structure is configured for engagement with a second substrate such that the connection interconnects the second substrate with the first substrate.
Statement 6. The system of any one of the statements 1-5, wherein the compliant member is formed from a material having a yield strength lower than a stress that would be experienced were the compliant member comprised of a purely elastic material. In some examples, the compliant member formed from a metal.
Statement 7. The system of any one of the statements 1-6, wherein the member of the first structure is a rigid cantilever, and the compliant member of the second structure is a compliant cantilever.
Statement 8. The system of any one of the statements 1-7, wherein the first structure is a component of a first array such that the first array includes a plurality of the first structures. Further, the system includes a second array, the second array including a plurality of the second structures. In these examples, the first array and the second array are configured for heterogeneous integration.
Statement 9. The system of any one of the statements 1-8, wherein the member of the first structure is rigid and reusable such that the member does not experience irreversible deformation to form the connection. In some examples, the first structure is rigid and reusable such that the first structure does not experience irreversible deformation to form the connection.
Statement 10. The system of any one of the statements 1-9, wherein the connection between the first structure and the second structure is a releasable connection. In other words, the second structure can be removed from the first structure by moving the second structure away from the first structure. As this action occurs, the compliant member shifts to accommodate this release/removal of the connection, and/or portions of the compliant member permanently deform, break away, or change shape to accommodate a release of the second structure from the first structure.
Statement 11. The system of any one of the statements 1-10, wherein the compliant member of the second structure undergoes permanent deformation to remove the connection and separate the first structure from the second structure after formation of the connection.
Statement 12. The system of any one of the statements 1-11, wherein the first structure and the second structure are formed from conducting materials to accommodate electrical connection between the first structure and the second structure.
Statement 13. The system of any one of the statements 1-12, wherein the first structure includes a proximal side facing towards the second structure, and a distal side opposite the proximal side and facing away from the second structure, with the compliant member engaging at least a portion of the proximal side of the first structure upon the deformation to form the connection.
Statement 14. The system of any one of the statements 1-13, wherein the compliant member of the second structure includes a curved portion configured to engage the first structure to form the connection.
Statement 15. Method of making a system for mechanical attachment according to any of statements 1-14.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A system for mechanical attachment, comprising:
a first structure, including:
a first body defining a first end and a second end opposite the first end, with the first end configured to be fixed to a first supporting surface, and
a member extending from the second end of the first body; and
a second structure configured for engagement with the first structure, including:
a second body defining a first end and a second end opposite the first end, with the first end configured to be fixed to a second supporting surface and
a compliant member extending from the second end of the second body, with the compliant member configured for deformation,
wherein the second structure is configured to form a connection with the first structure by deformation of at least a portion of the compliant member relative to the first structure.

2. The system of claim 1, wherein formation of the first structure and second structure is configured to accommodate a first force to form the connection and shift the portion of the compliant member along the first structure, the first force being less than a second force to disengage the first structure from the second structure and remove the connection.

3. The system of claim 1, wherein the compliant member of the second structure includes:
a first region extending from the second end of the second body;
a second region extending orthogonally from the first region in parallel relation relative to the second body; and
a third region extending from the second region,
wherein the regions of the compliant member include orthogonal orientations relative to each other.

4. The system of claim 1, wherein a length of the compliant member is greater than a length of the member of the first structure to accommodate variations in thermal expansion or transient motion between the first and second structures.

5. The system of claim 1, wherein the first structure is configured for engagement with a first substrate and the second structure is configured for engagement with a second substrate such that the connection interconnects the second substrate with the first substrate.

6. The system of claim 1, wherein the compliant member is formed from a material having a yield strength that is experienced within the compliant member on engagement with the first structure.

7. The system of claim 1, wherein the member of the first structure is a rigid cantilever, and the compliant member of the second structure is a compliant cantilever.

8. The system of claim 1, further comprising:
a first array, the first array including a plurality of the first structures; and
a second array, the second array including a plurality of the second structures,
wherein the first array and the second array are configured for heterogeneous integration.

9. The system of claim 1, wherein the member of the first structure is rigid and reusable such that the member does not experience irreversible deformation to form the connection.

10. The system of claim 1, wherein the connection is a releasable connection.

11. The system of claim 10, wherein the compliant member of the second structure is configured to undergo permanent deformation to remove the connection and separate the first structure from the second structure after formation of the connection.

12. The system of claim 1, wherein the first structure and the second structure are formed from conducting materials to accommodate electrical connection between the first structure and the second structure.

13. The system of claim 1, wherein the first structure includes proximal side and a distal side opposite the proximal side, the compliant member engaging at least a portion of the proximal side of the first structure upon the deformation to form the connection.

14. The system of claim 1, wherein the compliant member of the second structure includes a curved portion configured to engage the first structure to form the connection.

15. A method of making a system for mechanical attachment as in one of claims 1-14.
